(19) United States
(12) Patent Application Publication
(10) Pub. No.: US 2020/0225577 A1
(43) Pub. Date: Jul. 16, 2020

(54) COMPOSITION, FILM, OPTICAL FILTER, SOLID IMAGE PICKUP ELEMENT, AND INFRARED SENSOR

(71) Applicant: FUJIFILM Corporation, Tokyo (JP)

(72) Inventors: Kazutaka TAKAHASHI, Haibara-gun (JP); Masahiro MORI, Haibara-gun (JP)

(73) Assignee: FUJIFILM Corporation, Tokyo (JP)

(21) Appl. No.: 16/829,719

(22) Filed: Mar. 25, 2020

Related U.S. Application Data
(63) Continuation of application No. PCT/JP2018/034939, filed on Sep. 21, 2018.

(30) Foreign Application Priority Data
Sep. 28, 2017 (JP) 2017-188007
Aug. 22, 2018 (JP) 2018-155311

(51) Int. Cl. G03F 7/00; C08F 290/14; C09D 5/32; G03F 7/029; C09D 135/02; G02B 5/20

(52) U.S. Cl. CPC G03F 7/0007; C08F 290/14; G02B 5/208; G03F 7/029; C09D 135/02; C09D 5/32

(57) ABSTRACT

Provided is a composition with which a film capable of detecting infrared light with high sensitivity for use in an infrared sensor or the like can be formed. In addition, provided are a film, an optical filter, a solid image pickup element, and an infrared sensor. This composition includes: a color material that transmits infrared light and blocks visible light; a near infrared absorbing colorant; and a curable compound. In the composition, a ratio A/B of a minimum value A of an absorbance of the composition in a wavelength range of 400 to 700 nm to a maximum value B of an absorbance of the composition in a wavelength range of 1,400 to 1,500 nm is 4.5 or higher, and in a case where a film having a thickness of 1 μm is formed using the composition, the film has a maximum value of a refractive index in a wavelength range of 800 nm or longer.

### CROSS-REFERENCE TO RELATED APPLICATIONS

This application is a Continuation of PCT International Application No. PCT/JP2018/034939 filed on Sep. 21, 2018, which claims priority under 35 U.S.C § 119(a) to Japanese Patent Application No. 2017-188007 filed on Sep. 28, 2017 and Japanese Patent Application No. 2018-155311 filed on Aug. 22, 2018. Each of the above application(s) is hereby expressly incorporated by reference, in its entirety, into the present application.

### BACKGROUND OF THE INVENTION

### 1. Field of the Invention

The present invention relates to a composition that is used for manufacturing an infrared transmitting filter or the like, and a film formed of the composition. In addition, the present invention relates to an optical filter including a pixel of an infrared transmitting filter, a solid image pickup element, and an infrared sensor.

### 2. Description of the Related Art

A solid image pickup element is used as an optical sensor in various applications. For example, infrared light is less likely to be scattered than visible light due to its longer wavelength and can be used in, for example, distance measurement or three-dimensional measurement. In addition, the infrared light is invisible to persons or animals. Therefore, even in a case where a subject is irradiated with light emitted from an infrared light source at night, the subject cannot recognize the infrared light. Thus, near infrared light can be used for imaging a nocturnal wild animal or imaging a subject without provoking the subject for a security reason. This way, an optical sensor (infrared sensor) that detects infrared light can be used in various applications, and the development of a film that can be used in an infrared sensor is desired.

WO2015/166779A describes a coloring composition including a colorant and a resin, in which a ratio A/B of a minimum value A of an absorbance in a wavelength range of 400 to 830 nm to a maximum value B of an absorbance in a wavelength range of 1,000 to 1,300 nm is 4.5 or higher.

### SUMMARY OF THE INVENTION

In general, as the wavelength of light used for detection increases, the sensitivity of an infrared sensor is likely to decrease. Accordingly, a component other than light having a desired wavelength becomes a noise such that the detection accuracy of the infrared sensor may decrease.

Accordingly, an object of the present invention is to provide a composition with which a film capable of detecting infrared light with high sensitivity for use in an infrared sensor or the like can be formed. In addition, another object of the present invention is to provide a film capable of detecting infrared light with high sensitivity for use in an infrared sensor or the like, an optical filter, a solid image pickup element, and an infrared sensor.

As a result of detailed investigation, the present inventors found that the objects can be achieved using a composition described below, thereby completing the present invention.

That is, the present invention is as follows.

<1> A composition comprising:

a color material that transmits infrared light and blocks visible light;

a near infrared absorbing colorant; and

a curable compound,

in which a ratio A/B of a minimum value A of an absorbance of the composition in a wavelength range of 400 to 700 nm to a maximum value B of an absorbance of the composition in a wavelength range of 1,400 to 1,500 nm is 4.5 or higher, and

in a case where a film having a thickness of 1 μm is formed using the composition, the film has a maximum value of a refractive index in a wavelength range of 800 nm or longer.

<2> The composition according to <1>,

in which the maximum value of the refractive index is 1.8 or higher.

<3> The composition according to <1> or <2>,

in which the maximum value of the refractive index is present on a longer wavelength side than a maximum absorption wavelength of the near infrared absorbing colorant.

<4> The composition according to <1> or <2>,

in which the maximum value of the refractive index is present in a wavelength range of 800 to 1,000 nm.

<5> The composition according to any one of <1> to <4>,

in which the near infrared absorbing colorant is at least one selected from a squarylium compound, a pyrrolopyrrole compound, a cyanine compound, a phthalocyanine compound, or an immonium compound.

<6> The composition according to any one of <1> to <5>,

in which the color material that transmits infrared light and blocks visible light includes two or more chromatic colorants and forms black using a combination of the two or more chromatic colorants, or includes one or more chromatic colorants and an organic black colorant.

<7> The composition according to any one of <1> to <6>,

in which a content of the near infrared absorbing colorant is 5 to 200 parts by mass with respect to 100 parts by mass of the color material that transmits infrared light and blocks visible light.

<8> The composition according to any one of <1> to <7>,

in which the color material that transmits infrared light and blocks visible light includes at least a blue colorant.

<9> The composition according to any one of <1> to <8>,

in which a content of a blue colorant is 10% to 50% by mass with respect to a total mass of the color material that transmits infrared light and blocks visible light.

<10> The composition according to any one of <1> to <9>,

in which the curable compound includes a compound having at least one selected from a fluorene skeleton or a triazine skeleton.

<11> The composition according to any one of <1> to <10>, further comprising:

inorganic particles.

<12> The composition according to <11>,

in which the inorganic particles are titanium dioxide particles.

<13> The composition according to any one of <1> to <12>,

in which in a case where a film having a thickness of 1 μm is formed using the composition from which the near infrared absorbing colorant is excluded, a minimum value of a refractive index of the film with respect to light in a wavelength of 900 to 1,000 nm is 1.7 or higher.

<14> The composition according to any one of <1> to <13>, which is a composition for forming a first pixel of an optical filter including the first pixel and a second pixel, in which in the first pixel, a ratio A/B of a minimum value A of an absorbance in a wavelength range of 400 to 700 nm to a maximum value B of an absorbance in a wavelength range of 1,400 to 1,500 nm is 4.5 or higher and a maximum value of a refractive index is in a wavelength range of 800 nm or longer, a second pixel is adjacent to the first pixel and is different from the first pixel, and a difference t1−t2 between a refractive index t1 of the first pixel and a refractive index t2 of the second pixel is larger than −0.1 in at least a part of a wavelength range of 900 to 1,400 nm.

<15> A film which is formed using the composition according to any one of <1> to <14>.

<16> An optical filter comprising:

a first pixel that is formed using the composition according to any one of <1> to <14>; and

a second pixel that is adjacent to the first pixel and is different from the first pixel.

<17> An optical filter comprising:

a first pixel in which a ratio A/B of a minimum value A of an absorbance in a wavelength range of 400 to 700 nm to a maximum value B of an absorbance in a wavelength range of 1,400 to 1,500 nm is 4.5 or higher and a maximum value of a refractive index is in a wavelength range of 800 nm or longer; and

a second pixel that is adjacent to the first pixel and is different from the first pixel,

in which a difference t1−t2 between a refractive index t1 of the first pixel and a refractive index t2 of the second pixel is larger than −0.1 in at least a part of a wavelength range of 900 to 1,400 nm.

<18> The optical filter according to <17>,

in which the maximum value of the refractive index of the first pixel is 1.8 or higher.

<19> The optical filter according to <17> or <18>,

in which the maximum value of the refractive index of the first pixel is present in a wavelength range of 800 to 1,000 nm.

<20> The optical filter according to any one of <16> to <19>,

in which a difference t1−t2 between a refractive index t1 of the first pixel and a refractive index t2 of the second pixel is larger than −0.1 in at least a part of a wavelength range of 900 to 1,000 nm.

<21> A solid image pickup element comprising:

the film according to <15> or the optical filter according to any one of <16> to <20>.

<22> An infrared sensor comprising:

the film according to <15> or the optical filter according to any one of <16> to <20>.

According to the present invention it is possible to provide a composition with which a film capable of detecting infrared light with high sensitivity for use in an infrared sensor or the like can be formed. In addition, it is possible is to provide a film capable of detecting infrared light with high sensitivity for use in an infrared sensor or the like, an optical filter, a solid image pickup element, and an infrared sensor.

### BRIEF DESCRIPTION OF THE DRAWINGS

FIG. 1 is a schematic cross-sectional view showing a configuration of an embodiment of an infrared sensor according to the present invention.

FIG. 2 is a front view illustrating an optical filter manufactured in Examples and Reference Examples.

FIG. 3 is a cross-sectional view taken along line a-a of FIG. 2.

FIG. 4 is a cross-sectional view taken along line b-b of FIG. 2.

### DESCRIPTION OF THE PREFERRED EMBODIMENTS

In this specification, a total solid content denotes the total mass of all the components of the composition excluding a solvent.

In this specification, unless specified as a substituted group or as an unsubstituted group, a group (atomic group) denotes not only a group having no substituent but also a group having a substituent. For example, “alkyl group” denotes not only an alkyl group having no substituent (unsubstituted alkyl group) but also an alkyl group having a substituent (substituted alkyl group).

In this specification, unless specified otherwise, “exposure” denotes not only exposure using light but also drawing using a corpuscular beam such as an electron beam or an ion beam. Examples of the light used for exposure include an actinic ray or radiation, for example, a bright light spectrum of a mercury lamp, a far ultraviolet ray represented by an excimer laser, an extreme ultraviolet ray (EUV ray), an X-ray, or an electron beam.

In this specification, “(meth)acrylate” denotes either or both of acrylate or methacrylate, “(meth)acryl” denotes either or both of acryl and methacryl, and “(meth)acryloyl” denotes either or both of acryloyl and methacryloyl.

In this specification, in a chemical formula, Me represents a methyl group, Et represents an ethyl group, Pr represents a propyl group, Bu represents a butyl group, and Ph represents a phenyl group.

In this specification, the term “step” denotes not only an individual step but also a step which is not clearly distinguishable from another step as long as an effect expected from the step can be achieved.

In this specification, a weight-average molecular weight and a number-average molecular weight are defined as values in terms of polystyrene obtained by gel permeation chromatography (GPC). In this specification, an weight-average molecular weight (Mw) and a number-average molecular weight (Mn) can be obtained by using HLC-8220 (manufactured by Tosoh Corporation) as a measuring device, using TSKgel Super AWM-H (manufactured by Tosoh Corporation; 6.0 mm ID (inner diameter)×15.0 cm) as a column, and using a 10 mmol/L lithium bromide N-methyl pyrrolidinone (NMP) solution as an eluent.

In this specification, “near infrared light” denotes light (electromagnetic wave) in a wavelength range of 700 to 2,500 nm.

A pigment described in the present invention denotes an insoluble colorant compound which is not likely to dissolve in a solvent. Typically, a pigment denotes a colorant compound which is present in a state of being dispersed as particles in a composition. As the solvent described herein, for example, an arbitrary solvent can be used, and examples thereof are described in “Solvent” described below. It is preferable that the pigment used in the present invention has a solubility of 0.1 g/100 g Solvent or lower at 25° C., for example, both in propylene glycol monomethyl ether acetate and in water.

<Composition>

A composition according to an embodiment of the present invention includes:

a color material that transmits infrared light and blocks visible light;
a near infrared absorbing colorant; and
a curable compound,

in which a ratio A/B of a minimum value A of an absorbance of the composition in a wavelength range of 400 to 700 nm to a maximum value B of an absorbance of the composition in a wavelength range of 1,400 to 1,500 nm is 4.5 or higher, and

in a case where a film having a thickness of 1 μm is formed using the composition, the film has a maximum value of a refractive index in a wavelength range of 800 nm or longer.

In the composition according to the embodiment of the present invention, a ratio A/B of a minimum value A of an absorbance of the composition in a wavelength range of 400 to 700 nm to a maximum value B of an absorbance of the composition in a wavelength range of 1,400 to 1,500 nm is 4.5 or higher. Therefore, a film having high light blocking properties with respect to light in a wavelength range of 400 to 700 nm can be formed. Thus, with the composition according to the embodiment of the present invention, a film that transmits infrared light in a state where noise derived from visible light is small can be formed.

This composition has a characteristic in which, in a case where a film having a thickness of 1 μm is formed using the composition, the film has a maximum value of a refractive index in a wavelength range of 800 nm or longer. That is, in a case where a film having a thickness of 1 μm is formed using the composition according to the embodiment of the present invention, anomalous dispersion of a refractive index in a wavelength range of 800 nm or longer occurs. Here, the meaning of the anomalous dispersion of the refractive index is as follows. In general, a refractive index of a material tends to decrease as the wavelength increases. This phenomenon refers to normal dispersion of the refractive index. On the other hand, a phenomenon in which a refractive index largely deviates from the normal dispersion and rapidly increases as the wavelength increases refer to anomalous dispersion.

This way, in the film formed using the composition according to the embodiment of the present invention, the maximum value of the refractive index is present in a wavelength range of 800 nm or longer. Therefore, a refractive index of light in a wavelength range of 800 nm or longer is high, and light collecting properties of infrared light transmitted through the film can be improved. Thus, by using the film formed using the composition according to the embodiment of the present invention in an infrared sensor or the like, light collecting properties of infrared light having a desired wavelength can be improved while allowing transmission of the infrared light in a state where noise derived from visible light is small, and the sensitivity of the infrared sensor can be significantly improved.

The maximum value of the above-described refractive index is preferably 1.8 or higher, more preferably 1.85 or higher, and still more preferably 1.9 or higher. In addition, it is preferable that the maximum value of the above-described refractive index is present on a longer wavelength side than a maximum absorption wavelength of the near infrared absorbing colorant in the composition according to the embodiment of the present invention, it is more preferable that the maximum value of the above-described refractive index is present on a longer wavelength side than the maximum absorption wavelength of the above-described near infrared absorbing colorant by 15 nm or longer, and it is still more preferable that the maximum value of the above-described refractive index is present on a longer wavelength side than the maximum absorption wavelength of the above-described near infrared absorbing colorant by 30 nm or longer. In addition, the maximum value of the above-described refractive index is present preferably in a wavelength range of 800 to 1,000 nm, more preferably in a wavelength range of 830 to 970 nm, and in a wavelength range of 860 to 940 nm.

In addition, in the composition according to the embodiment of the present invention, in a case where a film having a thickness of 1 μm is formed using the composition from which the near infrared absorbing colorant is excluded, a minimum value of a refractive index of the film with respect to light in a wavelength of 900 to 1,000 nm is preferably 1.7 or higher and more preferably 1.75 or higher. In this aspect, light collecting properties of infrared light transmitted through the film can be further improved.

In addition, it is preferable that the composition according to the embodiment of the present invention is a composition for forming a first pixel of an optical filter including the first pixel and a second pixel, the first pixel having a configuration in which a ratio A/B of a minimum value A of an absorbance in a wavelength range of 400 to 700 nm to a maximum value B of an absorbance in a wavelength range of 1,400 to 1,500 nm is 4.5 or higher and a maximum value of a refractive index is present in a wavelength range of 800 nm or longer, and a second pixel being adjacent to the first pixel and being different from the first pixel, in which a difference (t1−t2) between a refractive index t1 of the first pixel and a refractive index t2 of the second pixel is larger than −0.1 in at least a part of a wavelength range of 900. to 1,400 nm (preferably at least a part of a wavelength of 900 to 1,000 nm). In this aspect, an optical filter in which light collecting properties of infrared light transmitted through the first pixel is higher can be obtained, and by using this optical filter as an infrared sensor or the like, the sensitivity of the infrared sensor can be significantly improved. The difference between the above-described refractive indices is preferably −0.05 or higher and more preferably 0 or higher.

The absorbance conditions may be satisfied using any means. For example, as described below in detail, the composition includes: a color material that transmits infrared light and blocks visible light; and a near infrared absorbing colorant, in which the contents and kinds of the components are adjusted. As a result, the absorbance conditions can be suitably satisfied.

In addition, examples of a method for obtaining the film having a maximum value of a refractive index in a wavelength range of 800 nm or longer include a method of adjusting the kind, content, and the like of the near infrared absorbing colorant, a method of adjusting a mixing ratio between the color material that transmits infrared light and blocks visible light and the near infrared absorbing colorant, and a method of adding a conductive material such as a conductive polymer or carbon as another additive for adjustment. For example, by using a near infrared absorbing colorant that is likely to aggregate in the film, by using a near infrared absorbing colorant having a narrower half-width of an absorbance at a maximum absorption wavelength, by increasing the content of the near infrared absorbing colorant, or by increasing the content of the conductive material, the maximum value of the refractive index can be further increased. In addition, examples of a method of shifting the maximum value of the refractive index to a longer wavelength side include a method of adding a near infrared absorbing colorant having a maximum absorption wavelength on a longer wavelength side and a method of increasing the number of aggregates of the near infrared absorbing colorant in the film.

Regarding the spectral characteristics of the composition according to the embodiment of the present invention, the value of A/B is preferably 7.5 or higher, more preferably 15 or higher, and still more preferably 30 or higher. The upper limit is, for example, 90 or lower.

An absorbance Aλ at a wavelength λ is defined by the following Expression (1).

Aλ=−log(Tλ/100) (1)

Aλ represents the absorbance at the wavelength λ, and Tλ represents a transmittance (%) at the wavelength λ.

In the present invention, a value of the absorbance may be a value measured in the form of a solution or a value of a film which is formed using the composition according to the embodiment of the present invention. In a case where the absorbance is measured in the form of the film, it is preferable that the absorbance is measured using a film that is formed by applying the composition to a glass substrate using a method such as spin coating such that the thickness of the dried film is a predetermined value, and drying the applied composition using a hot plate at 100° C. for 120 seconds. The thickness of the film can be obtained by measuring the thickness of the substrate including the film using a stylus surface profilometer (DEKTAK 150, manufactured by ULVAC Inc.). In addition, the absorbance can be measured using a well-known spectrophotometer of the related art. Measurement conditions of the absorbance are not particularly limited. It is preferable that the maximum value B of the absorbance in a wavelength range of 1,400 to 1,500 nm is measured under conditions which are adjusted such that the minimum value A of the absorbance in a wavelength range of 400 to 700 nm is 0.1 to 3.0. By measuring the absorbance under the above-described conditions, a measurement error can be further reduced. A method of adjusting the minimum value A of the absorbance in a wavelength range of 400 to 700 nm to be 0.1 to 3.0 is not particularly limited. For example, in a case where the absorbance is measured in the form of a solution, for example, a method of adjusting the optical path length of a sample cell can be used. In addition, in a case where the absorbance is measured in the form of the film, for example, a method of adjusting the thickness of the film can be used.

It is more preferable that the composition according to the embodiment of the present invention satisfies at least one of the following spectral characteristics (1) or (2).

(1): A ratio A1/B1 of a minimum value A1 of an absorbance in a wavelength range of 400 to 830 nm to a maximum value B1 of an absorbance in a wavelength range of 1,000 to 1,500 nm is 4.5 or more, preferably 7.5 or more, more preferably 15 or more, and still more preferably 30 or more. According to this aspect, a film that can block light in a wavelength range of 400 to 830 nm and transmits light having a wavelength of longer than 900 nm can be formed.

(2): A ratio A2/B2 of a minimum value A2 of an absorbance in a wavelength range of 400 to 950 nm to a maximum value B2 of an absorbance in a wavelength range of 1,100 to 1,500 nm is 4.5 or more, preferably 7.5 or more, more preferably 15 or more, and still more preferably 30 or more. According to this aspect, a film that can block light in a wavelength range of 400 to 950 nm and transmits light having a wavelength of longer than 1,000 nm can be formed.

In a case where a film is formed using the composition according to the embodiment of the present invention such that the thickness after drying is 0.1 to 50 μm (preferably 0.1 to 20 m and more preferably 0.5 to 10 μm), it is preferable that the film has the following spectral characteristics at least one of the above-described thicknesses: that a maximum value of a light transmittance of the film in a thickness direction in a wavelength range of 400 to 700 nm is 20% or lower (preferably 15% or lower and more preferably 10% or lower); and that a minimum value of a light transmittance of the film in the thickness direction in a wavelength range of 1,400 to 1,500 nm is 70% or higher (preferably 75% or higher and more preferably 80% or higher).

In addition, it is preferable that the composition according to the embodiment of the present invention satisfies at least one of the following spectral characteristics (IR1) or (IR2).

(IR1): An aspect in which, in a case where a film having a thickness of 1 μm, 2 μm, 3 m, 4 μm, or 5 μm is formed using the composition according to the embodiment of the present invention, a maximum value of a light transmittance of the film in a thickness direction in a wavelength range of 400 to 830 nm is 20% or lower (preferably 15% or lower and more preferably 10% or lower), and a minimum value of a light transmittance of the film in the thickness direction in a wavelength range of 1,000 to 1,500 nm is 70% or higher (preferably 75% or higher and more preferably 80% or higher).

(IR2): An aspect in which, in a case where a film having a thickness of 1 μm, 2 μm, 3 m, 4 μm, or 5 μm after drying is formed using the composition according to the embodiment of the present invention, a maximum value of a light transmittance of the film in a thickness direction in a wavelength range of 400 to 950 nm is 20% or lower (preferably 15% or lower and more preferably 10% or lower), and a minimum value of a light transmittance of the film in the thickness direction in a wavelength range of 1,100 to 1,500 nm is 70% or higher (preferably 75% or higher and more preferably 80% or higher).

Regarding the composition according to the embodiment of the present invention, at at least one value of the film thicknesses, the minimum value A of the absorbance in a wavelength range of 400 to 700 nm is, for example, preferably 0.1 to 5 and more preferably 0.3 to 3. In addition, the maximum value B of the absorbance in a wavelength range of 1,400 to 1,500 nm is, for example, preferably 0.01 to 0.5 and more preferably 0.02 to 0.3.

Methods of measuring the spectral characteristics, the thickness, and the refractive index of the film formed using the composition according to the embodiment of the present invention are as follows. The composition according to the embodiment of the present invention is applied to a glass substrate using a method such as spin coating such that the thickness of the dried film is a predetermined value, and then is dried using a hot plate at 100° C. for 120 seconds. The thickness of the film is measured using a stylus surface profilometer (DEKTAK 150, manufactured by ULVAC Inc.). Regarding the spectral characteristics, the transmittance in a wavelength range of 300 to 1,300 nm is measured using an ultraviolet-visible-near infrared spectrophotometer (U-4100, manufactured by Hitachi High-Technologies Corporation). The refractive index is measured using an ellipsometer VUV-VASE (manufactured by J. A. Woollam Co., Inc.).

The composition according to the embodiment of the present invention can also be referred to as an infrared light transmitting composition because it transmits infrared light. Hereinafter, each of components which can form the composition according to the embodiment of the present invention will be described.

<<Color Material that Transmits Infrared Light and Blocks Visible Light>>

The composition according to the embodiment of the present invention includes the color material that transmits infrared light and blocks visible light (hereinafter, also referred to as “color material that blocks visible light”). In the present invention, it is preferable that the color material that blocks the visible light is a color material that absorbs light in a wavelength range of violet to red. In addition, in the present invention, it is preferable that the color material that blocks the visible light is a color material that blocks light in a wavelength range of 400 to 700 nm. In addition, it is preferable that the color material that blocks visible light is a color material that transmits light in a wavelength range of 1,400 to 1,500 nm. In the present invention, it is preferable that the color material that blocks the visible light satisfies at least one of the following requirement (1) or (2).

(1): The light blocking material includes two or more chromatic colorants, and a combination of the two or more chromatic colorants forms black.

(2): The light blocking material includes an organic black colorant. In the aspect (2), it is preferable that the light blocking material further includes a chromatic colorant.

In the present invention, the chromatic colorant denotes a colorant other than a white colorant and a black colorant. In addition, in the present invention, the organic black colorant used for the color material that blocks the visible light denotes a material that absorbs visible light and transmits at least a part of near infrared light. Accordingly, in the present invention, the organic black colorant used for the color material that blocks the visible light does not denote a black colorant that absorbs both visible light and near infrared light, for example, carbon black or titanium black. It is preferable that the organic black colorant is a colorant having a maximum absorption wavelength in a wavelength range of 400 to 700 nm.

In the present invention, it is preferable that the color material that blocks the visible light is a material in which the ratio A/B of the minimum value A of the absorbance in a wavelength range of 400 to 700 nm to the maximum value B of the absorbance in a wavelength range of 1,400 to 1,500 nm is 4.5 or more. The above-described characteristics may be satisfied using one material alone or using a combination of a plurality of materials. For example, in the aspect (1), it is preferable that the spectral characteristics are satisfied using a combination of a plurality of chromatic colorants. In addition, in the aspect (2), the spectral characteristics may be satisfied using an organic black colorant. In addition, the spectral characteristics may be satisfied using a combination of an organic black colorant and a chromatic colorant.

(Chromatic Colorant)

It is preferable that the chromatic colorant is selected from a red colorant, a green colorant, a blue colorant, a yellow colorant, a violet colorant, and an orange colorant. The chromatic colorant used in the present invention may be a pigment or a dye. It is preferable that the chromatic colorant is a pigment. It is preferable that an average particle size (r) of the pigment satisfies preferably 20 nm≤r≤300 nm, more preferably 25 nm≤r≤250 nm, and still more preferably 30 nm≤r≤200 nm. “Average particle size” described herein denotes the average particle size of secondary particles which are aggregates of primary particles of the pigment. In addition, regarding a particle size distribution of the secondary particles of the pigment (hereinafter, simply referred to as “particle size distribution”) which can be used, secondary particles having a particle size of (average particle size±100) nm account for preferably 70% by mass or more and more preferably 80% by mass or more in the pigment. The particle size distribution of the secondary particles can be measured using a scattering intensity distribution.

It is preferable that the pigment is an organic pigment. Preferable examples of the organic pigment are as follows:

Color Index (C.I.) Pigment Yellow 1, 2, 3, 4, 5, 6, 10, 11, 12, 13, 14, 15, 16, 17, 18, 20, 24, 31, 32, 34, 35, 35:1, 36, 36:1, 37, 37:1, 40, 42, 43, 53, 55, 60, 61, 62, 63, 65, 73, 74, 77, 81, 83, 86, 93, 94, 95, 97, 98, 100, 101, 104, 106, 108, 109, 110, 113, 114, 115, 116, 117, 118, 119, 120, 123, 125, 126, 127, 128, 129, 137, 138, 139, 147, 148, 150, 151, 152, 153, 154, 155, 156, 161, 162, 164, 166, 167, 168, 169, 170, 171, 172, 173, 174, 175, 176, 177, 179, 180, 181, 182, 185, 187, 188, 193, 194, 199, 213, and 214 (all of which are yellow pigments);

C.I. Pigment Orange 2, 5, 13, 16, 17:1, 31, 34, 36, 38, 43, 46, 48, 49, 51, 52, 55, 59, 60, 61, 62, 64, 71, and 73 (all of which are orange pigments);

C.I. Pigment Red 1, 2, 3, 4, 5, 6, 7, 9, 10, 14, 17, 22, 23, 31, 38, 41, 48:1, 48:2, 48:3, 48:4, 49, 49:1, 49:2, 52:1, 52:2, 53:1, 57:1, 60:1, 63:1, 66, 67, 81:1, 81:2, 81:3, 83, 88, 90, 105, 112, 119, 122, 123, 144, 146, 149, 150, 155, 166, 168, 169, 170, 171, 172, 175, 176, 177, 178, 179, 184, 185, 187, 188, 190, 200, 202, 206, 207, 208, 209, 210, 216, 220, 224, 226, 242, 246, 254, 255, 264, 270, 272, and 279 (all of which are red pigments);

C.I. Pigment Green 7, 10, 36, 37, 58, and 59 (all of which are green pigments);

C.I. Pigment Violet 1, 19, 23, 27, 32, 37, and 42 (all of which are violet pigments); and

C.I. Pigment Blue 1, 2, 15, 15:1, 15:2, 15:3, 15:4, 15:6, 16, 22, 60, 64, 66, 79, and 80 (all of which are blue pigments).

Among these organic pigments, one kind may be used alone, or two or more kinds may be used in combination.

As the dye, well-known dyes can be used without any particular limitation. In terms of a chemical structure, a dye such as a pyrazole azo dye, an anilino azo dye, a triarylmethane dye, an anthraquinone dye, an anthrapyridone dye, a benzylidene dye, an oxonol dye, a pyrazolotriazole azo dye, a pyridone azo dye, a cyanine dye, a phenothiazine dye, a pyrrolopyrazoleazomethine dye, a xanthene dye, a phthalocyanine dye, a benzopyran dye, an indigo dye, or a pyrromethene dye can be used. In addition, a polymer of the above-described dyes may be used. In addition, dyes described in JP2015-028144A and JP2015-034966A can also be used.

(Organic Black Colorant)

Examples of the organic black colorant include a bisbenzofuranone compound, an azomethine compound, a perylene compound, and an azo compound. Among these, a bisbenzofuranone compound or a perylene compound is preferable. Examples of the bisbenzofuranone compound include a compound described in JP2010-534726A, JP2012-515233A, and JP2012-515234A. For example, “Irgaphor Black” (manufactured by BASF SE) is available. Examples of the perylene compound include C.I. Pigment Black 31 and 32. Examples of the azomethine compound include compounds described in JP1989-170601A (JP-H1-170601A) and JP1990-034664A (JP-H2-034664A). For example, “CHROMOFINE BLACK A1103” (manufactured by Dainichiseika Color & Chemicals Mfg. Co., Ltd.) is available. It is preferable that the bisbenzofuranone compound is one of the following compounds represented by the following formulae or a mixture thereof.

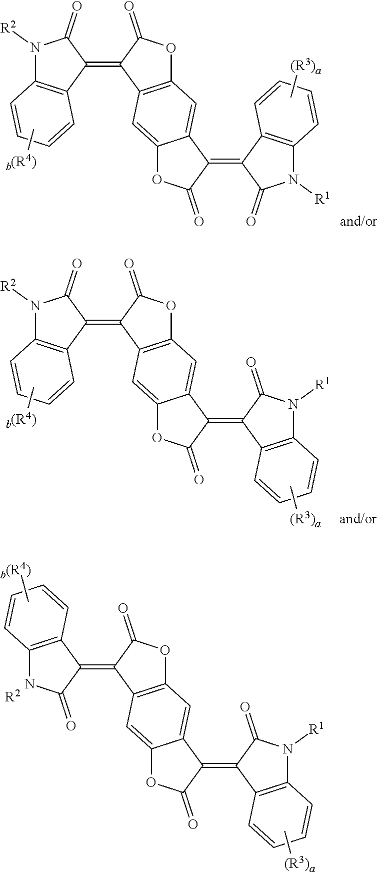

In the formulae, R¹ and R² each independently represent a hydrogen atom or a substituent, R³ and R⁴ each independently represent a substituent, a and b each independently represent an integer of 0 to 4, in a case where a is 2 or more, a plurality of R³'s may be the same as or different from each other, a plurality of R³'s may be bonded to each other to form a ring, in a case where b is 2 or more, a plurality of R⁴'s may be the same as or different from each other, and a plurality of R⁴'s may be bonded to each other to form a ring. The substituent represented by R¹ to R⁴ is a halogen atom, a cyano group, a nitro group, an alkyl group, an alkenyl group, an alkynyl group, an aralkyl group, an aryl group, a heteroaryl group, —OR³⁰¹, —COR³⁰², —COOR³⁰³, —OCOR³⁰⁴, —NR³⁰⁵R³⁰⁶, —NHCOR³⁰⁷, —CONR³⁰⁸R³⁰⁹, —NHCONR³¹⁰R³¹¹, —NHCOOR³¹², —SR³¹³, —SO₂R³¹⁴, —SO₂OR³¹⁵, —NHSO₂R³¹⁶, or —SO₂NR³¹⁷R³¹⁸. R³⁰¹ to R³¹⁸ each independently represent a hydrogen atom, an alkyl group, an alkenyl group, an alkynyl group, an aryl group, or a heteroaryl group. The details of the bisbenzofuranone compound can be found in paragraphs “0014” to “0037” of JP2010-534726A, the content of which is incorporated herein by reference.

In a case where black is formed using a combination of the two or more chromatic colorants, it is preferable that the color material that blocks visible light includes two or more selected from a red colorant, a blue colorant, a yellow colorant, a violet colorant, and a green colorant. In addition, in this case, it is also preferable that the color material that blocks visible light includes at least a blue colorant from the viewpoint of the spectral characteristics and the refractive index of the obtained film. Examples of preferable combinations include the following (1) to (7). Among these, (1) to (6) are preferable, (3) to (5) are more preferable, and (3) is still more preferable.

(1) An aspect in which the light blocking material includes a red colorant and a blue colorant.

(2) An aspect in which the light blocking material includes a red colorant, a blue colorant, and a yellow colorant.

(3) An aspect in which the light blocking material includes a red colorant, a blue colorant, a yellow colorant, and a violet colorant.

(4) An aspect in which the light blocking material includes a red colorant, a blue colorant, a yellow colorant, a violet colorant, and a green colorant.

(5) An aspect in which the light blocking material includes a red colorant, a blue colorant, a yellow colorant, and a green colorant.

(6) An aspect in which the light blocking material includes a red colorant, a blue colorant, and a green colorant.

(7) An aspect in which the light blocking material includes a yellow colorant and a violet colorant.

In the aspect (1), a mass ratio (red colorant:blue colorant) between the red colorant and the blue colorant is preferably 20 to 80:20 to 80, more preferably 20 to 60:40 to 80, and more preferably 20 to 50:50 to 80.

In the aspect (2), a mass ratio (red colorant:blue colorant:yellow colorant) between the red colorant, the blue colorant, and the yellow colorant is preferably 10 to 80:20 to 80:10 to 40, more preferably 10 to 60:30 to 80:10 to 30, and still more preferably 10 to 40:40 to 80:10 to 20.

In the aspect (3), a mass ratio (red colorant:blue colorant:yellow colorant:violet colorant) between the red colorant, the blue colorant, the yellow colorant, and the violet colorant is preferably 10 to 80:20 to 80:5 to 40:5 to 40, more preferably 10 to 60:30 to 80:5 to 30:5 to 30, and still more preferably 10 to 40:40 to 80:5 to 20:5 to 20.

In the aspect (4), a mass ratio (red colorant:blue colorant:yellow colorant:violet colorant:green colorant) between the red colorant, the blue colorant, the yellow colorant, the violet colorant, and the green colorant is preferably 10 to 80:20 to 80:5 to 40:5 to 40:5 to 40, more preferably 10 to 60:30 to 80:5 to 30:5 to 30:5 to 30, and still more preferably 10 to 40:40 to 80:5 to 20:5 to 20:5 to 20.

In the aspect (5), a mass ratio (red colorant:blue colorant:yellow colorant:green colorant) between the red colorant, the blue colorant, the yellow colorant, and the green colorant is preferably 10 to 80:20 to 80:5 to 40:5 to 40, more preferably 10 to 60:30 to 80:5 to 30:5 to 30, and still more preferably 10 to 40:40 to 80:5 to 20:5 to 20.

In the aspect (6), a mass ratio (red colorant:blue colorant:green colorant) between the red colorant, the blue colorant, and the green colorant is preferably 10 to 80:20 to 80:10 to 40, more preferably 10 to 60:30 to 80:10 to 30, and still more preferably 10 to 40:40 to 80:10 to 20.

In the aspect (7), a mass ratio (yellow colorant:violet colorant) between the yellow colorant and the violet colorant is preferably 10 to 50:40 to 80, more preferably 20 to 40:50 to 70, and still more preferably 30 to 40:60 to 70.

As the yellow colorant, C.I. Pigment Yellow 139, 150, or 185 is preferable, C.I. Pigment Yellow 139 or 150 is more preferable, and C.I. Pigment Yellow 139 is still more preferable. As the blue colorant, C.I. Pigment Blue 15:6 is preferable. As the violet colorant, for example, C.I. Pigment Violet 23 is preferable. As the red colorant, Pigment Red 122, 177, 224, or 254 is preferable, Pigment Red 122, 177, or 254 is more preferable, and Pigment Red 254 is still more preferable. As the green colorant, C.I. Pigment Green 7, 36, 58, or 59 is preferable.

In the present invention, in a case where an organic black colorant is used as the color material that blocks the visible light, it is preferable that the organic black colorant is used in combination with a chromatic colorant. By using the organic black colorant in combination with a chromatic colorant, excellent spectral characteristics are likely to be obtained. Examples of the chromatic colorant which can be used in combination with the organic black colorant include a red colorant, a blue colorant, and a violet colorant. Among these, a red colorant or a blue colorant is preferable, and from the viewpoint of the spectral characteristics and the refractive index of the obtained film, a blue colorant is more preferable. In addition, regarding a mixing ratio between the chromatic colorant and the organic black colorant, the amount of the chromatic colorant is preferably 10 to 200 parts by mass and more preferably 15 to 150 parts by mass with respect to 100 parts by mass of the organic black colorant.

The content of the pigment in the color material that blocks the visible light is preferably 95% by mass or more, more preferably 97% by mass or more, and still more preferably 99% by mass or more with respect to the total mass of the color material that blocks the visible light.

It is preferable that the color material that blocks visible light used in the present invention includes at least a blue colorant, and the content of the blue colorant is preferably 10% to 50% by mass, more preferably 15% to 45% by mass, and still more preferably 20% to 40% by mass with respect to the total mass of the color material that blocks visible light. In addition, it is preferable that the above-described blue colorant is a blue pigment. In this aspect, a film having a higher refractive index is likely to be formed.

The content of the color material that blocks visible light in the composition according to the embodiment of the present invention is preferably 10% to 70% by mass with respect to the total solid content of the composition according to the embodiment of the present invention. The lower limit is preferably 30% by mass or more and more preferably 40% by mass or more.

<<Near Infrared Absorbing Colorant>>

The composition according to the embodiment of the present invention includes a near infrared absorbing colorant. As the near infrared absorbing colorant, a compound having a maximum absorption wavelength in a wavelength range of longer than 700 nm and 1,300 nm or shorter, (preferably in a wavelength range of longer than 700 nm and 1,100 nm or shorter and more preferably in a wavelength range of longer than 700 nm and 1,000 nm or shorter) can be preferably used. As the near infrared absorbing colorant, a pigment or a dye may be used.

The molecular weight of the near infrared absorbing colorant is preferably 300 to 3,000. The upper limit is preferably 2,000 or less and more preferably 1,000 or less. The lower limit is preferably 400 or more and more preferably 500 or more. In a case where the molecular weight of the near infrared absorbing colorant is in the above-described range, the near infrared absorbing colorant is likely to aggregate in the film, and the number of aggregates of the near infrared absorbing colorant in the film is likely to increase. Therefore, a film having a maximum value of a refractive index in a wavelength range of 800 nm or longer is likely to be formed. Further, the value of the refractive index at the above-described maximum value can also be further increased.

As the near infrared absorbing colorant, a compound that includes a i-conjugated plane having a monocycle or fused aromatic ring can be preferably used. The number of atoms constituting the i-conjugated plane included in the near infrared absorbing colorant other than hydrogen is preferably 10 or more, more preferably 15 or more, still more preferably 20 or more, and still more preferably 30 or more. For example, the upper limit is preferably 100 or lower, more preferably 70 or lower, and still more preferably 50 or lower. In a case where the number of atoms constituting the it-conjugated plane of the near infrared absorbing colorant is in the above-described range, the near infrared absorbing colorant is likely to aggregate in the film, and a film having a maximum value of a refractive index in a wavelength range of 800 nm or longer is likely to be formed. Further, the value of the refractive index at the above-described maximum value can also be further increased.

The number of monocycle or fused aromatic rings in the i-conjugated plane included in the near infrared absorbing colorant is preferably 2 or more, more preferably 3 or more, still more preferably 4 or more, and still more preferably 5 or more. The upper limit is preferably 100 or lower, more preferably 50 or lower, and still more preferably 30 or lower. Examples of the aromatic ring include a benzene ring, a naphthalene ring, a pentalene ring, an indene ring, an azulene ring, a heptalene ring, an indacene ring, a perylene ring, a pentacene ring, a quaterrylene ring, an acenaphthene ring, a phenanthrene ring, an anthracene ring, a naphthacene ring, a chrysene ring, a triphenylene ring, a fluorene ring, a pyridine ring, a quinoline ring, an isoquinoline ring, an imidazole ring, a benzimidazole ring, a pyrazole ring, a thiazole ring, a benzothiazole ring, a triazole ring, a benzotriazole ring, an oxazole ring, a benzoxazole ring, an imidazoline ring, a pyrazine ring, a quinoxaline ring, a pyrimidine ring, a quinazoline ring, a pyridazine ring, a triazine ring, a pyrrole ring, an indole ring, an isoindole ring, a carbazole ring, and a fused ring including the above-described ring.

As the near infrared absorbing colorant, at least one selected from a squarylium compound, a pyrrolopyrrole compound, a cyanine compound, a phthalocyanine compound, an immonium compound, a naphthalocyanine compound, a quaterrylene compound, a merocyanine compound, a croconium compound, an oxonol compound, a dithiol compound, a triarylmethane compound, a pyrromethene compound, an azomethine compound, an anthraquinone compound, or a dibenzofuranone compound is preferable, a squarylium compound, a pyrrolopyrrole compound, a cyanine compound, a phthalocyanine compound, or an immonium compound is more preferable, a squarylium compound or a pyrrolopyrrole compound is still more preferable, and a squarylium compound is still more preferable from the viewpoint that a film in which a maximum value of a refractive index is present in a wavelength range of 800 nm or longer and the value of the refractive index at the maximum value is higher is likely to be formed.

Examples of the immonium compound include a compound described in JP2008-528706A, the content of which is incorporated herein by reference. Examples of the phthalocyanine compound include a compound described in paragraph “0093” of JP2012-077153A, oxytitaniumphthalocyanine described in JP2006-343631A, and a compound described in paragraphs “0013” to “0029” of JP2013-195480A, the contents of which are incorporated herein by reference. Examples of the naphthalocyanine compound include a compound described in paragraph “0093” of JP2012-077153A, the content of which is incorporated herein by reference. In addition, a compound described in paragraphs JP2016-146619A can also be used as the near infrared absorbing colorant, the content of which is incorporated herein by reference.

As the pyrrolopyrrole compound, a compound represented by Formula (PP) is preferable.

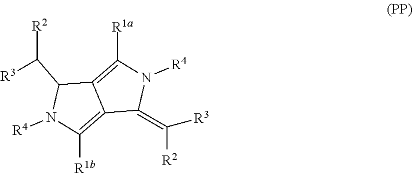

In the formula, R^{1a} and R^{1b} each independently represent an alkyl group, an aryl group, or a heteroaryl group, R² and R³ each independently represent a hydrogen atom or a substituent, R² and R³ may be bonded to each other to form a ring, R⁴'s each independently represent a hydrogen atom, an alkyl group, an aryl group, a heteroaryl group, —BR^{4A}R^{4B}, or a metal atom, R⁴ may form a covalent bond or a coordinate bond with at least one selected from R^{1a}, R^{1b}, or R³, and R^{4A} and R^{4B} each independently represent a substituent. The details of Formula (PP) can be found in paragraphs “0017” to “0047” of JP2009-263614A, paragraphs “0011” to “0036” of JP2011-068731A, and paragraphs “0010” to “0024” of WO2015/166873A, the contents of which are incorporated herein by reference.

In Formula (PP), R^{1a} and Rib each independently represent preferably an aryl group or a heteroaryl group, and more preferably an aryl group. In addition, the alkyl group, the aryl group, and the heteroaryl group represented by R^{1a} to R^{1b} may have a substituent or may be unsubstituted. Examples of the substituent include substituents described in paragraphs “0020” to “0022” of 2009-263614A and the following substituent T. In addition, in a case where the alkyl group, the aryl group, and the heteroaryl group represented by R^{1a} and R^{1b} has two or more substituents, the substituents may be bonded to each other to form a ring.

(Substituent T)

The substituent T includes an alkyl group (preferably an alkyl group having 1 to 30 carbon atoms), an alkenyl group (preferably an alkenyl group having 2 to 30 carbon atoms), an alkynyl group (preferably an alkynyl group having 2 to 30 carbon atoms), an aryl group (preferably an aryl group having 6 to 30 carbon atoms), an amino group (preferably an amino group having 0 to 30 carbon atoms), an alkoxy group (preferably an alkoxy group having 1 to 30 carbon atoms), an aryloxy group (preferably an aryloxy group having 6 to 30 carbon atoms), a heteroaryloxy group, an acyl group (preferably having an acyl group 1 to 30 carbon atoms), an alkoxycarbonyl group (preferably an alkoxycarbonyl group having 2 to 30 carbon atoms), an aryloxycarbonyl group (preferably an aryloxycarbonyl group having 7 to 30 carbon atoms), an acyloxy group (preferably an acyloxy group having 2 to 30 carbon atoms), an acylamino group (preferably an acylamino group having 2 to 30 carbon atoms), an alkoxycarbonylamino group (preferably an alkoxycarbonylamino group having 2 to 30 carbon atoms), an aryloxycarbonylamino group (preferably an aryloxycarbonylamino group having 7 to 30 carbon atoms), a sulfamoyl group (preferably a sulfamoyl group having 0 to 30 carbon atoms), a carbamoyl group (preferably a carbamoyl group having 1 to 30 carbon atoms), an alkylthio group (preferably an alkylthio group having 1 to 30 carbon atoms), an arylthio group (preferably an arylthio group having 6 to 30 carbon atoms), a heteroarylthio group (preferably having 1 to 30 carbon atoms), an alkylsulfonyl group (preferably having 1 to 30 carbon atoms), an arylsulfonyl group (preferably having 6 to 30 carbon atoms), a heteroarylsulfonyl group (preferably having 1 to 30 carbon atoms), an alkylsulfinyl group (preferably having 1 to 30 carbon atoms), an arylsulfinyl group (preferably having 6 to 30 carbon atoms), a heteroarylsulfinyl group (preferably having 1 to 30 carbon atoms), a ureido group (preferably having 1 to 30 carbon atoms), a hydroxyl group, a carboxyl group, a sulfo group, a phosphate group, a carboxylic acid amide group (preferably a group represented by —NHCOR^{A1}. R^{A1} represents a hydrocarbon group or a heterocyclic group. The hydrocarbon group and the heterocyclic group may further have a substituent. As the substituent, a halogen atom is preferable, and a fluorine atom is more preferable), a sulfonic acid amide group (preferably a group represented by —NHSO₂R^{A2}. R^{A2} represents a hydrocarbon group or a heterocyclic group. The hydrocarbon group and the heterocyclic group may further have a substituent. As the substituent, a halogen atom is preferable, and a fluorine atom is more preferable), an imide acid group (preferably a group represented by —SO₂NHSO₂R_{A3}, —CONHSO₂R^{A4}, —CONHCOR^{A5}, or —SO₂NHCOR^{A6}. R^{A3} to R^{A6} each independently represent a hydrocarbon group or a heterocyclic group. The hydrocarbon group and the heterocyclic group may further have a substituent), a mercapto group, a halogen atom, a cyano group, an alkylsulfino group, an arylsulfino group, a hydrazino group, an imino group, and a heteroaryl group (preferably having 1 to 30 carbon atoms).

In a case where the above-described groups can be further substituted, the groups may further have a substituent. Examples of the substituent include the groups described above regarding the substituent T.

Specific examples of the group represented by R^{1a} and R^{1b} include an aryl group which has an alkoxy group as a substituent, an aryl group which has a hydroxyl group as a substituent, and an aryl group which has an acyloxy group as a substituent.

In Formula (PP), R² and R³ each independently represent a hydrogen atom or a substituent. Examples of the substituent include the above-described substituent T. It is preferable that at least one of R² or R³ represents an electron-withdrawing group. A substituent having a positive Hammett's substituent constant σ value (sigma value) acts as an electron-withdrawing group. Here, the substituent constant obtained by Hammett's rule includes a σp value and a σm value. The values can be found in many common books. In the present invention, a substituent having the Hammett's substituent constant σ value of 0.2 or more can be exemplified as the electron-withdrawing group. σ value is preferably 0.25 or more, more preferably 0.3 or more, and still more preferably 0.35 or more. The upper limit is not particularly limited, but preferably 0.80 or lower. Specific examples of the electron-withdrawing group include a cyano group (σp value=0.66), a carboxyl group (—COOH: σp value=0.45), an alkoxycarbonyl group (for example, —COOMe: σp value=0.45), an aryloxycarbonyl group (for example, —COOPh: σp value=0.44), a carbamoyl group (for example, —CONH₂: σp value=0.36), an alkylcarbonyl group (for example, —COMe: σp value=0.50), an arylcarbonyl group (for example, —COPh: σp value=0.43), an alkylsulfonyl group (for example, —SO₂Me: σp value=0.72), and an arylsulfonyl group (for example, —SO₂Ph: σp value=0.68). Among these, a cyano group is preferable. Here, Me represents a methyl group, and Ph represents a phenyl group. For example, the Hammett's substituent constant σ value can be found in the description of paragraphs “0017” and “0018” of JP2011-068731A, the content of which is incorporated herein by reference.

In Formula (PP), it is preferable that R² represents an electron-withdrawing group (preferably a cyano group) and R³ represents a heteroaryl group. It is preferable that the heteroaryl group is a 5- or 6-membered ring. In addition, the heteroaryl group is preferably a monocycle or a fused ring, more preferably a monocycle or a fused ring composed of 2 to 8 rings, and still more preferably a monocycle or a fused ring composed of 2 to 4 rings. The number of heteroatoms constituting the heteroaryl group is preferably 1 to 3 and more preferably 1 or 2. Examples of the heteroatom include a nitrogen atom, an oxygen atom, and a sulfur atom. It is preferable that the heteroaryl group has one or more nitrogen atoms. Two R²'s in Formula (PP) may be the same as or different from each other. In addition, two R³'s in Formula (PP) may be the same as or different from each other.

In the Formula (PP), R⁴ represents preferably a hydrogen atom, an alkyl group, an aryl group, a heteroaryl group, or a group represented by —BR^{4A}R^{4B}, more preferably a hydrogen atom, an alkyl group, an aryl group, or a group represented by —BR^{4A}R^{4B}, and still more preferably a group represented by —BR^{4A}R^{4B}. As the substituent represented by R^{4A} and R^{4B}, a halogen atom, an alkyl group, an alkoxy group, an aryl group, or a heteroaryl group is preferable, an alkyl group, an aryl group, or a heteroaryl group is more preferable, and an aryl group is still more preferable. Each of the groups may further have a substituent. Two R⁴'s in Formula (PP) may be the same as or different from each other. R^{4A} and R^{4B} may be bonded to each other to form a ring.

Specific examples of the compound represented by Formula (PP) include the following compounds. In the following structural formulae, Et represents an ethyl group, and Ph represents a phenyl group. In addition, Examples of the pyrrolopyrrole compound include compounds described in paragraphs “0016” to “0058” of JP2009-263614A, compounds described in paragraphs “0037” to “0052” of JP2011-068731A, compounds described in paragraphs “0010” to “0033” of WO2015/166873A, the contents of which are incorporated herein by reference.

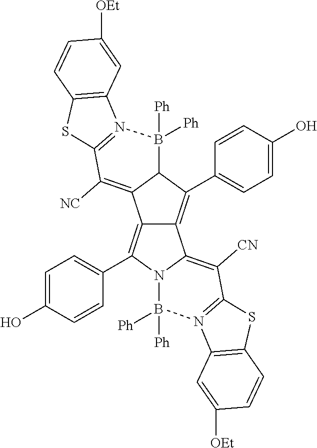

As the squarylium compound, a compound represented by the following Formula (SQ) is preferable.

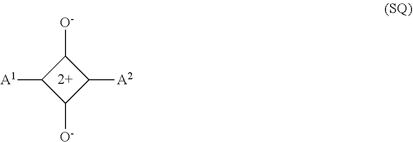

In Formula (SQ), A¹ and A² each independently represent an aryl group, a heteroaryl group, or a group represented by the following Formula (A-1).

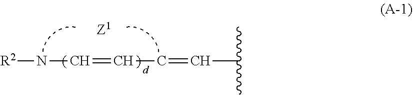

In Formula (A-1), Z¹ represents a non-metal atomic group for forming a nitrogen-containing heterocycle, R² represents an alkyl group, an alkenyl group, or an aralkyl group, d represents 0 or 1, and a wave line represents a direct bond.

The number of carbon atoms in the aryl group represented by A¹ and A² is preferably 6 to 48, more preferably 6 to 24, and still more preferably 6 to 12.

It is preferable that the heteroaryl group represented by A¹ and A² is a 5- or 6-membered ring. In addition, the heteroaryl group is preferably a monocycle or a fused ring composed of 2 to 8 rings, more preferably a monocycle or a fused ring composed of 2 to 4 rings, and still more preferably a monocycle or a fused ring composed of 2 or 3 rings. Examples of a heteroatom constituting the ring of the heteroaryl group include a nitrogen atom, an oxygen atom, and a sulfur atom. Among these, a nitrogen atom or a sulfur atom is preferable. The number of heteroatoms constituting the ring of the heteroaryl group is preferably 1 to 3 and more preferably 1 or 2.

The aryl group and the heteroaryl group may have a substituent. In a case where the aryl group and the heteroaryl group have two or more substituents, the plurality of substituents may be the same as or different from each other.

Examples of the substituent include a halogen atom, a cyano group, a nitro group, an alkyl group, an alkenyl group, an alkynyl group, an aryl group, a heteroaryl group, an aralkyl group, —OR¹⁰, —COR¹¹, —COOR¹², —OCOR¹³, —NR¹⁴R¹⁵, —NHCOR¹⁶, —CONR¹⁷R¹⁸, —NHCONR¹⁹R²⁰, —NHCOOR²¹, —SR²², —SO₂R²³, —SO₂OR²⁴, —NHSO₂R²⁵, and —SO₂NR²⁶R²⁷. R¹⁰ to R²⁷ each independently represent a hydrogen atom, an alkyl group, an alkenyl group, an alkynyl group, an aryl group, a heteroaryl group, or an aralkyl group. In a case where R¹² in —COOR¹² represents a hydrogen atom, the hydrogen atom may be dissociable or may be in the form of a salt. In a case where R²⁴ in —SO₂OR²⁴ represents a hydrogen atom, the hydrogen atom may be dissociable or may be in the form of a salt.

Next, the group represented by Formula (A-1) which is represented by A¹ and A² will be described.

In Formula (A-1), R² represents an alkyl group, an alkenyl group, or an aralkyl group and preferably an alkyl group. In Formula (A-1), the nitrogen-containing heterocycle formed by Z¹ is preferably a 5- or 6-membered ring. In addition, the nitrogen-containing heterocycle is preferably a monocycle or a fused ring composed of 2 to 8 rings, more preferably a monocycle or a fused ring composed of 2 to 4 rings, and still more preferably a fused ring composed of 2 or 3 rings. In addition to a nitrogen atom, the nitrogen-containing heterocycle may include a sulfur atom. In addition, the nitrogen-containing heterocycle may have a substituent. Examples of the substituent include the above-described substituent.

Details of the formula (SQ) can be found in the description of paragraphs “0020” to “0049” of JP2011-208101A, the content of which is incorporated herein by reference.

As shown below, cations in Formula (SQ) are present without being localized.

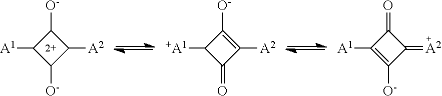

The squarylium compound is preferably a compound represented by the following formula (SQ-1).

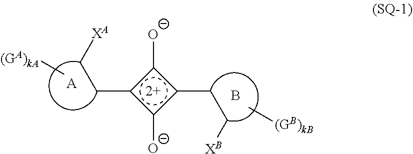

A Ring A and a ring B each independently represent an aromatic ring.

X^{A} and X^{B} each independently represent a substituent.

G^{A} and G^{B} each independently represent a substituent.

kA represents an integer of 0 to n_{A}, and kB represents an integer of 0 to n_{B}.

n_{A} and n_{B} represent integers representing the maximum numbers of G^{A}'s and G^{B}'S which may be substituted in the ring A and the ring B, respectively.

X^{A} and G^{A}, X^{B} and G^{B}, or X^{A} and X^{B} may be bonded to each other to form a ring, and in a case where a plurality of G^{A}'s and a plurality of G^{B}'s are present, G^{A}'s and G^{B}'s may be bonded to each other to form ring structures, respectively.

Examples of a substituent represented by G^{A} and G^{B} include the substituent T described in Formula (PP).

As the substituent represented by X^{A} and X^{B}, a group having active hydrogen is preferable, —OH, —SH, —COOH, —SO₃H, —NR^{X1}R^{X2}, —NHCOR^{X1}, —CONR^{X1}R^{X2}, —NHCONR^{X1}R^{X2}, —NHCOOR^{X1}, —NHSO₂R^{X1}, —B(OH)₂, or —PO(OH)₂ is more preferable, and —OH, —SH, or —NR^{X1}R^{X2} is still more preferable. R^{X1} and R^{X2} each independently represent a hydrogen atom or a substituent. Examples of the substituent X^{A} and X^{B} include an alkyl group, an aryl group, and a heteroaryl group. Among these, an alkyl group is preferable.

The ring A and the ring B each independently represent an aromatic ring. The aromatic ring may be a monocycle or a fused ring. Specific examples of the aromatic ring include a benzene ring, a naphthalene ring, an indene ring, an azulene ring, a heptalene ring, an indacene ring, a perylene ring, a pentacene ring, an acenaphthene ring, a phenanthrene ring, an anthracene ring, a naphthacene ring, a chrysene ring, a triphenylene ring, a fluorene ring, a biphenyl ring, a pyrrole ring, a furan ring, a thiophene ring, an imidazole ring, an oxazole ring, a thiazole ring, a pyridine ring, a pyrazine ring, a pyrimidine ring, a pyridazine ring, an indolizine ring, an indole ring, a benzofuran ring, a benzothiophene ring, an isobenzofuran ring, a quinolizine ring, a quinoline ring, a phthalazine ring, a naphthyridine ring, a quinoxaline ring, a quinoxazoline ring, an isoquinoline ring, a carbazole ring, a phenanthridine ring, an acridine ring, a phenanthroline ring, a thianthrene ring, a chromene ring, a xanthene ring, a phenoxathiin ring, a phenothiazine ring, and a phenazine ring. Among these, a benzene ring or a naphthalene ring is preferable. The aromatic ring may be unsubstituted or may have a substituent. Examples of the substituent include the substituent T described above regarding the Formula (PP).

X^{A} and G^{A}, X^{B} and G^{B}, or X^{A} and X^{B} may be bonded to each other to form a ring, and in a case where a plurality of G^{A}'s and a plurality of G^{B}'s are present, G^{A}'s and G^{B}'s may be bonded to each other to form rings, respectively. It is preferable that the ring is a 5- or 6-membered ring. The ring may be a monocycle or a fused ring. In a case where X^{A} and G^{A}, X^{B} and G^{B}, X^{A} and X^{B}, GA's, or G^{B}'s are bonded to each other to form a ring, the groups may be directly bonded to each other to form a ring, or may be bonded to each other through a divalent linking group selected from an alkylene group, —CO—, —O—, —NH—, —BR—, or a combination thereof to form a ring. R represents a hydrogen atom or a substituent. Examples of the substituent include the substituent T described above regarding Formula (PP). Among these, an alkyl group or an aryl group is preferable.

kA represents an integer of 0 to n_{A}, kB represents an integer of 0 to n_{B}, n_{A} represents an integer representing the maximum number of G^{A}'s which may be substituted in the ring A, and n_{B} represents an integer representing the maximum number of G^{B}'s which may be substituted in the ring B. kA and kB each independently represent preferably an integer of 0 to 4, more preferably 0 to 2, and still more preferably 0 or 1.

Specific examples of the squarylium compound include the following compounds. In addition, examples of the squarylium compound include a compound described in paragraphs “0044” to “0049” of JP2011-208101A, a compound described in paragraphs “0060” and “0061” of JP6065169B, a compound described in paragraph “0040” of WO2016/181987A, a compound described in WO2013/133099A, a compound described in WO2014/088063A, a compound described in JP2014-126642A, a compound described in JP2016-146619A, a compound described in JP2015-176046A, a compound described in JP2017-025311A, a compound described in WO2016/154782A, a compound described in JP5884953B, a compound described in JP6036689B, a compound described in JP5810604B, and a compound described in JP2017-068120A, the contents of which are incorporated herein by reference.

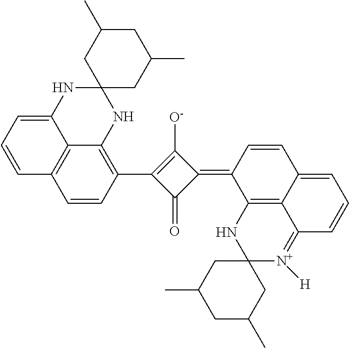 [SMILES: CC1CC(C)CC2(C1)Nc1cccc3ccc(C4=C([O-])/C(=c5\ccc6cccc7c6c5NC5(CC(C)CC(C)C5)[NH+]=7)C4=O)c(c13)N2]

As the cyanine compound, a compound represented by Formula (C) is preferable. Formula (C)

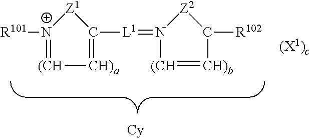

In the formula, Z¹ and Z² each independently represent a non-metal atomic group for forming a 5- or 6-membered nitrogen-containing heterocycle which may be fused,

R¹⁰¹ and R¹⁰² each independently represent an alkyl group, an alkenyl group, an alkynyl group, or an aryl group,

L¹ represents a methine chain including an odd number of methine groups,

a and b each independently represent 0 or 1,

in a case where a represents 0, a carbon atom and a nitrogen atom are bonded through a double bond. In a case where b represents 0, a carbon atom and a nitrogen atom are bonded through a single bond, and

in a case where a site represented by Cy in the formula is a cation site, X¹ represents an anion, and c represents the number of X¹'s for balancing charge. In a case where a site represented by Cy in the formula is an anion site, X¹ represents a cation, and c represents the number of X¹'s for balancing charge. In a case where charge of a site represented by Cy in the formula is neutralized in a molecule, c represents 0.

Specific examples of the cyanine compound include a compound described in paragraphs “0044” and “0045” of JP2009-108267A, a compound described in paragraphs “0026” to “0030” of JP2002-194040, a compound described in JP2015-172004A, a compound described in JP2015-172102A, a compound described in JP2008-088426A, and a compound described in JP 2017-031394A, the contents of which are incorporated herein by reference.

In the present invention, as the near infrared absorbing colorant, a commercially available product can also be used. Examples of the commercially available product include SDO-C33 (manufactured by Arimoto Chemical Co., Ltd.); EXCOLOR IR-14, EXCOLOR IR-10A, EXCOLOR TX-EX-801B, and EXCOLOR TX-EX-805K (manufactured by Nippon Shokubai Co., Ltd.); Shigenox NIA-8041, Shigenox NIA-8042, Shigenox NIA-814, Shigenox NIA-820, Shigenox NIA-839 (manufactured by Hakkol Chemical Co., Ltd.); Epolite V-63, Epolight 3801, and Epolight 3036 (manufactured by Epolin Inc.); PRO-JET 825LDI (manufactured by Fujifilm Corporation); NK-3027, NK-5060, and SMP-388 (manufactured by Hayashibara Co., Ltd.); and YKR-3070 (manufactured by Mitsui Chemicals, Inc.).

The content of the near infrared absorbing colorant is preferably 1% to 30% by mass with respect to the total solid content of the composition according to the embodiment of the present invention. The upper limit is preferably 20% by mass or less, and more preferably 10% by mass or less. The lower limit is preferably 3% by mass or more and more preferably 5% by mass or more.

The content of the near infrared absorbing colorant is preferably 5 to 200 parts by mass with respect to 100 parts by mass of the color material that blocks visible light. The upper limit is preferably 100 parts by mass or less and more preferably 50 parts by mass or less. The lower limit is preferably 10 parts by mass or more and more preferably 15 parts by mass or more. In a case where the ratio between the near infrared absorbing colorant and the color material that blocks visible light is in the above-described range, a film in which a maximum value of a refractive index is present in a wavelength range of 800 nm or longer and the value of the refractive index at the maximum value is higher can be formed.

The total content of the near infrared absorbing colorant and the color material that blocks visible light is preferably 10% to 70% by mass with respect to the total solid content of the composition according to the embodiment of the present invention. The lower limit is preferably 20% by mass or more and more preferably 25% by mass or more.

In the composition according to the embodiment of the present invention, one infrared absorber may be used alone, or two or more infrared absorbing colorants may be used in combination. In a case where two or more near infrared absorbing colorants are used in combination, it is preferable that the total content of the near infrared absorbing colorant is in the above-described range.

<<Curable Compound>>

The composition according to the embodiment of the present invention includes a curable compound. Examples of the curable compound include a polymerizable compound and a resin. The resin may be a non-polymerizable resin (resin not having a polymerizable group) or a polymerizable resin (resin having a polymerizable group). Examples of the polymerizable group include a group having an ethylenically unsaturated bond, an epoxy group, a methylol group, and an alkoxymethyl group. Examples of the group having an ethylenically unsaturated bond include a vinyl group, a (meth)allyl group, and a (meth)acryloyl group. The polymerizable resin (resin having a polymerizable group) may be a polymerizable compound.

In the present invention, it is preferable that a compound including at least a resin is used as the curable compound, it is more preferable that a resin and a monomer type polymerizable compound are used as the curable compound, and it is still more preferable that a resin and a monomer type polymerizable compound which has a group having an ethylenically unsaturated bond are used as the curable compound.

In addition, in the present invention, it is preferable that a compound having at least one selected from a fluorene skeleton or a triazine skeleton is used as the curable compound. By using the compound having the above-described skeleton, a film having a high refractive index can be formed. The above-described compound may be a monomer type compound or a polymer type compound. In addition, the above-described compound may be a compound having only either one of a fluorene skeleton or a triazine skeleton in one molecule or a compound having both a fluorene skeleton and a triazine skeleton in one molecule.

Examples of the curable compound having a fluorene skeleton include a compound having a partial structure represented by the following Formula.

### (Fr)

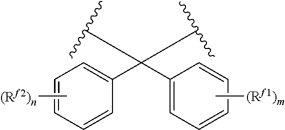

In the formula, a wave line represents a direct bond, R^{f1} and R^{f2} each independently represent a substituent, and m and n each independently represent an integer of 0 to 5. In a case where m represents 2 or more, m R^{f1}'s may be the same as or different from each other, or two R^{f1}'s among m R^{f1}'s may be bonded to each other to form a ring. In a case where n represents 2 or more, n R^{f2}'s may be the same as or different from each other, or two R^{f2}'s among n R^{f2}'s may be bonded to each other to form a ring. Examples of the substituent represented by R^{f1} and R^{f2} include the groups described above regarding the substituent T.

Examples of the curable compound having a triazine skeleton include a compound having a partial structure represented by the following Formula (Ta). In the formula, a wave line represents a direct bond.

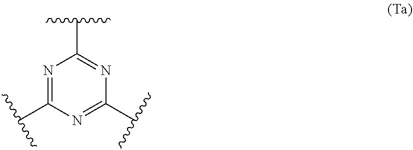 [SMILES: *c1nc(*)nc(*)n1]

As the curable compound having a triazine skeleton, a compound having a group represented by the following Formula (Ta-1) is also preferable.

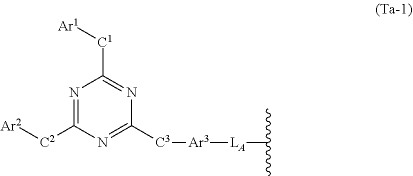

In the formula, a wave line represents a direct bond.

C¹ to C³ each independently represent —NR_{N}—, —O—, or —S—. R_{N} represents a hydrogen atom, an alkyl group (preferably having 1 to 7 carbon atoms), or an aryl group. C¹ to C³ each independently represent preferably —NH—, —N(CH₃)—, —O—, or —S—, and more preferably —NH—.

Ar¹ and Ar² each independently represent an aryl group or a heterocyclic group. As the aryl group, a phenyl group is preferable. The heterocyclic group may be aromatic or non-aromatic but is preferably aromatic. The number of heteroatoms constituting the heterocycle is preferably 1 to 3. It is preferable that the heteroatoms constituting the heterocycle are a nitrogen atom, an oxygen atom, or a sulfur atom. The aryl group and the heterocyclic group may have a substituent. Examples of the substituent include the groups described above regarding the substituent T and a polymerizable group. Preferable examples of the polymerizable group include a vinyl group, a (meth)allyl group, and a (meth)acryloyl group.

Ar3 represents an arylene group or a divalent heterocyclic group. As the arylene group, a phenylene group is preferable.

L_{A} represents a single bond or a divalent linking group. As the divalent linking group, —NH—, —O—, —CO—, —CO—O—, an alkylene group (preferably having 1 to 3 carbon atoms), or a group including a combination thereof (for example, —O-alkylene group-) is preferable.

Preferable examples of the curable compound having a triazine skeleton include a compound represented by the following Formula (I).

(A)ₘ-X-(B)ₙ (I)

In Formula (I), m represents an integer 2 or more. n represents an integer of 0 or more.

A represents a group represented by Formula (Ta-1).

X represents a (m+n)-valent linking group.

B represents a polymer chain or a substituent.

A plurality of A's may be the same as or different from each other. In a case where a plurality of B's is present, B's may be the same as or different from each other.

The (m+n)-valent linking group represented by X is not particularly limited, and examples thereof include a group (in which a ring structure may be formed) including the following structural unit or a combination of two or more of the structural units.

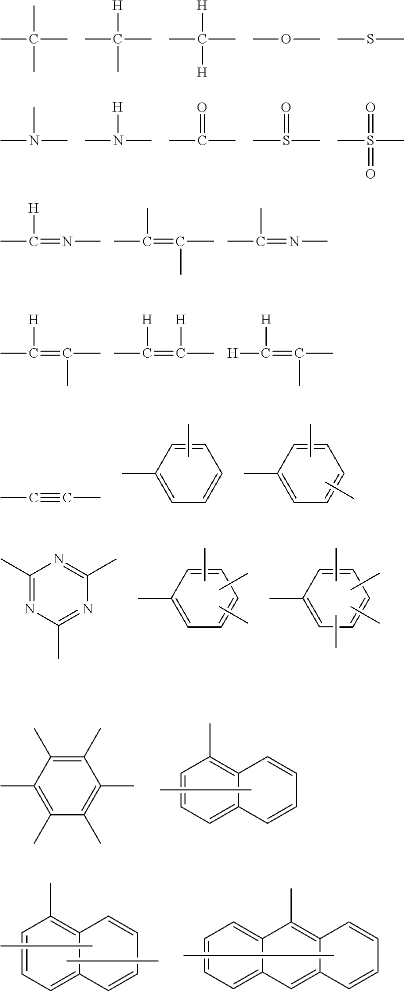

The polymer chain represented by B is a chain including a plurality of predetermined repeating units. The structure of the polymer chain is not particularly limited and can be selected from well-known polymer depending on the purpose and the like. In particular, as the polymer chain, a polymer chain formed of a polymer selected from the group consisting of a polymer or copolymer of a vinyl monomer, an ester polymer, an ether polymer, a urethane polymer, an amide polymer, an epoxy polymer; and a silicone polymer is preferable, and a polymer chain formed of a polymer or copolymer of a (meth)acrylic compound is more preferable. The polymer chain may have a substituent. In a case where a plurality of substituents is present, the substituents may be the same as or different from each other. The weight-average molecular weight of the polymer chain represented by B is preferably 200 to 10,000 and more preferably 300 to 5,000. Examples of the substituent represented by B include the groups described above regarding the substituent T.

As the curable compound having a triazine skeleton, a compound represented by the following Formula (Ta-10) is also preferable.

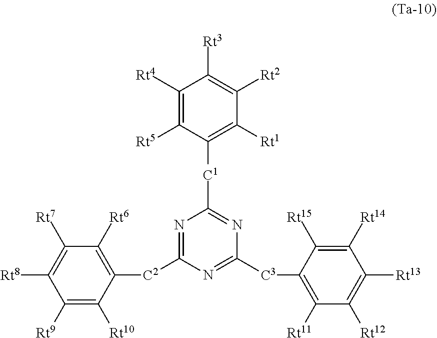

C¹ to C³ each independently represent —NR_{N}—, —O—, or —S—. R_{N} represents a hydrogen atom, an alkyl group (preferably having 1 to 7 carbon atoms), or an aryl group. C¹ to C³ each independently represent preferably —NH—, —N(CH₃)—, —O—, or —S—, and more preferably —NH—.

Rt¹ to Rt¹⁵ each independently represent a hydrogen atom or a substituent, and at least one of Rt¹ to Rt¹⁵ represents a polymerizable group. Examples of the substituent include the groups described above regarding the substituent T and a polymerizable group. Preferable examples of the polymerizable group include a vinyl group, a (meth) allyl group, and a (meth) acryloyl group.

It is preferable that at least one of Rt¹ to Rt⁵ and at least one of Rt⁶ to Rt¹⁰ each independently represent a polymerizable group, and it is more preferable that one of Rt¹ to Rt⁵ and one of Rt⁶ to Rt¹⁰ each independently represent a polymerizable group.

In the composition according to the embodiment of the present invention, the content of the curable compound is preferably 0.1% to 80% by mass with respect to the total solid content of the composition according to the embodiment of the present invention. The lower limit is preferably 0.5% by mass or more, more preferably 1% by mass or more, and still more preferably 5% by mass or more. The upper limit is preferably 70% by mass or less, more preferably 60% by mass or less, still more preferably 50% by mass or less, still more preferably 40% by mass or less, and still most preferably 30% by mass or less. As the curable compound, one kind may be used alone, or two or more kinds may be used. In a case where two or more curable compounds are used, it is preferable that the total content is in the above-described range.

(Polymerizable Compound)

Examples of the polymerizable compound include a compound which has a group having an ethylenically unsaturated bond, a compound having an epoxy group, a compound having a methylol group, and a compound having an alkoxymethyl group. The polymerizable compound may be a monomer or a resin. The monomer type polymerizable compound that has a group having an ethylenically unsaturated bond can be preferably used as a radically polymerizable compound. In addition, the compound having an epoxy group, the compound having a methylol group, and the compound having an alkoxymethyl group can be preferably used as a cationically polymerizable compound.

The molecular weight of the monomer type polymerizable compound is preferably lower than 2,000, more preferably 100 or higher and lower than 2,000, and still more preferably 200 or higher and lower than 2,000. The upper limit is, for example, preferably 1,500 or lower. The weight-average molecular weight (Mw) of the resin type polymerizable compound is preferably 2,000 to 2,000,000. The upper limit is preferably 1,000,000 or less and more preferably 500,000 or less. The lower limit is preferably 3,000 or more, and more preferably 5,000 or more.

Examples of the resin type polymerizable compound include an epoxy resin and a resin which includes a repeating unit having a polymerizable group. Examples of the repeating unit having a polymerizable group include the following (A2-1) to (A2-4).

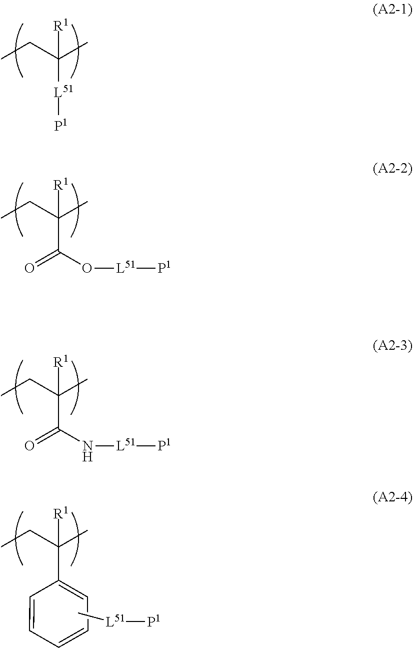

R¹ represents a hydrogen atom or an alkyl group. The number of carbon atoms in the alkyl group is preferably 1 to 5, more preferably 1 to 3, and still more preferably 1. It is preferable that R¹ represents a hydrogen atom or a methyl group.

L⁵¹ represents a single bond or a divalent linking group. Examples of the divalent linking group include an alkylene group, an arylene group, —O—, —S—, —CO—, —COO—, —OCO—, —SO₂—, —NR¹⁰— (R¹⁰ represents a hydrogen atom or an alkyl group and preferably a hydrogen atom), and a group including a combination thereof. The number of carbon atoms in the alkylene group is preferably 1 to 30, more preferably 1 to 15, and still more preferably 1 to 10. The alkylene group may have a substituent but is preferably unsubstituted. The alkylene group may be linear, branched, or cyclic. In addition, the cyclic alkylene group may be monocyclic or polycyclic. The number of carbon atoms in the arylene group is preferably 6 to 18, more preferably 6 to 14, and still more preferably 6 to 10.

P¹ represents a polymerizable group. Examples of the polymerizable group include a group having an ethylenically unsaturated bond, an epoxy group, a methylol group, and an alkoxymethyl group.

The compound which has a group having an ethylenically unsaturated bond is preferably a (meth)acrylate compound having trifunctional to pentadecafunctional and more preferably a (meth)acrylate compound having trifunctional to hexafunctional. Examples of the compound which includes a group having an ethylenically unsaturated bond can be found in paragraphs “0033” and “0034” of JP2013-253224A, the content of which is incorporated herein by reference. As compounds having the group having an ethylenically unsaturated bond, ethyleneoxy-modified pentaerythritoltetraacrylate (as a commercially available product, NK ESTER ATM-35E manufactured by Shin-Nakamura Chemical Co., Ltd.), dipentaerythritoltriacrylate (as a commercially available product, KAYARAD D-330 manufactured by Nippon Kayaku Co., Ltd.), dipentaerythritoltetraacrylate (as a commercially available product, KAYARAD D-320 manufactured by Nippon Kayaku Co., Ltd.), dipentaerythritolpenta(meth)acrylate (as a commercially available product, KAYARAD D-310 manufactured by Nippon Kayaku Co., Ltd.), dipentaerythritolhexa(meth)acrylate (as a commercially available product, KAYARAD DPHA manufactured by Nippon Kayaku Co., Ltd., A-DPH-12E, manufactured by Shin-Nakamura Chemical Co., Ltd.), or compounds having a structure in which the (meth)acryloyl group is bonded through an ethylene glycol residue and/or a propylene glycol residue is preferable. In addition, oligomers of the above-described examples can be used. For example, the details of the polymerizable compound can be found in paragraphs “0034” to “0038” of JP2013-253224A, the content of which is incorporated herein by reference. Examples of the compound having an ethylenically unsaturated bond include a polymerizable monomer in paragraph “0477” of JP2012-208494A (corresponding to paragraph “0585” of US2012/0235099A), the contents of which are incorporated herein by reference. In addition, diglycerin ethylene oxide (EO)-modified (meth)acrylate (as a commercially available product, M-460 manufactured by Toagosei Co., Ltd.), pentaerythritoltetraacrylate (A-TMMT manufactured by Shin-Nakamura Chemical Co., Ltd.), or 1,6-hexanediol diacrylate (KAYARAD HDDA manufactured by Nippon Kayaku Co., Ltd.) is also preferable. Oligomers of the above-described examples can be used. For example, RP-1040 (manufactured by Nippon Kayaku Co., Ltd.) is used. In addition, ARONIX M-350 or TO-2349 (manufactured by Toagosei Co., Ltd.) can also be used.

The compound which includes a group having an ethylenically unsaturated bond may further have an acid group such as a carboxyl group, a sulfo group, or a phosphate group. Examples of a commercially available product include ARONIX series (for example, M-305, M-510, or M-520, manufactured by Toagosei Co., Ltd.).

In addition, a compound having a caprolactone structure is also preferable as the compound which includes a group having an ethylenically unsaturated bond. Examples of the compound having a caprolactone structure can be found in paragraphs “0042” to “0045” of JP2013-253224A, the content of which is incorporated herein by reference. As the compound having a caprolactone structure, for example, KAYARAD DPCA series (manufactured by Nippon Kayaku Co., Ltd.) is commercially available, and examples thereof include DPCA-20, DPCA-30, DPCA-60, and DPCA-120.

As the compound which has a group having an ethylenically unsaturated bond, a compound which has a group having an ethylenically unsaturated bond and an alkyleneoxy group can also be used. As the compound which has a group having an ethylenically unsaturated bond and an alkyleneoxy group, a compound which has a group having an ethylenically unsaturated bond, an ethyleneoxy group, and/or a propyleneoxy group is preferable, a compound which has a group having an ethylenically unsaturated bond and an ethyleneoxy group is more preferable, and a trifunctional to hexafunctional (meth)acrylate compound having 4 to 20 ethyleneoxy groups is still more preferable. Examples of a commercially available product of the compound which has a group having an ethylenically unsaturated bond and an alkyleneoxy group include SR-494 (manufactured by Sartomer) which is a tetrafunctional (meth)acrylate having four ethyleneoxy groups, and KAYARAD TPA-330 (manufactured by Nippon Kayaku Co., Ltd.) which is a trifunctional (meth)acrylate having three isobutyleneoxy groups.

It is preferable that a compound having at least one selected from a fluorene skeleton or a triazine skeleton is used as the compound that includes a group having an ethylenically unsaturated bond. By using the compound having this skeleton, the refractive index of the obtained film can be further increased. Examples of the compound that includes a group having an ethylenically unsaturated bond and a triazine skeleton include the above-described compound having a partial structure represented by Formula (Ta). Examples of the compound that includes a group having an ethylenically unsaturated bond and a fluorene skeleton include the above-described compound having a partial structure represented by Formula (Fr). In addition, the details of the compound that includes a group having an ethylenically unsaturated bond and a fluorene skeleton can be found in JP2017-048367A, the content of which is incorporated herein by reference. In addition, examples of a commercially available product of the compound that includes a group having an ethylenically unsaturated bond and a fluorene skeleton include OGSOL EA-0300 (manufactured by Osaka Gas Chemicals Co., Ltd., a (meth)acrylate monomer having a fluorene skeleton).

As the compound having the group having an ethylenically unsaturated bond, a urethane acrylate described in JP1973-041708B (JP-S48-041708B), JP1976-037193A (JP-S51-037193A), JP1990-032293B (JP-H2-032293B), or JP1990-016765B (JP-H2-016765B), or a urethane compound having an ethylene oxide skeleton described in JP1983-049860B (JP-S58-049860B), JP1981-017654B (JP-S56-017654B), JP1987-039417B (JP-S62-039417B), or JP1987-039418B (JP-S62-039418B) is also preferable. In addition, an addition-polymerizable compound having an amino structure or a sulfide structure in the molecules described in JP1988-277653A (JP-S63-277653A), JP1988-260909A (JP-S63-260909A), or JP1989-105238A (JP-H1-105238A) can be used. Examples of a commercially available product of the polymerizable compound include UA-7200 (manufactured by Shin-Nakamura Chemical Co., Ltd.), DPHA-40H (manufactured by Nippon Kayaku Co., Ltd.), and UA-306H, UA-306T, UA-3061, AH-600, T-600 and AI-600 (manufactured by Kyoeisha Chemical Co., Ltd.).

In addition, as the compound that includes a group having an ethylenically unsaturated bond, a compound described in JP6057891B can also be used.

In addition, as the compound having the group having an ethylenically unsaturated bond, for example, 8UH-1006 or 8UH-1012 (manufactured by Taisei Fine Chemical Co., Ltd.) or LIGHT ACRYLATE POB-AO (manufactured by Kyoeisha Chemical Co., Ltd.) is also preferably used.

In a case where the composition according to the embodiment of the present invention includes the compound which includes a group having an ethylenically unsaturated bond, the content of the compound which includes a group having an ethylenically unsaturated bond is preferably 0.1% by mass or higher, more preferably 0.5% by mass or higher, still more preferably 1% by mass or higher, and still more preferably 5% by mass or higher with respect to the total solid content of the composition. The upper limit is preferably 80% by mass or lower, more preferably 70% by mass or lower, still more preferably 60% by mass or lower, still more preferably 50% by mass or lower, still more preferably 40% by mass or lower, and still more preferably 30% by mass or lower.

Examples of the compound having an epoxy group (hereinafter, also referred to as “epoxy compound”) include a monofunctional or polyfunctional glycidyl ether compound, and a polyfunctional aliphatic glycidyl ether compound. In addition, as the epoxy compound, a compound having an alicyclic epoxy group can also be used.

Examples of the epoxy compound include a compound having one or more epoxy groups in one molecule. It is preferable that the epoxy compound is a compound having 1 to 100 epoxy groups in one molecule. The upper limit of the number of epoxy groups is, for example, 10 or lower or 5 or lower. The lower limit of the number of epoxy groups is preferably 2 or more.

The epoxy compound may be a low molecular weight compound (for example, molecular weight: less than 1,000) or a high molecular weight compound (macromolecule; for example, molecular weight: 1,000 or more, and in the case of a polymer, weight-average molecular weight: 1,000 or more). The weight-average molecular weight of the epoxy compound is preferably 2,000 to 100,000. The upper limit of the weight-average molecular weight is preferably 10,000 or less, more preferably 5,000 or less, and still more preferably 3,000 or less.

Examples of a commercially available product of the epoxy compound include EHPE 3150 (manufactured by Daicel Corporation), EPICLON N-695 (manufactured by DIC Corporation), ADEKA GLYCILOL ED-505 (manufactured by ADEKA CORPORATION, an epoxy group-containing monomer), and MARPROOF G-0150M, G-0105SA, G-0130SP, G-0250SP, G-1005S, G-1005SA, G-1010S, G-2050M, G-01100, or G-01758 (manufactured by NOF Corporation, an epoxy group-containing polymer). As the epoxy compound, compounds described in paragraphs “0034” to “0036” of JP2013-011869A, paragraphs “0147” to “0156” of JP2014-043556A, and paragraphs “0085” to “0092” of JP2014-089408A can also be used. The contents of this specification are incorporated herein by reference.

In a case where the composition according to the embodiment of the present invention includes the epoxy compound, the content of the epoxy compound is preferably 0.1% by mass or higher, more preferably 0.5% by mass or higher, still more preferably 1% by mass or higher, and still more preferably 5% by mass or higher with respect to the total solid content of the composition. The upper limit is preferably 80% by mass or lower, more preferably 70% by mass or lower, still more preferably 60% by mass or lower, still more preferably 50% by mass or lower, still more preferably 40% by mass or lower, and still more preferably 30% by mass or lower.

Examples of the compound having a methylol group (hereinafter, also referred to as “methylol compound”) include a compound in which a methylol group is bonded to a nitrogen atom or a carbon atom which forms an aromatic ring. In addition, examples of the compound having an alkoxymethyl group (hereinafter, also referred to as “alkoxymethyl compound”) include a compound in which an alkoxymethyl group is bonded to a nitrogen atom or a carbon atom which forms an aromatic ring. As the compound in which an alkoxymethyl group or a methylol group is bonded to a nitrogen atom, for example, alkoxy methylated melamine, methylolated melamine, alkoxy methylated benzoguanamine, methylolated benzoguanamine, alkoxy methylated glycoluril, methylolated glycoluril, alkoxy methylated urea, or methylolated urea is preferable. In addition, the details can be found in paragraphs “0134” to “0147” of JP2004-295116A or paragraphs “0095” to “0126” of JP2014-089408A, the contents of which are incorporated herein by reference.

In a case where the composition according to the embodiment of the present invention includes the methylol compound, the content of the methylol compound is preferably 0.1% by mass or higher, more preferably 0.5% by mass or higher, still more preferably 1% by mass or higher, and still more preferably 5% by mass or higher with respect to the total solid content of the composition. The upper limit is preferably 80% by mass or lower, more preferably 70% by mass or lower, still more preferably 60% by mass or lower, still more preferably 50% by mass or lower, still more preferably 40% by mass or lower, and still more preferably 30% by mass or lower.

In a case where the composition according to the embodiment of the present invention includes the alkoxymethyl compound, the content of the alkoxymethyl compound is preferably 0.1% by mass or higher, more preferably 0.5% by mass or higher, still more preferably 1% by mass or higher, and still more preferably 5% by mass or higher with respect to the total solid content of the composition. The upper limit is preferably 80% by mass or lower, more preferably 70% by mass or lower, still more preferably 60% by mass or lower, still more preferably 50% by mass or lower, still more preferably 40% by mass or lower, and still more preferably 30% by mass or lower.

(Resin)

The composition according to the embodiment of the present invention may include a resin as the curable compound. It is preferable that the curable compound includes at least a resin. The resin can also be used as a dispersant. The resin which is used to disperse the pigments and the like will also be called a dispersant. However, the above-described uses of the resin are merely exemplary, and the resin can be used for purposes other than the uses. The resin having a polymerizable group also corresponds to the polymerizable compound.

The weight-average molecular weight (Mw) of the resin is preferably 2,000 to 2,000,000. The upper limit is preferably 1,000,000 or less and more preferably 500,000 or less. The lower limit is preferably 3,000 or more and more preferably 5,000 or more.

Examples of the resin include a (meth)acrylic resin, an epoxy resin, an enethiol resin, a polycarbonate resin, a polyether resin, a polyarylate resin, a polysulfone resin, a polyethersulfone resin, a polyphenylene resin, a polyarylene ether phosphine oxide resin, a polyimide resin, a polyamide imide resin, a polyolefin resin, a cyclic olefin resin, a polyester resin, and a styrene resin. Examples of the epoxy resin include the polymer type compounds among the compounds described above as the examples of the epoxy compound regarding the polymerizable compound. Examples of a commercially available product of the cyclic olefin resin include ARTON F4520 (manufactured by JSR Corporation). In addition, a resin described in Examples of WO02016/088645A, a resin described in JP2017-057265A, a resin described in JP2017-032685A, a resin described in JP2017-075248A, or a resin described in JP2017-066240A can also be used, the contents of which are incorporated herein by reference.

In the present invention, a resin having at least one skeleton selected from a fluorene skeleton or a triazine skeleton can be preferably used. The fluorene skeleton and the triazine skeleton may be included in a main chain of a repeating unit or may be included in a side chain. By using the resin having this skeleton, the refractive index of the obtained film can be further increased. Examples of the resin having a triazine skeleton include the above-described resin having a partial structure represented by Formula (Ta). Examples of the resin having a fluorene skeleton include the above-described resin having a partial structure represented by Formula (Fr). Specific examples of the resin having a fluorene skeleton include a resin having the following structure. In the following structural formula, A represents a residue of a carboxylic dianhydride selected from pyromellitic dianhydride, benzophenone tetracarboxylic dianhydride, biphenyl tetracarboxylic dianhydride, or diphenyl ether tetracarboxylic dianhydride, and M represents a phenyl group or a benzyl group. The details of the resin having a fluorene skeleton can be found in US2017/0102610A and JP6031807B the content of which is incorporated herein by reference. In addition, specific examples of the resin having the triazine skeleton include a resin having the following structure. As a resin having a triazine skeleton. Examples of the resin having a triazine skeleton include a resin described in paragraphs “0013” to “0032” of JP2017-133035A.

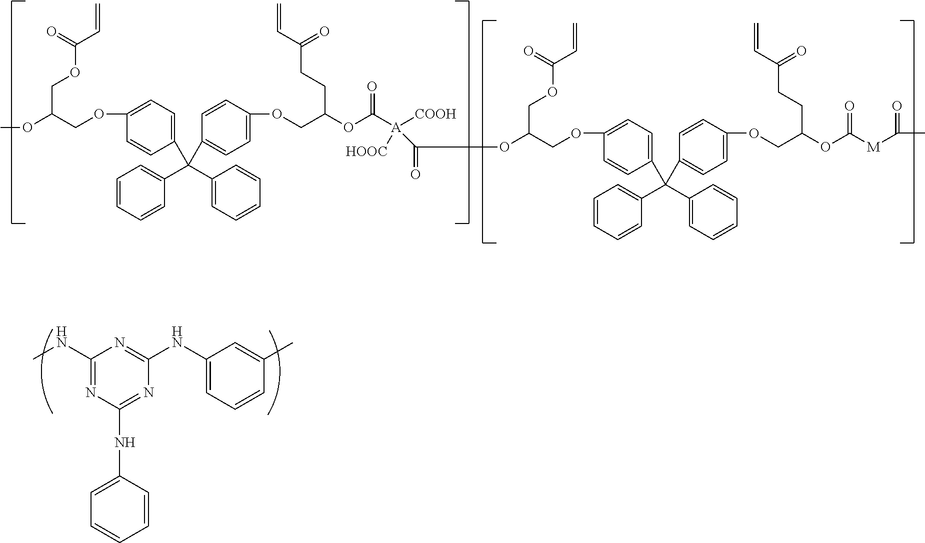

In the present invention a resin having a carbazole skeleton at a side chain can also be preferably used. By using the above-described resin, the refractive index of the obtained film can be further increased. Examples of the resin having a carbazole skeleton at a side chain include a resin having the following structure.

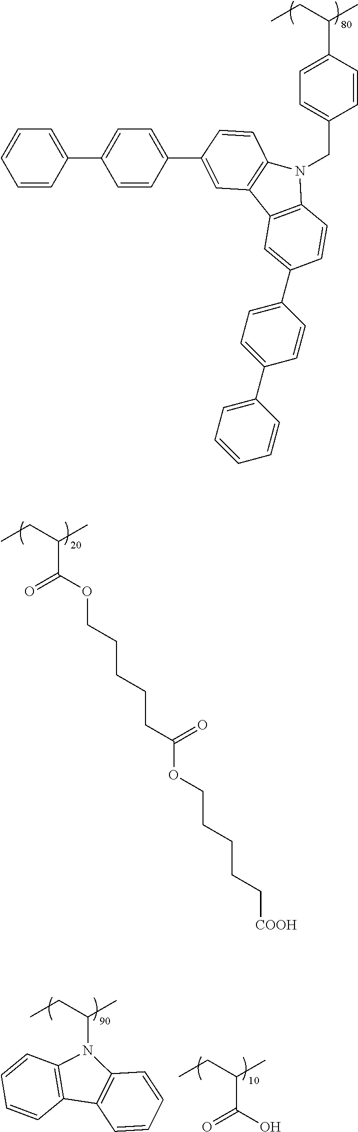

The resin used in the present invention may have an acid group. Examples of the acid group include a carboxyl group, a phosphate group, a sulfo group, and a phenolic hydroxy group. Among these, a carboxyl group is preferable. These acid groups, one kind may be used alone, or two or more kinds may be used in combination. The resin having an acid group can be used as an alkali-soluble resin.

As the resin having an acid group, a polymer having a carboxyl group at a side chain is preferable. Specific examples of the resin include an alkali-soluble phenol resin such as a methacrylic acid copolymer, an acrylic acid copolymer, an itaconic acid copolymer, a crotonic acid copolymer, a maleic acid copolymer, a partially esterified maleic acid copolymer, or a novolac resin, an acidic cellulose derivative having a carboxyl group at a side chain thereof, and a resin obtained by adding an acid anhydride to a polymer having a hydroxy group. In particular, a copolymer of (meth)acrylic acid and another monomer which is copolymerizable with the (meth)acrylic acid is preferable as the alkali-soluble resin. Examples of the monomer which is copolymerizable with the (meth)acrylic acid include an alkyl (meth)acrylate, an aryl (meth)acrylate, and a vinyl compound. Examples of the alkyl (meth)acrylate and the aryl (meth)acrylate include methyl (meth)acrylate, ethyl (meth)acrylate, propyl (meth)acrylate, butyl (meth)acrylate, isobutyl (meth)acrylate, pentyl (meth)acrylate, hexyl (meth)acrylate, octyl (meth)acrylate, phenyl (meth)acrylate, benzyl (meth)acrylate, tolyl (meth)acrylate, naphthyl (meth)acrylate, and cyclohexyl (meth)acrylate. Examples of the vinyl compound include styrene, α-methylstyrene, vinyl toluene, glycidyl methacrylate, acrylonitrile, vinyl acetate, N-vinylpyrrolidone, tetrahydrofurfuryl methacrylate, a polystyrene macromonomer, and a polymethyl methacrylate macromonomer. Examples of other monomers include a N-position-substituted maleimide monomer described in JP 1998-300922A (JP-H10-300922A) such as N-phenylmaleimide or N-cyclohexylmaleimide. Among these monomers which are copolymerizable with the (meth)acrylic acid, one kind may be used alone, or two or more kinds may be used in combination.

The resin having an acid group may further include a repeating unit having a polymerizable group. In a case where the resin having an acid group further includes the repeating unit having a polymerizable group, the content of the repeating unit having a polymerizable group is preferably 10 to 90 mol %, more preferably 20 to 90 mol %, and still more preferably 20 to 85 mol % with respect to all the repeating units. In addition, the content of the repeating unit having an acid group is preferably 1 to 50 mol %, more preferably 5 to 40 mol %, and still more preferably 5 to 30 mol % with respect to all the repeating units.

As the resin having an acid group, a copolymer including benzyl (meth)acrylate and (meth)acrylic acid; a copolymer including benzyl (meth)acrylate, (meth)acrylic acid, and 2-hydroxyethyl (meth)acrylate; or a multi-component copolymer including benzyl (meth)acrylate, (meth)acrylic acid, and another monomer can be preferably used. In addition, copolymers described in JP1995-140654A (JP-H7-140654A) obtained by copolymerization of 2-hydroxyethyl (meth)acrylate can be preferably used, and examples thereof include: a copolymer including 2-hydroxypropyl (meth)acrylate, a polystyrene macromonomer, benzyl methacrylate, and methacrylic acid; a copolymer including 2-hydroxy-3-phenoxypropyl acrylate, a polymethyl methacrylate macromonomer, benzyl methacrylate, and methacrylic acid; a copolymer including 2-hydroxyethyl methacrylate, a polystyrene macromonomer, methyl methacrylate, and methacrylic acid; or a copolymer including 2-hydroxyethyl methacrylate, a polystyrene macromonomer, benzyl methacrylate, and methacrylic acid.

As the resin having an acid group, a polymer obtained by polymerization of monomer components including a compound represented by the following Formula (ED1) and/or a compound represented by the following Formula (ED2) (hereinafter, these compounds will also be referred to as “ether dimer”) is also preferable.

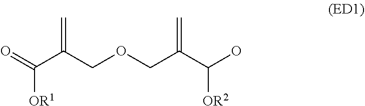

In Formula (ED1), R¹ and R² each independently represent a hydrogen atom or a hydrocarbon group having 1 to 25 carbon atoms which may have a substituent.

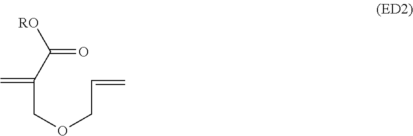

In Formula (ED2), R represents a hydrogen atom or an organic group having 1 to 30 carbon atoms. Specific examples of the compound represented by the formula (ED2) can be found in the description of JP2010-168539A.

Specific examples of the ether dimer can be found in paragraph “0317” of JP2013-029760A, the content of which is incorporated herein by reference. Among these ether dimers, one kind may be used alone, or two or more kinds may be used in combination.

The resin having an acid group may include a repeating unit which is derived from a compound represented by the following Formula (X).

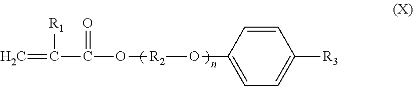

In Formula (X), R¹ represents a hydrogen atom or a methyl group, R² represents an alkylene group having 2 to 10 carbon atoms, and R³ represents a hydrogen atom or an alkyl group having 1 to 20 carbon atoms which may have a benzene ring. n represents an integer of 1 to 15.

The details of the resin having an acid group can be found in paragraphs “0558” to “0571” of JP2012-208494A (corresponding to paragraphs “0685” to “0700” of US2012/0235099A) and paragraphs “0076” to “0099” of JP2012-198408A, the contents of which are incorporated herein by reference. In addition, as the resin having an acid group, a commercially available product may also be used. Examples of the commercially available product include ACRYBASE FF-426 (manufactured by Fujikura Kasei Co., Ltd.).

The acid value of the resin having an acid group is preferably 30 to 200 mgKOH/g. The lower limit is preferably 50 mgKOH/g or more and more preferably 70 mgKOH/g or more. The upper limit is preferably 150 mgKOH/g or less and more preferably 120 mgKOH/g or less.

Examples of the resin having an acid group include resins having the following structures. In the following structural formulae, Me represents a methyl group.

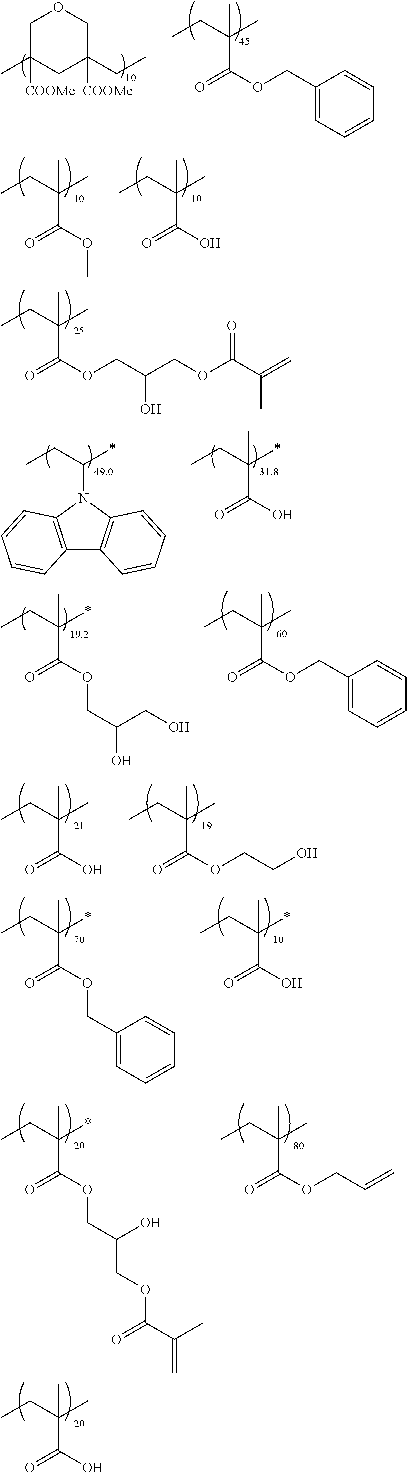

The composition according to the embodiment of the present invention may include a resin as a dispersant. Examples of the dispersant include an acidic dispersant (acidic resin) and a basic dispersant (basic resin). Here, the acidic dispersant (acidic resin) refers to a resin in which the amount of an acid group is more than the amount of a basic group. In a case where the sum of the amount of an acid group and the amount of a basic group in the acidic dispersant (acidic resin) is represented by 100 mol %, the amount of the acid group in the acidic resin is preferably 70 mol % or more and more preferably substantially 100 mol %. The acid group in the acidic dispersant (acidic resin) is preferably a carboxyl group. An. acid value of the acidic dispersant (acidic resin) is preferably 40 to 105 mgKOH/g, more preferably 50 to 105 mgKOH/g, and still more preferably 60 to 105 mgKOH/g. In addition, the basic dispersant (basic resin) refers to a resin in which the amount of a basic group is more than the amount of an acid group. In a case where the sum of the amount of an acid group and the amount of a basic group in the basic dispersant (basic resin) is represented by 100 mol %, the amount of the basic group in the basic resin is preferably more than 50 mol %. The basic group in the basic dispersant is preferably an amino group.

It is preferable that the resin A used as the dispersant further includes a repeating unit having an acid group. By the resin, which is used as the dispersant, including the repeating unit having an acid group, in a case where a pattern is formed using a photolithography method, the amount of residues formed in an underlayer of a pixel can be reduced.

It is preferable that the resin used as the dispersant is a graft copolymer. Since the graft copolymer has affinity to the solvent due to the graft chain, the pigment dispersibility and the dispersion stability over time are excellent. The details of the graft copolymer can be found in the description of paragraphs “0025” to “0094” of JP2012-255128A, the content of which is incorporated herein by reference. In addition, specific examples of the graft copolymer include the following resins. The following resin may also be a resin having an acid group (alkali-soluble resin). In addition, other examples of the graft copolymer include resins described in paragraphs “0072” to “0094” of JP2012-255128A, the content of which is incorporated herein by reference.

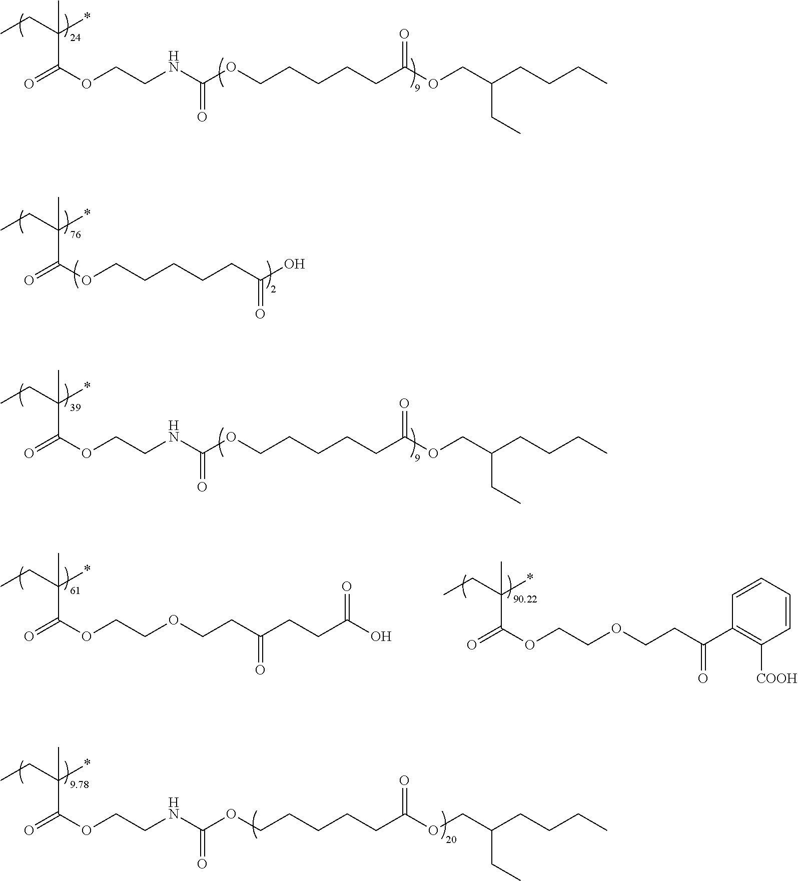

In addition, in the present invention, as the resin (dispersant), an oligoimine dispersant having a nitrogen atom at least either a main chain or a side chain is also preferably used. As the oligoimine dispersant, a resin, which includes a structural unit having a partial structure X with a functional group (pKa: 14 or less) and a side chain including a side chain Y having 40 to 10000 atoms and has a basic nitrogen atom at least either a main chain or a side chain, is preferable. The basic nitrogen atom is not particularly limited as long as it is a nitrogen atom exhibiting basicity. The oligoimine dispersant can be found in the description of paragraphs “0102” to “0166” of JP2012-255128A, the content of which is incorporated herein by reference. As the oligoimine dispersant, a resin having the following structure or a resin described in paragraphs “0168” to “0174” of JP2012-255128A can be used.

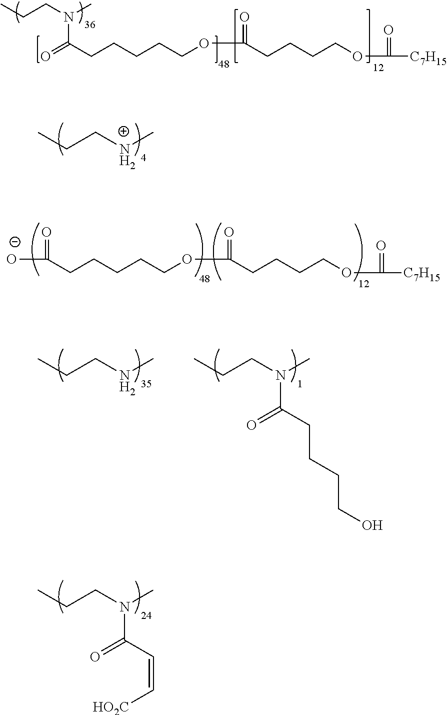

The dispersant is available as a commercially available product, and specific examples thereof include DISPERBYK series (for example, DISPERBYK 2000, manufactured by BYK Chemie). In addition, a pigment dispersant described in paragraphs “0041” to “0130” of JP2014-130338A can also be used, the content of which is incorporated herein by reference. In addition, the resin having an acid group or the like can also be used as a dispersant.

In a case where the composition according to the embodiment of the present invention includes a resin, the content of the resin is preferably 0.1% to 50% by mass with respect to the total solid content of the composition according to the embodiment of the present invention. The lower limit is preferably 1% by mass or more, more preferably 3% by mass or more, still more preferably 5% by mass or more, and still more preferably 10% by mass or more. The upper limit is more preferably 40% by mass or less and still more preferably 30% by mass or less. In addition, the content of the resin having an acid group is preferably 0.1 to 50% by mass with respect to the total solid content of the composition according to the embodiment of the present invention. The lower limit is preferably 1% by mass or more, more preferably 3% by mass or more, still more preferably 5% by mass or more, and still more preferably 10% by mass or more. The upper limit is more preferably 40% by mass or lower, and still more preferably 30% by mass or lower. The composition according to the embodiment of the present invention may include one resin or two or more resins. In a case where the composition includes two or more, it is preferable that the total content is in the above-described range.

In a case where the composition according to the embodiment of the present invention includes the polymerizable compound (preferably the monomer type polymerizable compound that has a group having an ethylenically unsaturated bond) and the resin, a mass ratio (polymerizable compound/resin) of the polymerizable compound to the resin is preferably 0.4 to 1.4. The lower limit of the mass ratio is preferably 0.5 or more and more preferably 0.6 or more. The upper limit of the mass ratio is preferably 1.3 or less and more preferably 1.2 or less. In a case where the mass ratio is in the above-described range, a pattern having more excellent rectangularity can be formed.

In addition, a mass ratio (polymerizable compound/resin having an acid group) of the polymerizable compound (preferably the monomer type polymerizable compound that has a group having an ethylenically unsaturated bond) to the resin having an acid group is preferably 0.4 to 1.4. The lower limit of the mass ratio is preferably 0.5 or more and more preferably 0.6 or more. The upper limit of the mass ratio is preferably 1.3 or less and more preferably 1.2 or less. In a case where the mass ratio is in the above-described range, a pattern having more excellent rectangularity can be formed.

<<Compound Having at Least One Skeleton Selected from Fluorene Skeleton or Triazine Skeleton>>

As components other than the curable compound, the composition according to the embodiment of the present invention may also include a compound having at least one skeleton selected from a fluorene skeleton or a triazine skeleton. That is as a compound other than the polymerizable compound or the polymer, the composition according to the embodiment of the present invention may also include a compound having at least one skeleton selected from a fluorene skeleton or a triazine skeleton. By the composition according to the embodiment of the present invention including the above-described compound, the refractive index of the obtained film can be further increased.

In a case where the composition according to the embodiment of the present invention includes the compound having the above-described skeleton, the content of the compound having the above-described skeleton is 1% to 16% by mass with respect to the total solid content of the composition according to the embodiment of the present invention. The lower limit is preferably 2% by mass or more, more preferably 3% by mass or more, still more preferably 4% by mass or more, and still more preferably 5% by mass or more. The upper limit is more preferably 14% by mass or less and still more preferably 12% by mass or less.

<<Inorganic Particles>>

It is preferable that the composition according to the embodiment of the present invention includes inorganic particles. As the inorganic particles, inorganic particles that have a high refractive index and are colorless, white, or transparent are preferable, oxide particles of titanium (Ti), zirconium (Zr), aluminum (Al), silicon (Si), zinc (Zn), magnesium (Mg), or the like are preferable, titanium dioxide (TiO2) particles, zirconium oxide (ZrO2) particles, or silicon dioxide (SiO2) particles are more preferable, and titanium dioxide particles are still more preferable. The purity of the titanium dioxide particles is preferably 70% or higher, more preferably 80% or higher, and still more preferably 85% or higher. The purity of the titanium dioxide particles refers to the content of a component represented by Formula TiO₂. In addition, in the titanium dioxide particles, the content of lower titanium oxide represented by TiₙO₂ₙ₋₁ (n represents a number of 2 to 4), titanium nitride, or the like is preferably 30% by mass or lower, more preferably 20% by mass or lower, and still more preferably 15% by mass or lower.

The average primary particle size of the inorganic particles used in the present invention is preferably 1 to 100 nm, more preferably 1 to 80 nm, and still more preferably 1 to 50 nm. Also, the average primary particle size of the inorganic particles in the present invention refers to a value obtained by diluting a mixed solution or a dispersion including the inorganic particles to 80 times with propylene glycol monomethyl ether acetate and measuring the obtained dilute solution using a dynamic light scattering method. This measured value refers to a number-average particle size obtained using MICROTRAC UPA-EX150 (manufactured by Nikkiso Co., Ltd.).

The refractive index of the inorganic particles is preferably 1.75 to 2.70 and more preferably 1.90 to 2.70. The specific surface area of the inorganic particles is preferably 10 to 400 m²/g, more preferably 20 to 200 m²/g, and still more preferably 30 to 150 m²/g. The shape of the inorganic particles is not particularly limited. Examples of the inorganic particles include a granular shape, a spherical shape, a square shape, a spindle shape, and an unstructured shape.

The inorganic particles used in the present invention may be surface-treated with an organic compound. Examples of the organic compound used for the surface treatment include polyol, alkanolamine, stearic acid, a silane coupling agent, and a titanate coupling agent. Among these, a silane coupling agent is preferable. The surface treatment may be performed using only one surface treatment agent or using a combination of two or more surface treatment agents. In addition, it is preferable that the surfaces of the inorganic particles are covered with an oxide of aluminum, silicon, zirconia, or the like.

As the inorganic particles, a commercially available product can be preferably used. Examples of a commercially available product of the titanium dioxide particles include TTO series (for example, TTO-51 (A) or TTO-51 (C)), TTO-S, and V series (for example, TTO-S-1, TTO-S-2, or TTO-V-3) manufactured by Ishihara Sangyo Kaisha, Ltd. and MT series (for example, MT-01 or MT-05) manufactured by TAYCA Corporation. Examples of a commercially available product of the zirconium dioxide particles include UEP (manufactured by Daiichi Kigenso Kagaku Kogyo Co., Ltd.), PCS (manufactured by Nihondenko Co., Ltd.), JS-01, JS-03, and JS-04 (manufactured by Nihondenko Co., Ltd.), and UEP-100 (manufactured by Daiichi Kigenso Kagaku Kogyo Co., Ltd.). Examples of a commercially available product of the silicon dioxide particles include OG502-31 manufactured by Clariant AG.

The content of the inorganic particles is preferably 0.1% to 40% by mass with respect to the total solid content of the composition. The upper limit is preferably 30% by mass or less and more preferably 25% by mass or less. The lower limit is preferably 1% by mass or more and more preferably 10% by mass or more.

The content of the inorganic particles is preferably 1% to 60% by mass with respect to the total content of the color material that transmits infrared light and blocks visible light, the near infrared absorbing colorant, and the inorganic particles. The upper limit is preferably 50% by mass or less and more preferably 40% by mass or less. The lower limit is preferably 5% by mass or more and more preferably 10% by mass or more.

In addition, the total content of the color material that transmits infrared light and blocks visible light, the near infrared absorbing colorant, and the inorganic particles is preferably 1% to 70% by mass with respect to the total solid content of the composition. The upper limit is preferably 60% by mass or less and more preferably 50% by mass or less. The lower limit is preferably 10% by mass or more and more preferably 20% by mass or more.

In the present invention, as the inorganic particle, one kind may be used alone, or two or more kinds may be used in combination.

<<Photopolymerization Initiator>>

The composition according to the embodiment of the present invention may include a photopolymerization initiator. Examples of the photopolymerization initiator include a photoradical polymerization initiator and a photocationic polymerization initiator. It is preferable that the photopolymerization initiator is selected and used according to the kind of the polymerizable compound. In a case where a radically polymerizable compound such as the compound which has a group having an ethylenically unsaturated bond is used as the polymerizable compound, it is preferable that a photoradical polymerization initiator is used as the photopolymerization initiator. In a case where the cationicallypolymerizable compound is used as the polymerizable compound, it is preferable that the photocationic polymerization initiator is used as the photopolymerization initiator. The photopolymerization initiator is not particularly limited and can be appropriately selected from well-known photopolymerization initiators. For example, a compound having photosensitivity to light in a range from an ultraviolet range to a visible range is preferable.

The content of the photopolymerization initiator is preferably 0.1% to 50% by mass, more preferably 0.5 to 30% by mass, and still more preferably 1 to 20% by mass with respect to the total solid content of the composition. In a case where the content of the photopolymerization initiator is in the above-described range, more sensitivity and pattern formability can be obtained. The composition according to the embodiment of the present invention may include one photopolymerization initiator or two or more photopolymerization initiators. In a case where the composition includes two or more photopolymerization initiators, it is preferable that the total content of the photopolymerization initiators is in the above-described range.

(Photoradical Polymerization Initiator)

Examples of the photoradical polymerization initiator include a halogenated hydrocarbon derivative (for example, a compound having a triazine skeleton or a compound having an oxadiazole skeleton), an acylphosphine compound, a hexaarylbiimidazole, an oxime compound, an organic peroxide, a thio compound, a ketone compound, an aromatic onium salt, an α-hydroxyketone compound, and an α-aminoketone compound. In addition, from the viewpoint of exposure sensitivity, as the photopolymerization initiator, a trihalomethyltriazine compound, a benzyldimethylketal compound, an α-hydroxyketone compound, an α-aminoketone compound, an acylphosphine compound, a phosphine oxide compound, a metallocene compound, an oxime compound, a triarylimidazole dimer, an onium compound, a benzothiazole compound, a benzophenone compound, an acetophenone compound, a cyclopentadiene-benzene-iron complex, a halomethyloxadiazole compound, or a 3-aryl-substituted coumarin compound is preferable, a compound selected from an oxime compound, an α-hydroxy ketone compound, an α-aminoketone compound, and an acylphosphine compound is more preferable, and an oxime compound is still more preferable. The details of the photoradical polymerization initiator can be found in paragraphs “0065” to “0111” of JP2014-130173A, the content of which is incorporated herein by reference.

Examples of a commercially available product of the α-hydroxyketone compound include IRGACURE-184, DAROCUR-1173, IRGACURE-500, IRGACURE-2959, and IRGACURE-127 (all of which are manufactured by BASF SE). Examples of a commercially available product of the α-aminoketone compound include IRGACURE-907, IRGACURE-369, IRGACURE-379, and IRGACURE-379EG (all of which are manufactured by BASF SE). Examples of a commercially available product of the acylphosphine compound include IRGACURE-819, and DAROCUR-TPO (all of which are manufactured by BASF SE).

Examples of the oxime compound include a compound described in JP2001-233842A, a compound described in JP2000-080068A, a compound described in JP2006-342166A, a compound described in J. C. S. Perkin II (1979, pp. 1653 to 1660), a compound described in J. C. S. Perkin II (1979, pp. 156 to 162), a compound described in Journal of Photopolymer Science and Technology (1995, pp. 202 to 232), a compound described in JP2000-066385A, a compound described in JP2000-080068A, a compound described in JP2004-534797A, a compound described in JP2006-342166A, a compound described in JP2017-019766A, a compound described in JP6065596B, a compound described in WO2015/152153A, and a compound described in WO2017/051680A. Specific examples of the oxime compound include 3-benzoyloxyiminobutane-2-one, 3-acetoxyiminobutane-2-one, 3-propionyloxyiminobutane-2-one, 2-acetoxyiminopentane-3-one, 2-acetoxyimino-1-phenylpropane-1-one, 2-benzoyloxyimino-1-phenylpropane-1-one, 3-(4-toluene sulfonyloxy) iminobutane-2-one, and 2-ethoxycarbonyloxyimino-1-phenylpropane-1-one. Examples of a commercially available product of the oxime compound include IRGACURE-OXE01, IRGACURE-OXE02, IRGACURE-OXE03, or IRGACURE-OXE04 (all of which are manufactured by BASF SE), TR-PBG-304 (manufactured by Changzhou Tronly New Electronic Materials Co., Ltd.), and ADEKA OPTOMER N-1919 (manufactured by ADEKA CORPORATION, a photopolymerization initiator 2 described in JP2012-014052A). As the oxime compound, a compound having no colorability or a compound having high transparency that is not likely to be discolored can also be preferably used. Examples of a commercially available product of the oxime compound include ADEKA ARKLS NCI-730, NCI-831, and NCI-930 (all of which are manufactured by ADEKA CORPORATION).

In the present invention, an oxime compound having a fluorene ring can also be used as the photopolymerization initiator. Specific examples of the oxime compound having a fluorene ring include a compound described in JP2014-137466A. The content of this specification is incorporated herein by reference.

In the present invention, an oxime compound having a fluorine atom can also be used as the photoradical polymerization initiator. Specific examples of the oxime compound having a fluorine atom include a compound described in JP2010-262028A, Compound 24 and 36 to 40 described in JP2014-500852A, and Compound (C-3) described in JP2013-164471A. The content of this specification is incorporated herein by reference.

In the present invention, as the photoradical polymerization initiator, an oxime compound having a nitro group can be used. It is preferable that the oxime compound having a nitro group is a dimer. Specific examples of the oxime compound having a nitro group include a compound described in paragraphs “0031” to “0047” of JP2013-114249A and paragraphs “0008” to “0012” and “0070” to “0079” of JP2014-137466A, a compound described in paragraphs “0007” to 0025” of JP4223071B, and ADEKA ARKLS NCI-831 (manufactured by ADEKA CORPORATION).

In the present invention, an oxime compound having a benzofuran skeleton can also be used as the photoradical polymerization initiator. Specific examples include OE-01 to OE-75 described in WO2015/036910A.

Specific examples of the oxime compound which are preferably used in the present invention are shown below, but the present invention is not limited thereto.

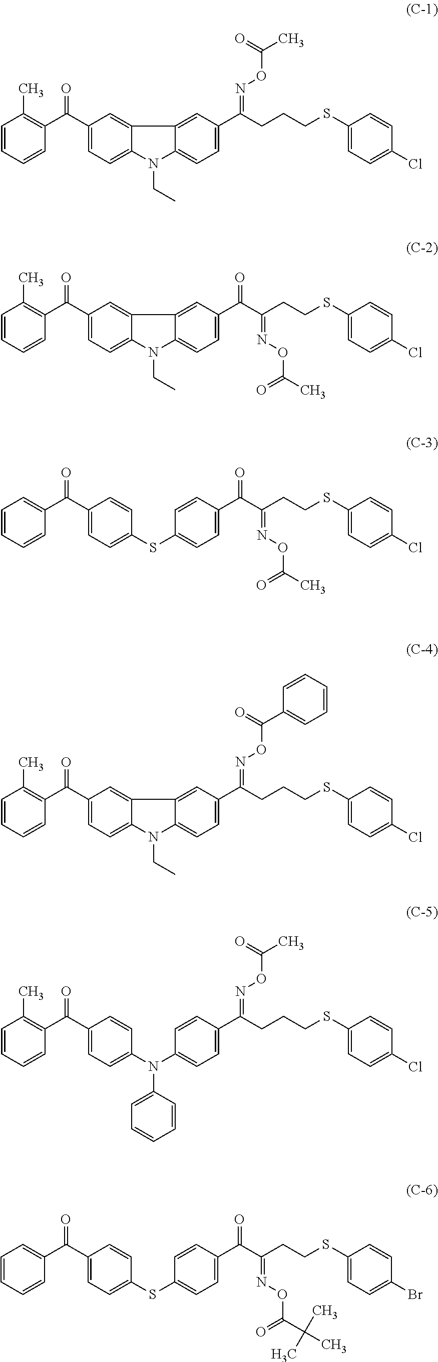 [SMILES: CCn1c2ccc(C(=O)c3ccccc3C)cc2c2cc(/C(CCCSc3ccc(Cl)cc3)=N/OC(C)=O)ccc21 ; CCn1c2ccc(C(=O)/C(CCSc3ccc(Cl)cc3)=N/OC(C)=O)cc2c2cc(C(=O)c3ccccc3C)ccc21 ; CC(=O)O/N=C(\CCSc1ccc(Cl)cc1)C(=O)c1ccc(Sc2ccc(C(=O)c3ccccc3)cc2)cc1 ; CCn1c2ccc(C(=O)c3ccccc3C)cc2c2cc(/C(CCCSc3ccc(Cl)cc3)=N/OC(=O)c3ccccc3)ccc21 ; CC(=O)O/N=C(\CCCSc1ccc(Cl)cc1)c1ccc(N(c2ccccc2)c2ccc(C(=O)c3ccccc3C)cc2)cc1 ; CC(C)(C)C(=O)O/N=C(\CCSc1ccc(Br)cc1)C(=O)c1ccc(Sc2ccc(C(=O)c3ccccc3)cc2)cc1]

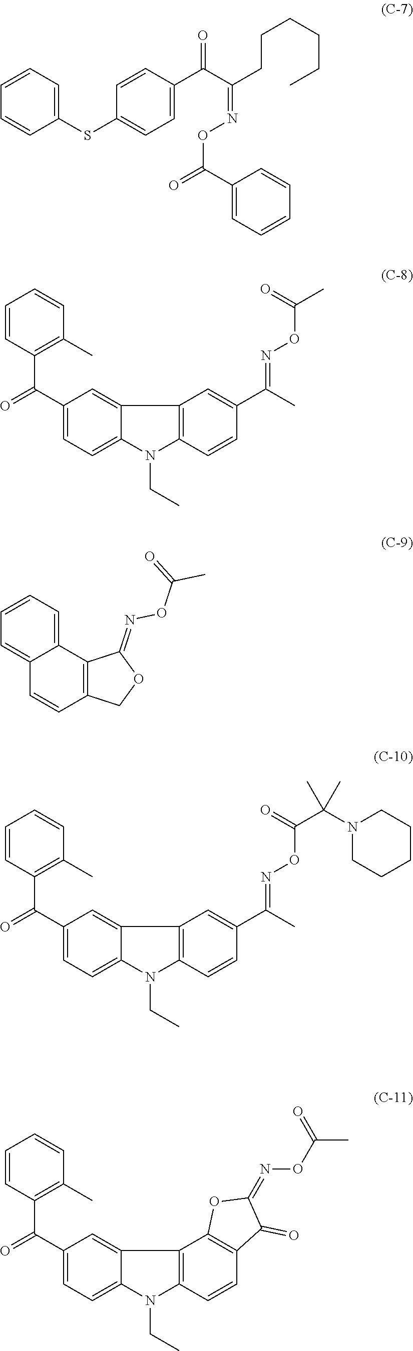 [SMILES: CCCCCC/C(=N/OC(=O)c1ccccc1)C(=O)c1ccc(Sc2ccccc2)cc1 ; CCn1c2ccc(C(=O)c3ccccc3C)cc2c2cc(/C(C)=N/OC(C)=O)ccc21 ; CC(=O)O/N=C1\OCc2ccc3ccccc3c21 ; CCn1c2ccc(C(=O)c3ccccc3C)cc2c2cc(/C(C)=N/OC(=O)C(C)(C)N3CCCCC3)ccc21 ; CCn1c2ccc(C(=O)c3ccccc3C)cc2c2c3c(ccc21)C(=O)/C(=N\OC(C)=O)O3]

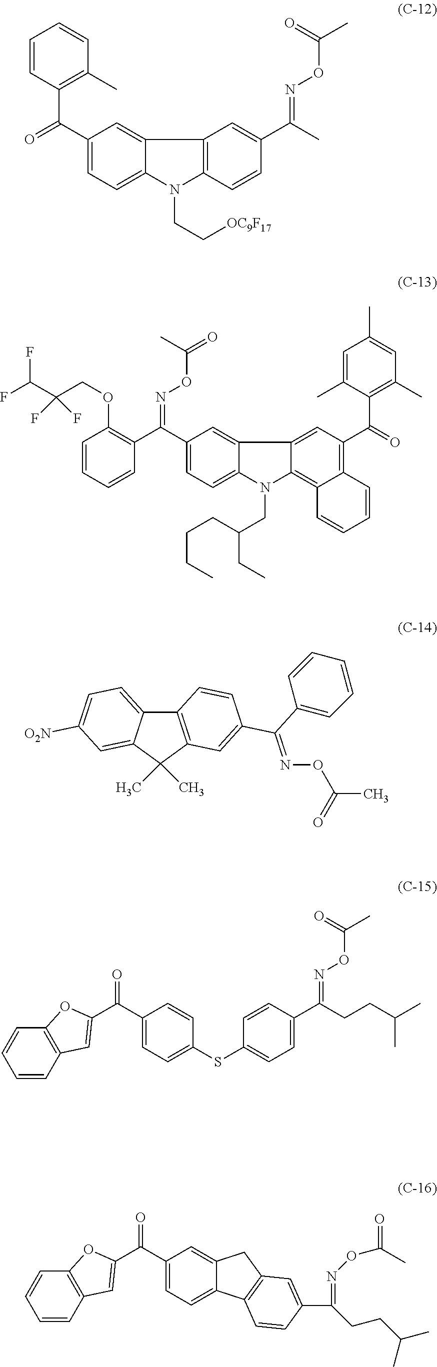

The oxime compound is preferably a compound having a maximum absorption wavelength in a wavelength range of 350 to 500 nm and more preferably a compound having a maximum absorption wavelength in a wavelength range of 360 to 480 nm. In addition, the molar absorption coefficient of the oxime compound at a wavelength of 365 nm or a wavelength of 405 nm is preferably high, more preferably 1,000 to 300,000, still more preferably 2,000 to 300,000, and still more preferably 5,000 to 200,000 from the viewpoint of sensitivity. The molar absorption coefficient of the compound can be measured using a sensitivity. The molar absorption coefficient of the compound can be measured using a well-known method. For example, it is preferable that the molar absorption coefficient can be measured using a spectrophotometer (Cary-5 spectrophotometer, manufactured by Varian Medical Systems, Inc.) and ethyl acetate as a solvent at a concentration of 0.01 g/L.

In the present invention, as the photoradical polymerization initiator, a photoradical polymerization initiator having difunctional groups or trifunctional or higher functional groups may be used. Specific examples of the photoradical polymerization initiator include a dimer of an oxime compound described in JP2010-527339A, JP2011-524436A, WO2015/004565A, paragraphs “0417” to “0412” of JP2016-532675A, or paragraphs “0039” to “0055” of WO2017/033680A, a compound (E) and a compound (G) described in JP2013-522445A, and Cmpd 1 to 7 described in WO2016/034963A.

It is preferable that the photoradical polymerization initiator includes an oxime compound and an α-aminoketone compound. By using the oxime compound and the α-aminoketone compound in combination, the developability is improved, and a pattern having excellent rectangularity is likely to be formed. In a case where the oxime compound and the α-aminoketone compound are used in combination, the content of the α-aminoketone compound is preferably 50 to 600 parts by mass and more preferably 150 to 400 parts by mass with respect to 100 parts by mass of the oxime compound.

The content of the photoradical polymerization initiator is preferably 0.1% to 50% by mass, more preferably 0.5% to 30% by mass, and still more preferably 1% to 20% by mass with respect to the total solid content of the composition according to the embodiment of the present invention. In a case where the content of the photoradical polymerization initiator is in the above-described range, more sensitivity and pattern formability can be obtained. The composition according to the embodiment of the present invention may include only one photoradical polymerization initiator or two or more photoradical polymerization initiators. In a case where the composition includes two or more photoradical polymerization initiators, it is preferable that the total content of the photoradical polymerization initiators is in the above-described range.

(Photocationic Polymerization Initiator)

Examples of the photocationic polymerization initiator include a photoacid generator. Examples of the photoacid generator include compounds which are decomposed by light irradiation to generate an acid including: an onium salt compound such as a diazonium salt, a phosphonium salt, a sulfonium salt, or an iodonium salt; and a sulfonate compound such as imidosulfonate, oximesulfonate, diazodisulfone, disulfone, or o-nitrobenzyl sulfonate. The details of the photocationic polymerization initiator can be found in paragraphs “0139” to “0214” of JP2009-258603A, the content of which is incorporated herein by reference.

The content of the photocationic polymerization initiator is preferably 0.1% to 50% by mass, more preferably 0.5% to 30% by mass, and still more preferably 1% to 20% by mass with respect to the total solid content of the composition according to the embodiment of the present invention. In a case where the content of the photocationic polymerization initiator is in the above-described range, more sensitivity and pattern formability can be obtained. The composition according to the embodiment of the present invention may include only one photocationic polymerization initiator or two or more photocationic polymerization initiators. In a case where the composition includes two or more photocationic polymerization initiators, it is preferable that the total content of the two or more photocationic polymerization initiators is in the above-described range.

<<Polyfunctional Thiol>>

The composition according to the embodiment of the present invention may further include a polyfunctional thiol. The polyfunctional thiol is a compound having two or more thiol (SH) groups. By using the above-described photoradical polymerization initiator in combination, the polyfunctional thiol functions as a chain transfer agent in the process of radical polymerization after light irradiation such that a thiyl radical that is not likely to undergo polymerization inhibition due to oxygen is generated. Therefore, the sensitivity of the composition can be improved. In particular, it is preferable that the SH group is a polyfunctional aliphatic thiol that is bonded to an aliphatic group such as an ethylene group.

Examples of the polyfunctional thiol include hexanedithiol, decanedithiol, 1,4-butanediol bisthio propionate, 1,4-butanediolbisthioglycolate, ethylene glycol bisthioglycolate, ethylene glycol bisthiopropionate, trimethylolpropane tristhioglycolate, trimethylolpropane tristhiopropionate, trimethylolethane tris(3-mercaptobutyrate), trimethylolpropane tris(3-mercaptobutyrate), trimethylolpropane tris(3-mercaptopropionate), pentaerythritol tetrakisthioglycolate, pentaerythritol tetrakisthiopropionate, pentaerythritol tetrakis(3-mercaptopropionate), dipentaerythritol hexakis(3-mercaptopropionate), trimercaptopropionic acid tris(2-hydroxyethyl)isocyanurate, 1,4-dimethylmercaptobenzene, 2,4,6-trimercapto-s-triazine, and 2-(N,N-dibutylamino)-4,6-dimercapto-s-triazine. In addition, for example, a compound having the following structure can also be used.

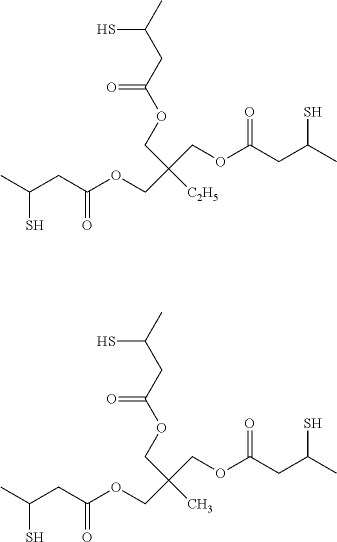

The content of the polyfunctional thiol is preferably 0.1% to 20% by mass, more preferably 0.1% to 15% by mass, and still more preferably 0.1% to 10% by mass with respect to the total solid content of the composition according to the embodiment of the present invention. The composition according to the embodiment of the present invention may include one polyfunctional thiol or two or more polyfunctional thiols. In a case where the composition includes two or more, it is preferable that the total content is in the above-described range.

<<Epoxy Resin Curing Agent>>

In a case where the composition according to the embodiment of the present invention includes an epoxy resin, it is preferable that the composition further includes an epoxy resin curing agent. Examples of the epoxy resin curing agent include an amine compound, an acid anhydride compound, an amide compound, a phenol compound, and a polyvalentcarboxylic acid. From the viewpoints of heat resistance and transparency of a cured product, as the epoxy resin curing agent, a polyvalentcarboxylic acid is preferable, and a compound having two or more carboxylic anhydride groups in a molecule is most preferable. Specific examples of the epoxy resin curing agent include butanedioic acid. The details of the epoxy resin curing agent can be found in paragraphs “0072” to “0078”, the content of which is incorporated herein by reference.

The content of the epoxy resin curing agent is preferably 0.01 to 20 parts by mass, more preferably 0.01 to 10 parts by mass, and still more preferably 0.1 to 6.0 parts by mass with respect to 100 parts by mass of the epoxy resin.

<<Pigment Derivative>>

The composition according to the embodiment of the present invention may further include a pigment derivative. Examples of the pigment derivative include a compound having a structure in which a portion of a pigment is substituted with an acid group, a basic group, a group having a salt structure, or a phthalimidomethyl group. As the pigment derivative, a compound represented by Formula (B1) is preferable.

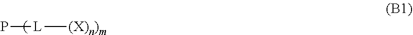

In Formula (B1), P represents a colorant structure, L represents a single bond or a linking group, X represents an acid group, a basic group, a group having a salt structure, or a phthalimidomethyl group, m represents an integer of 1 or more, n represents an integer of 1 or more, in a case where m represents 2 or more, a plurality of L's and a plurality of X's may be different from each other, and in a case where n represents 2 or more, a plurality of X's may be different from each other.

As the colorant structure represented by P, preferably at least one selected from a pyrrolopyrrole colorant structure, a diketopyrrolopyrrole colorant structure, a quinacridone colorant structure, an anthraquinone colorant structure, a dianthraquinone colorant structure, a benzoisoindole colorant structure, a thiazine indigo colorant structure, an azo colorant structure, a quinophthalone colorant structure, a phthalocyanine colorant structure, a naphthalocyanine colorant structure, a dioxazine colorant structure, a perylene colorant structure, a perinone colorant structure, a benzimidazolone colorant structure, a benzothiazole colorant structure, a benzimidazole colorant structure, or a benzoxazole colorant structure, more preferably at least one selected from a pyrrolopyrrole colorant structure, a diketopyrrolopyrrole colorant structure, a quinacridone colorant structure, or a benzimidazolone colorant structure, and still more preferably a pyrrolopyrrole colorant structure.

Examples of the linking group represented by L include a hydrocarbon group, a heterocyclic group, —NR—, —SO₂—, —S—, —O—, —CO—, and a group of a combination thereof. R represents a hydrogen atom, an alkyl group, or an aryl group.

Examples of the acid group represented by X include a carboxyl group, a sulfo group, a carboxylic acid amide group, a sulfonic acid amide group, and an imide acid group. As the carboxylic acid amide group, a group represented by —NHCOR^{X1} is preferable. As the sulfonic acid amide group, a group represented by —NHSO₂R^{X2} is preferable. As the imide acid group, a group represented by —SO₂NHSO₂R^{X3}, —CONHSO₂R^{X4}, —CONHCOR^{X5}, or —SO₂NHCOR^{X6} is preferable. R^{X1} to R^{X6} each independently represent a hydrocarbon group or a heterocyclic group. The hydrocarbon group and the heterocyclic group represented by R^{X1} to R^{X6} may further have a substituent. Examples of the substituent which may be further included include the substituent T described above regarding Formula (PP). Among these, a halogen atom is preferable and a fluorine atom is more preferable. Examples of the basic group represented by X include an amino group. Examples of the salt structure represented by X include a salt of the acid group or the basic group described above.

Examples of the pigment derivative include compounds having the following structures. In the following structural formulae, Et represents an ethyl group, and Ph represents a phenyl group. In addition, as the pigment derivative, compounds described in JP1981-118462A (JP-S56-118462A), JP1988-264674A (JP-S63-264674A), JP1989-217077A (JP-H1-217077A), JP1991-009961A (JP-H3-009961A), JP1991-026767A (JP-H3-026767A), JP1991-153780A (JP-H3-153780A), JP1991-045662A (JP-H3-045662A), JP1992-285669A (JP-H4-285669A), JP1994-145546A (JP-H6-145546A), JP1994-212088A (JP-H6-212088A), JP1994-240158A (JP-H6-240158A), JP1998-030063A (JP-H10-030063A), JP1998-195326A (JP-H10-195326A), paragraphs “0086” to “0098” of WO2011/024896A, paragraphs “0063” to “0094” of WO2012/102399A, paragraphs “0082” of WO2017/038252A, and JP 5299151B can be used, the content of which is incorporated herein by reference.

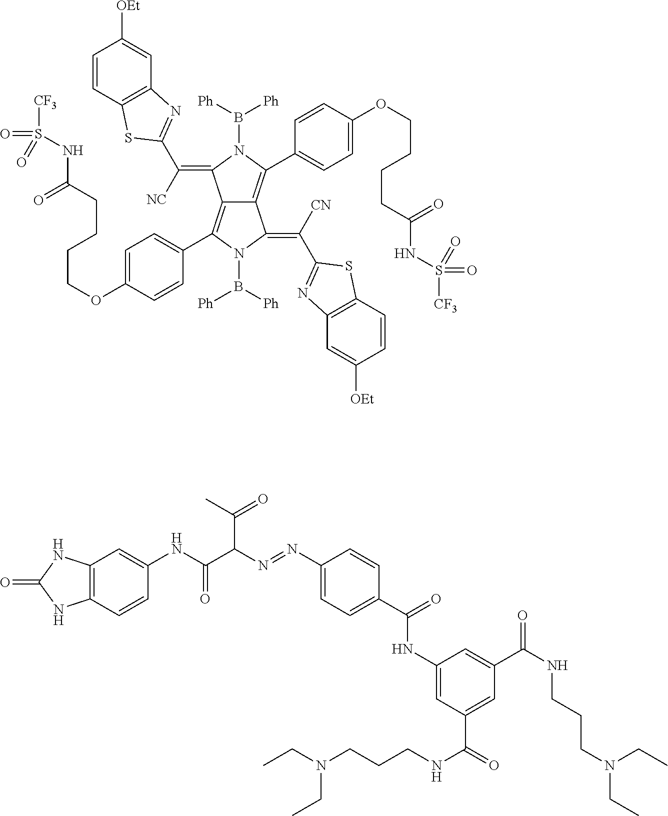 [SMILES: CCOc1ccc2sc(/C(C#N)=c3/c4c(-c5ccc(OCCCCC(=O)NS(=O)(=O)C(F)(F)F)cc5)n(B(c5ccccc5)c5ccccc5)/c(=C(/C#N)c5nc6cc(OCC)ccc6s5)c4c(-c4ccc(OCCCCC(=O)NS(=O)(=O)C(F)(F)F)cc4)n3B(c3ccccc3)c3ccccc3)nc2c1 ; CCN(CC)CCCNC(=O)c1cc(NC(=O)c2ccc(/N=N/C(C(C)=O)C(=O)Nc3ccc4[nH]c(=O)[nH]c4c3)cc2)cc(C(=O)NCCCN(CC)CC)c1]

In a case where the composition according to the embodiment of the present invention includes the pigment derivative, the content of the pigment derivative is preferably 1 to 50 parts by mass with respect to 100 parts by mass of the pigment. The lower limit value is preferably 3 parts by mass or more and more preferably 5 parts by mass or more. The upper limit value is preferably 40 parts by mass or lower and more preferably 30 parts by mass or lower. In a case where the content of the pigment derivative is in the above-described range, the pigment dispersibility can be improved, and aggregation of the pigment can be effectively suppressed. As the pigment derivative, one kind may be used alone, or two or more kinds may be used in combination. In a case where two or more pigment derivatives are used in combination, it is preferable that the total content of the two or more pigment derivatives is in the above-described range.

<<Solvent>>

The composition according to the embodiment of the present invention may include a solvent. Examples of the solvent include an organic solvent. Basically, the solvent is not particularly limited as long as it satisfies the solubility of the respective components and the application properties of the composition. Examples of the organic solvent include esters, ethers, ketones, and aromatic hydrocarbons. The details of the organic solvent can be found in paragraph “0223” of WO2015/166779A, the content of which is incorporated herein by reference. In addition, an ester solvent in which a cyclic alkyl group is substituted or a ketone solvent in which a cyclic alkyl group is substituted can also be preferably used. Specific examples of the organic solvent include dichloromethane, methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, cyclohexyl acetate, cyclopentanone, ethyl carbitol acetate, butyl carbitol acetate, propylene glycol monomethyl ether, and propylene glycol monomethyl ether acetate. In the present invention, as the organic solvent, one kind may be used alone, or two or more kinds may be used in combination. In this case, it may be preferable that the content of the aromatic hydrocarbon (for example, benzene, toluene, xylene, or ethylbenzene) as the solvent is low (for example, 50 mass parts per million (ppm) or less, 10 mass ppm or less, or 1 mass ppm or less with respect to the total mass of the organic solvent) in consideration of environmental aspects and the like.

In the present invention, a solvent having a low metal content is preferably used. For example, the metal content in the solvent is preferably 10 mass parts per billion (ppb) or less. Optionally, a solvent having a metal content at a mass parts per trillion (ppt) level may be used. For example, such a high-purity solvent is available from Toyo Gosei Co., Ltd. (The Chemical Daily, Nov. 13, 2015).

Examples of a method of removing impurities such as metal from the solvent include distillation (for example, molecular distillation or thin-film distillation) and filtering using a filter. The pore size of a filter used for the filtering is preferably 10 μm or lower, more preferably 5 μm or lower, and still more preferably 3 μm or lower. As a material of the filter, polytetrafluoroethylene, polyethylene, or nylon is preferable.

The solvent may include an isomer (a compound having the same number of atoms and a different structure). In addition, the organic solvent may include only one isomer or a plurality of isomers.

In the present invention, as the organic solvent, an organic solvent containing 0.8 mmol/L or less of a peroxide is preferable, and an organic solvent containing substantially no peroxide is more preferable.

The content of the solvent is preferably 10% to 99% by mass with respect to the total mass of the composition according to the embodiment of the present invention. The upper limit is preferably 95% by mass or less and more preferably 90% by mass or less. The lower limit is preferably 30% by mass or more, more preferably 40% by mass or more, still more preferably 50% by mass or more, still more preferably 60% by mass or more, and still most preferably 70% by mass or more.

<<Polymerization Inhibitor>>

The composition according to the embodiment of the present invention may include a polymerization inhibitor. Examples of the polymerization inhibitor include hydroquinone, p-methoxyphenol, di-tert-butyl-p-cresol, pyrogallol, tert-butylcatechol, benzoquinone, 4,4′-thiobis(3-methyl-6-tert-butylphenol), 2,2′-methylenebis(4-methyl-6-t-butylphenol), and N-nitrosophenylhydroxyamine salt (for example, an ammonium salt or a cerium (III) salt).

Among these, p-methoxyphenol is preferable. The content of the polymerization inhibitor is preferably 0.001% to 5% by mass with respect to the total solid content of the composition according to the embodiment of the present invention.

<<Silane Coupling Agent>>

The composition according to the embodiment of the present invention may include a silane coupling agent. In the present invention, the silane coupling agent refers to a silane compound having a functional group other than a hydrolyzable group. In addition, the hydrolyzable group refers to a substituent directly linked to a silicon atom and capable of forming a siloxane bond due to at least one of a hydrolysis reaction or a condensation reaction. Examples of the hydrolyzable group include a halogen atom, an alkoxy group, and an acyloxy group. Among these, an alkoxy group is preferable. That is, it is preferable that the silane coupling agent is a compound having an alkoxysilyl group. Examples of the functional group other than a hydrolyzable group include a vinyl group, a (meth)acryloyl group, a mercapto group, an epoxy group, an oxetanyl group, an amino group, an ureido group, a sulfide group, an isocyanate group, and a phenyl group. Among these, a (meth)acryloyl group or an epoxy group is preferable. Examples of the silane coupling agent include a compound described in paragraphs “0018” to “0036” of JP2009-288703A and a compound described in paragraphs “0056” to “0066” of JP2009-242604A, the contents of which are incorporated herein by reference.

The content of the silane coupling agent is preferably 0.01% to 15.0% by mass and more preferably 0.05% to 10.0% by mass with respect to the total solid content of the composition according to the embodiment of the present invention. As the silane coupling agent, one kind may be used alone, or two or more kinds may be used. In a case where two or more silane coupling agents are used, it is preferable that the total content is in the above-described range.

<<Surfactant>>

The composition according to the embodiment of the present invention may include a surfactant. As the surfactants, various surfactants such as a fluorine surfactant, a nonionic surfactant, a cationic surfactant, an anionic surfactant, or a silicone surfactant can be used. The details of the surfactant can be found in paragraphs “0238” to “0245” of WO2015/166779A, the content of which is incorporated herein by reference.

In the present invention, it is preferable that the surfactant is a fluorine surfactant. By the composition according to the embodiment of the present invention including a fluorine surfactant, liquid characteristics (in particular, fluidity) are further improved, and liquid saving properties can be further improved. In addition, a film having reduced thickness unevenness can be formed.

The fluorine content in the fluorine surfactant is preferably 3% to 40% by mass, more preferably 5% to 30% by mass, and still more preferably 7% to 25% by mass. The fluorine surfactant in which the fluorine content is in the above-described range is effective from the viewpoints of the uniformity in the thickness of the coating film and liquid saving properties, and the solubility thereof in the composition is also excellent.

Specific examples of the fluorine surfactant include a surfactant described in paragraphs “0060” to “0064” of JP2014-041318A (paragraphs “0060” to “0064” of corresponding WO2014/017669A) and a surfactant described in paragraphs “0117” to “0132” of JP2011-132503A, the contents of which are incorporated herein by reference. Examples of a commercially available product of the fluorine surfactant include: MEGAFACE F171, F172, F173, F176, F177, F141, F142, F143, F144, R30, F437, F475, F479, F482, F554, F780, EXP, and MFS-330 (all of which are manufactured by DIC Corporation); FLUORAD FC430, FC431, and FC171 (all of which are manufactured by Sumitomo 3M Ltd.); SURFLON S-382, SC-101, SC-103, SC-104, SC-105, SC-1068, SC-381, SC-383, S-393, and KH-40 (all of which are manufactured by Asahi Glass Co., Ltd.); and POLYFOX PF636, PF656, PF6320, PF6520, and PF7002 (all of which are manufactured by OMNOVA Solutions Inc.).

In addition, as the fluorine surfactant, an acrylic compound in which, in a case where heat is applied to a molecular structure which has a functional group having a fluorine atom, the functional group having a fluorine atom is cut and a fluorine atom is volatilized can also be preferably used. Examples of the fluorine surfactant include MEGAFACE DS series (manufactured by DIC Corporation, The Chemical Daily, Feb. 22, 2016, Nikkei Business Daily, Feb. 23, 2016), for example, MEGAFACE DS-21.

In addition, as the fluorine surfactant, a polymer of a fluorine atom-containing vinyl ether compound having a fluorinated alkyl group or a fluorinated alkylene ether group and a hydrophilic vinyl ether compound is also preferable. The details of this fluorine surfactant can be found in JP2016-216602A, the content of which is incorporated herein by reference.

As the fluorine surfactant, a block polymer can also be used. Examples of the block polymer include a compound described in JP2011-089090A. As the fluorine surfactant, a fluorine-containing polymer compound can be preferably used, the fluorine-containing polymer compound including: a repeating unit derived from a (meth)acrylate compound having a fluorine atom; and a repeating unit derived from a (meth)acrylate compound having 2 or more (preferably 5 or more) alkyleneoxy groups (preferably an ethyleneoxy group and a propyleneoxy group). For example, the following compound can also be used as the fluorine surfactant used in the present invention.

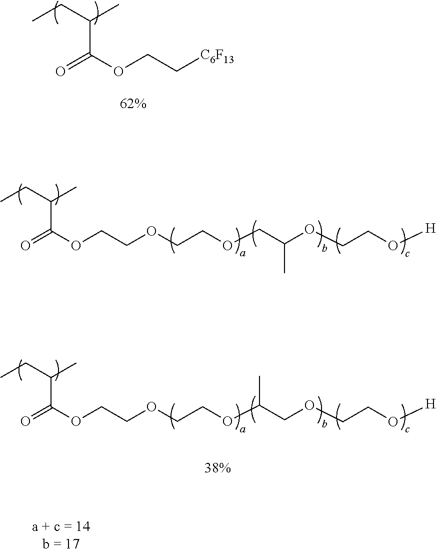

The weight-average molecular weight of the compound is preferably 3,000 to 50,000 and, for example, 14,000. In the compound, “%” representing the proportion of a repeating unit is mol %.

In addition, as the fluorine surfactant, a fluorine-containing polymer having an ethylenically unsaturated group at a side chain can also be used. Specific examples include a compound described in paragraphs “0050” to “0090” and paragraphs “0289” to “0295” of JP2010-164965A, for example, MEGAFACE RS-101, RS-102, RS-718K, and RS-72-K manufactured by DIC Corporation. As the fluorine surfactant, a compound described in paragraphs “0015” to “0158” of JP2015-117327A can also be used.

Examples of the nonionic surfactant include glycerol, trimethylolpropane, trimethylolethane, an ethoxylate and a propoxylate thereof (for example, glycerol propoxylate or glycerol ethoxylate), polyoxyethylene lauryl ether, polyoxyethylenestearyl ether, polyoxyethyleneoleyl ether, polyoxyethyleneoctylphenyl ether, polyoxyethylenenonylphenyl ether, polyethylene glycol dilaurate, polyethylene glycol distearate, sorbitan fatty acid esters, PLURONIC L10, L31, L61, L62, 10R5, 17R2, and 25R2 (manufactured by BASF SE), TETRONIC 304, 701, 704, 901, 904, and 150R1 (manufactured by BASF SE), SOLSPERSE 20000 (manufactured by Lubrication Technology Inc.), NCW-101, NCW-1001, and NCW-1002 (all of which are manufactured by Wako Pure Chemical Industries, Ltd.), PIONIN D-6112, D-6112-W, and D-6315 (all of which are manufactured by Takemoto Oil&Fat Co., Ltd.), and OLFINE E1010 and SURFYNOL 104, 400, and 440 (all of which are manufactured by Nissin Chemical Co., Ltd.).

The content of the surfactant is preferably 0.001% to 5.0% by mass and more preferably 0.005% to 3.0% by mass with respect to the total solid content of the composition according to the embodiment of the present invention. As the surfactant, one kind may be used alone, or two or more kinds may be used. In a case where two or more silane coupling agents are used, it is preferable that the total content is in the above-described range.

<<Ultraviolet Absorber>>

The composition according to the embodiment of the present invention may include an ultraviolet absorber. As the ultraviolet absorber, for example, a conjugated diene compound, an aminobutadiene compound, a methyldibenzoyl compound, a coumarin compound, a salicylate compound, a benzophenone compound, a benzotriazole compound, an acrylonitrile compound, an azomethine compound, indole compound, or a triazine compound can be used. The details of these can be found in paragraphs “0052” to “0072” of JP2012-208374A, paragraphs “0317” to “0334” of JP2013-068814A, and paragraphs “0061” to “0080” of JP2016-162946A, the contents of which are incorporated herein by reference. Examples of a commercially available product of the conjugated diene compound include UV-503 (manufactured by Daito Chemical Co., Ltd.). Specific examples of the indole compound include compounds having the following structures. In addition, as the benzotriazole compound, MYUA series (manufactured by Miyoshi Oil&Fat Co., Ltd.; The Chemical Daily, Feb. 1, 2016) may be used.

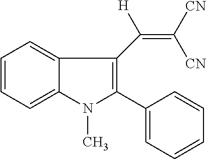 [SMILES: Cn1c(-c2ccccc2)c(C=C(C#N)C#N)c2ccccc21]

In the present invention, as the ultraviolet absorber, compounds represented by Formulae (UV-1) to (UV-3) can also be preferably used.

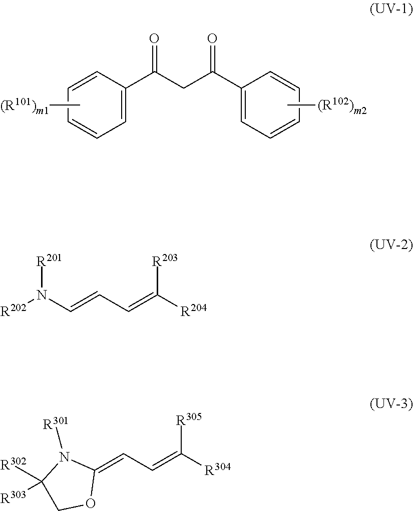

In Formula (UV-1), R¹⁰¹ and R¹⁰² each independently represent a substituent, and m1 and m2 each independently represent 0 to 4. In Formula (UV-2), R²⁰¹ and R²⁰² each independently represent a hydrogen atom or an alkyl group, and R²⁰³ and R²⁰⁴ each independently represent a substituent. In Formula (UV-3), R³⁰¹ to R³⁰³ each independently represent a hydrogen atom or an alkyl group, and R³⁰⁴ and R³⁰⁵ each independently represent a substituent.

Specific examples of the compounds represented by Formulae (UV-1) to (UV-3) include the following compounds.

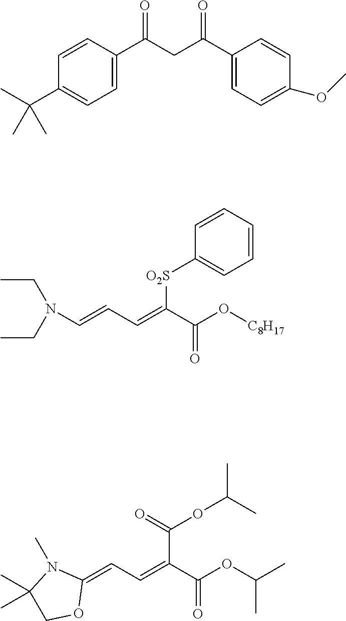

In the composition according to the embodiment of the present invention, the content of the ultraviolet absorber is preferably 0.01% to 10% by mass and more preferably 0.01% to 5% by mass with respect to the total solid content of the composition of the present invention. In the present invention, as the ultraviolet absorber, one kind may be used alone, or two or more kinds may be used. In a case where two or more pigment derivatives are used in combination, it is preferable that the total content of the two or more pigment derivatives is in the above-described range.

<<Antioxidant>>

The composition of according to the embodiment of the present invention may include an antioxidant. Examples of the antioxidant include a phenol compound, a phosphite compound, and a thioether compound. As the phenol compound, any phenol compound which is known as a phenol antioxidant can be used. As the phenol compound, for example, a hindered phenol compound is preferable. A compound having a substituent at a position (ortho position) adjacent to a phenolic hydroxy group is preferable. As the substituent, a substituted or unsubstituted alkyl group having 1 to 22 carbon atoms is preferable. In addition, as the antioxidant, a compound having a phenol group and a phosphite group in the same molecule is also preferable. In addition, as the antioxidant, a phosphorus antioxidant can also be preferably used. Examples of the phosphorus antioxidant include tris[2-[[2,4,8,10-tetrakis(1,1-dimethylethyl)dibenzo[d,f][1,3,2]dioxaphosphepin-6-yl]oxy]ethyl]amine, tris[2-[(4,6,9,11-tetra-tert-butyldibenzo[d,f][1,3,2]dioxaphosphepin-2-yl)oxy]ethyl]amine, and ethyl bis(2,4-di-tert-butyl-6-methylphenyl) phosphite. Examples of the commercially available product of the antioxidant include ADEKA STAB AO-20, ADEKA STAB AO-30, ADEKA STAB AO-40, ADEKA STAB AO-50, ADEKA STAB AO-50F, ADEKA STAB AO-60, ADEKA STAB AO-60G, ADEKA STAB AO-80, and ADEKA STAB AO-330 (all of which are manufactured by ADEKA CORPORATION). In addition, as the antioxidant, a polyfunctional hindered amine antioxidant described in WO17/006600A can also be used.

The content of the antioxidant is preferably 0.01% to 20% by mass and more preferably 0.3% to 15% by mass with respect to the mass of the total solid content of the composition according to the embodiment of the present invention. As the antioxidant, one kind may be used alone, or two or more kinds may be used in combination. In a case where two or more pigment derivatives are used in combination, it is preferable that the total content of the two or more pigment derivatives is in the above-described range.

<<Other Components>>

Optionally, the composition according to the embodiment of the present invention may further include a sensitizer, a curing accelerator, a filler, a thermal curing accelerator, a plasticizer, and other auxiliary agents (for example, conductive particles, a filler, an antifoaming agent, a flame retardant, a leveling agent, a peeling accelerator, an aromatic chemical, a surface tension adjuster, or a chain transfer agent). By including the components, properties such as film properties can be adjusted. The details of the components can be found in, for example, paragraph “0183” of JP2012-003225A (corresponding to paragraph “0237” of US2013/0034812A) and paragraphs “0101” to “0104” and “0107” to “0109” of JP2008-250074A, the contents of which are incorporated herein by reference. In addition, the composition according to the embodiment of the present invention may optionally include a potential antioxidant. The potential antioxidant is a compound in which a portion that functions as the antioxidant is protected by a protective group and this protective group is desorbed by heating the compound at 100° C. to 250° C. or by heating the compound at 80° C. to 200° C. in the presence of an acid/a base catalyst. Examples of the potential antioxidant include a compound described in WO2014/021023A, WO2017/030005A, and JP2017-008219A. Examples of a commercially available product of the potential antioxidant include ADEKA ARKLS GPA-5001 (manufactured by ADEKA CORPORATION).

In addition, it is also preferable that the composition according to the embodiment of the present invention includes a conductive material such as a conductive polymer or carbon. By the composition according to the embodiment of the present invention including the conductive material, the maximum value is likely to be further increased. In a case where the composition according to the embodiment of the present invention including the conductive material, the content of the conductive material is preferably 0.1% to 30% by mass and more preferably 1% to 20% by mass with respect to the total solid content of the composition according to the embodiment of the present invention.

For example, in a case where a film is formed by coating, the viscosity (23° C.) of the composition according to the embodiment of the present invention is preferably 1 to 100 mPa*s. The lower limit is more preferably 2 mPa·s or more and still more preferably 3 mPa·s or more. The upper limit is more preferably 50 mPa·s or less, still more preferably 30 mPa·s or less, and still more preferably 15 mPa·s or less.

A storage container of the compositions according to the embodiment of the present invention is not particularly limited, and a well-known storage container can be used. In addition, as the storage container, in order to suppress infiltration of impurities into the raw materials or the composition, a multilayer bottle in which a container inner wall having a six-layer structure is formed of six kinds of resins or a bottle in which a container inner wall having a seven-layer structure is formed of six kinds of resins is preferably used. Examples of the container include a container described in JP2015-123351A.

The use of the composition according to the embodiment of the present invention is not particularly limited. The composition according to the embodiment of the present invention can be preferably used to form an infrared transmitting filter or the like.

<Method of Preparing Composition>

The composition of according to the embodiment of the present invention can be prepared by mixing the above-described components with each other. During the preparation of the composition, all the components may be dissolved or dispersed in a solvent at the same time to prepare the composition. Optionally, two or more solutions or dispersions to which the respective components are appropriately added may be prepared, and the solutions or dispersions may be mixed with each other during use (during application) to prepare the composition.

In addition, in a case where the composition according to the embodiment of the present invention includes particles of a pigment or the like, it is preferable that a process of dispersing the particles is provided. Examples of a mechanical force used for dispersing the particles in the process of dispersing the particles include compression, squeezing, impact, shearing, and cavitation. Specific examples of the process include a beads mill, a sand mill, a roll mill, a ball mill, a paint shaker, a Microfluidizer, a high-speed impeller, a sand grinder, a flow jet mixer, high-pressure wet granulation, and ultrasonic dispersion. During the pulverization of the particles using a sand mill (beads mill), it is preferable that the process is performed under conditions for increasing the pulverization efficiency, for example, by using beads having a small size and increasing the filling rate of the beads. In addition, it is preferable that rough particles are removed by filtering, centrifugal separation, and the like after pulverization. In addition, as the process and the disperser for dispersing the particles, a process and a disperser described in “Complete Works of Dispersion Technology, Johokiko Co., Ltd., Jul. 15, 2005”, “Dispersion Technique focusing on Suspension (Solid/Liquid Dispersion) and Practical Industrial Application, Comprehensive Reference List, Publishing Department of Management Development Center, Oct. 10, 1978”, and paragraph “0022” JP2015-157893A can be suitably used. In addition, in the process of dispersing the particles, particles may be refined in a salt milling step. A material, a device, process conditions, and the like used in the salt milling step can be found in, for example, JP2015-194521A and JP2012-046629A.

During the preparation of the composition, it is preferable that the composition is filtered through a filter, for example, in order to remove foreign matter or to reduce defects. As the filter, any filter which is used in the related art for filtering or the like can be used without any particular limitation. Examples of a material of the filter include: a fluororesin such as polytetrafluoroethylene (PTFE); a polyamide resin such as nylon (for example, nylon-6 or nylon-6,6); and a polyolefin resin (including a polyolefin resin having a high density and an ultrahigh molecular weight) such as polyethylene or polypropylene (PP). Among these materials, polypropylene (including high-density polypropylene) or nylon is preferable.

The pore size of the filter is suitably about 0.01 to 7.0 μm and is preferably about 0.01 to 3.0 μm and more preferably about 0.05 to 0.5 μm. In a case where the pore size of the filter is in the above-described range, fine foreign matter can be reliably removed. In addition, it is preferable that a fibrous filter material is used. Examples of the fibrous filter material include polypropylene fiber, nylon fiber, and glass fiber. Specific examples include a filter cartridge of SBP type series (for example, SBP008), TPR type series (for example, TPR002 or TPR005), and SHPX type series (for example, SHPX003) all of which are manufactured by Roki Techno Co., Ltd.

In a case where a filter is used, a combination of different filters (for example, a first filter and a second filter) may be used. At this time, the filtering using each of the filters may be performed once, or twice or more.

In addition, a combination of filters having different pore sizes in the above-described range may be used. Here, the pore size of the filter can refer to a nominal value of a manufacturer of the filter. A commercially available filter can be selected from various filters manufactured by Pall Corporation (for example, DFA4201NXEY), Toyo Roshi Kaisha, Ltd., Entegris Japan Co., Ltd. (former Mykrolis Corporation), or Kits Microfilter Corporation. The second filter may be formed of the same material as that of the first filter.

In addition, the filtering using the first filter may be performed only on the dispersion, and the filtering using the second filter may be performed on a mixture of the dispersion and other components.

The total solid content (solid content concentration) of the composition according to the embodiment of the present invention changes depending on a coating method and, for example, is preferably 1% to 50% by mass. The lower limit is preferably 5% by mass or more and more preferably 10% by mass or more. The upper limit is preferably 40% by mass or less and more preferably 30% by mass or less.

<Pattern Forming Method>

Next, a pattern forming method using the composition according to the embodiment of the present invention will be described. It is preferable that a pattern forming method includes: a step of forming a composition layer on a support using the composition according to the embodiment of the present invention; and a step of forming a pattern on the composition layer using a photolithography method or a dry etching method.

It is preferable that the pattern formation using the photolithography method includes: a step of forming a composition layer on a support using the composition according to the embodiment of the present invention; a step of exposing the composition layer in a pattern shape; and a step of forming a pattern by removing a non-exposed portion by development. In addition, the formation of a pattern using a dry etching method can be performed using a method including: forming a composition layer on a support using the composition according to the embodiment of the present invention; curing the composition layer formed on the support to form a cured composition layer; forming a patterned resist layer on the cured composition layer; and dry-etching the cured composition layer with etching gas by using the patterned resist layer as a mask. Hereinafter, each step will be described.

<<Step of Forming Composition Layer>>

In the step of forming a composition layer, a composition layer is formed on a support using the composition according to the embodiment of the present invention. Examples of the support include a substrate formed of a material such as silicon, non-alkali glass, soda glass, PYREX (registered trade name) glass, or quartz glass. In addition, for example, an InGaAs substrate is preferably used. In addition, a charge coupled device (CCD), a complementary metal-oxide semiconductor (CMOS), a transparent conductive film, or the like may be formed on the support. In addition, a black matrix that separates pixels from each other may be formed on the support. In addition, if necessary, an undercoat layer may be provided on the support to improve adhesiveness with a layer above the support, to prevent diffusion of materials, or to make a surface of the substrate flat.

As a method of applying the composition to the support, a well-known method can be used. Examples of the well-known method include: a drop casting method; a slit coating method; a spray coating method; a roll coating method; a spin coating method; a cast coating method; a slit and spin method; a pre-wetting method (for example, a method described in JP2009-145395A); various printing methods including jet printing such as an inkjet method (for example, an on-demand method, a piezoelectric method, or a thermal method) or a nozzle jet method, flexographic printing, screen printing, gravure printing, reverse offset printing, and metal mask printing; a transfer method using a mold or the like; and a nanoimprint lithography method. The application method using an inkjet method is not particularly limited, and examples thereof include a method (in particular, 115 pages to 133 pages) described in “Extension of Use of InkJet—Infinite Possibilities in Patent—” (February, 2005, S. B. Research Co., Ltd.) and methods described in JP2003-262716A, JP2003-185831A, JP2003-261827A, JP2012-126830A, and JP2006-169325A. In addition, the details of the method of applying the resin composition can be found in WO2017/030174A and WO2017/018419A, the contents of which are incorporated herein by reference.

The composition layer formed on the support may be dried (pre-baked). In a case where a pattern is formed through a low-temperature process, pre-baking is not necessarily performed. In a case where pre-baking is performed, the pre-baking temperature is preferably 150° C. or less, more preferably 120° C. or less, and still more preferably 110° C. or less. The lower limit is, for example, 50° C. or more or 80° C. or more. The pre-baking time is preferably 10 to 3,000 seconds, more preferably 40 to 2,500 seconds, and still more preferably 80 to 2,200 seconds. Drying can be performed using a hot plate, an oven, or the like.

(Case where Pattern is Formed Using Photolithography Method)

<<Exposure Step>>

Next, the composition layer is exposed in a pattern shape (exposure step). For example, the composition layer can be exposed in a pattern shape using an exposure device such as a stepper through a mask having a predetermined mask pattern. As a result, an exposed portion can be cured. As radiation (light) used during the exposure, ultraviolet rays such as g-rays or i-rays are preferable, and i-rays are more preferable. For example, the irradiation dose (exposure dose) is preferably 0.03 to 2.5 J/cm², more preferably 0.05 to 1.0 J/cm², and most preferably 0.08 to 0.5 J/cm². The oxygen concentration during exposure can be appropriately selected. The exposure may be performed not only in air but also in a low-oxygen atmosphere having an oxygen concentration of 19 vol % or less (for example, 15 vol %, 5 vol %, or substantially 0 vol %) or in a high-oxygen atmosphere having an oxygen concentration of more than 21 vol % (for example, 22 vol %, 30 vol %, or 50 vol %). In addition, the exposure illuminance can be appropriately set and typically can be selected in a range of 1,000 W/m² to 100,000 W/m² (for example, 5,000 W/m², 15,000 W/m², or 35,000 W/m²). Conditions of the oxygen concentration and conditions of the exposure illuminance may be appropriately combined. For example, conditions are oxygen concentration: 10 vol % and illuminance: 10,000 W/m², or oxygen concentration: 35 vol % and illuminance: 20,000 W/m².

<<Development Step>>

Next, a pattern is formed by removing a non-exposed portion of the exposed composition layer by development. The non-exposed portion of the composition layer can be removed by development using a developer. As a result, a non-exposed portion of the composition layer in the exposure step is eluted into the developer, and only the photocured portion remains on the support. As the developer, an alkali developer which does not cause damages to a solid image pickup element as an underlayer, a circuit or the like is desired. For example, the temperature of the developer is preferably 20° C. to 30° C. The development time is preferably 20 to 180 seconds. In addition, in order to further improve residue removing properties, a step of shaking the developer off per 60 seconds and supplying a new developer may be repeated multiple times.

Examples of the alkaline agent used as the developer include: an organic alkaline compound such as ammonia water, ethylamine, diethylamine, dimethylethanolamine, diglycolamine, diethanolamine, hydroxyamine, ethylenediamine, tetramethylammonium hydroxide, tetraethylammonium hydroxide, tetrapropylammonium hydroxide, tetrabutylammonium hydroxide, ethyltrimethylammonium hydroxide, benzyltrimethylammonium hydroxide, dimethyl bis(2-hydroxyethyl)ammonium hydroxide, choline, pyrrole, piperidine, or 1,8-diazabicyclo[5.4.0]-7-undecene; and an inorganic alkaline compound such as sodium hydroxide, potassium hydroxide, sodium carbonate, sodium bicarbonate, sodium silicate, or sodium metasilicate. From the viewpoints of environment and safety, it is preferable that the alkaline agent is a compound having a high molecular weight. As the developer, an alkaline aqueous solution in which the above alkaline agent is diluted with pure water is preferably used. A concentration of the alkaline agent in the alkaline aqueous solution is preferably 0.001 to 10% by mass and more preferably 0.01% to 1% by mass. Further, a surfactant may be used for the developer. Examples of the surfactant include the above-described surfactants. Among these, a nonionic surfactant is preferable. From the viewpoint of easiness of transport, storage, and the like, the developer may be obtained by temporarily preparing a concentrated solution and diluting the concentrated solution to a necessary concentration during use. The dilution factor is not particularly limited and, for example, can be set to be in a range of 1.5 to 100 times. In a case where a developer including the alkaline aqueous solution is used, it is preferable that the layer is washed (rinsed) with pure water after development.

In the present invention, after a development step, after drying, a curing step of curing by a heat treatment (post-baking) or post-exposure may be performed.

Post-baking is a heat treatment which is performed after development to complete curing. For example, the heating temperature during post-baking is preferably 100° C. to 240° C. and more preferably 200° C. to 240° C. In addition, in a case where an organic electroluminescence (organic EL) element is used as a light-emitting light source, or in a case where a photoelectric conversion film of an image sensor is formed of an organic material, the heating temperature is preferably 150° C. or lower, more preferably 120° C. or lower, still more preferably 100° C. or lower, and even still more preferably 90° C. or lower. The lower limit is, for example, 50° C. or more. Post-baking can be performed continuously or batchwise using heating means such as a hot plate, a convection oven (hot air circulation dryer), a high-frequency heater under the above-described conditions.

For post-exposure, for example, g-rays, h-rays, i-rays, an excimer laser such as KrF or ArF, electron beams, or X-rays can be used. It is preferable that post-exposure is performed using an existing high-pressure mercury lamp at a low temperature of about 20° C. to 50° C. The irradiation time is 10 seconds to 180 seconds and preferably 30 seconds to 60 seconds. In a case where post-exposure and post-baking are performed in combination, it is preferable that post-exposure is performed before post-baking.

(Case where Pattern is Formed Using Dry Etching Method)

The formation of a pattern using a dry etching method can be performed using a method including: curing the composition layer on the support to form a cured composition layer; forming a patterned resist layer on the cured composition layer; and dry-etching the cured composition layer with etching gas by using the patterned resist layer as a mask. As a process of forming the resist layer, heat treatment after exposure or baking after development (post-baking) is preferably performed. The details of the pattern formation using the dry etching method can be found in paragraphs “0010” to “0067” of JP2013-064993A, the content of which is incorporated herein by reference.

By performing the respective steps as described above, a pattern (pixel) of the film having the specific spectral characteristics according to the embodiment of the present invention can be formed.

<Film>

Next, a film according to the embodiment of the present invention will be described. The film according to the embodiment of the present invention is obtained from the above-described composition according to the embodiment of the present invention. The film according to the embodiment of the present invention can be preferably used as an infrared transmitting filter.

It is preferable that the film according to the embodiment of the present invention has a maximum value of a refractive index in a wavelength range of 800 nm or longer and has the following spectral characteristics (IR11) or (IR12).

(IR11): an aspect in which a maximum value of a light transmittance in a thickness direction in a wavelength range of 400 to 830 nm is 20% or lower (preferably 15% or lower and more preferably 10% or lower), and a minimum value of a light transmittance of the film in the thickness direction in a wavelength range of 1,000 to 1,500 nm is 70% or higher (preferably 75% or higher and more preferably 80% or higher). According to this aspect, a filter that blocks light in a wavelength range of 400 to 830 nm and transmits light having a wavelength of longer than 900 nm can be formed.

(IR12): an aspect in which a maximum value of a light transmittance in a thickness direction in a wavelength range of 400 to 950 nm is 20% or lower (preferably 15% or lower and more preferably 10% or lower), and a minimum value of a light transmittance of the film in the thickness direction in a wavelength range of 1,100 to 1,500 nm is 70% or higher (preferably 75% or higher and more preferably 80% or higher). According to this aspect, a filter that blocks light in a wavelength range of 400 to 950 nm and transmits light having a wavelength of longer than 1,000 nm can be formed.

The thickness of the film according to the embodiment of the present invention can be adjusted according to the purpose. The thickness is preferably 100 μm or less, more preferably 15 μm or less, still more preferably 5 μm or less, and still more preferably 1 μm or less. The lower limit of the film thickness is preferably 0.1 μm or more, more preferably 0.2 μm or more, and still more preferably 0.3 μm or more.

In the film according to the embodiment of the present invention, the maximum value of the above-described refractive index is preferably 1.8 or higher, more preferably 1.85 or higher, and still more preferably 1.9 or higher. In addition, it is preferable that the maximum value of the above-described refractive index in the film according to the embodiment of the present invention is present on a longer wavelength side than a maximum absorption wavelength of the near infrared absorbing colorant in the composition used in the film according to the embodiment of the present invention, it is more preferable that the maximum value of the above-described refractive index is present on a longer wavelength side than the maximum absorption wavelength of the above-described near infrared absorbing colorant by 15 nm or longer, and it is still more preferable that the maximum value of the above-described refractive index is present on a longer wavelength side than the maximum absorption wavelength of the above-described near infrared absorbing colorant by 30 nm or longer. In addition, the maximum value of the above-described refractive index is present preferably in a wavelength range of 800 to 1,000 nm, more preferably in a wavelength range of 830 to 970 nm, and in a wavelength range of 860 to 940 nm.

In a case where the film according to the embodiment of the present invention is used for an infrared sensor or the like, the refractive index of the film according to the embodiment of the present invention with respect to light (infrared light) having a wavelength used for sensing in the infrared sensor or the like is preferably 1.6 to 2.1. The lower limit is preferably 1.65 or more and more preferably 1.7 or more. The upper limit is preferably 2.0 or less and more preferably 1.9 or less. Examples of the light (infrared light) used for the above-described sensing include any light in a wavelength range of 850 to 1,000 nm. For example, 850 nm, 900 nm, or 940 nm can be used.

The film according to the embodiment of the present invention can be used in various devices including a solid image pickup element such as a charge coupled device (CCD) or a complementary metal-oxide semiconductor (CMOS), an infrared sensor, or an image display device.

<Optical Filter>

Next, the optical filter according to the embodiment of the present invention will be described.

An optical filter according to a first embodiment of the present invention comprises: a first pixel that is obtained using the above-described composition according to the embodiment of the present invention; and a second pixel that is adjacent to the first pixel and is different from the first pixel.

In addition, an optical filter according to a second embodiment of the present invention comprises:

a first pixel in which a ratio A/B of a minimum value A of an absorbance in a wavelength range of 400 to 700 nm to a maximum value B of an absorbance in a wavelength range of 1,400 to 1,500 nm is 4.5 or higher and a maximum value of a refractive index is in a wavelength range of 800 nm or longer; and

a second pixel that is adjacent to the first pixel and is different from the first pixel,

in which a difference (t1−t2) between a refractive index t1 of the first pixel and a refractive index t2 of the second pixel is larger than −0.1 in at least a part of a wavelength range of 900 to 1,400 nm (preferably at least a part of a wavelength of 900 to 1,000 nm).

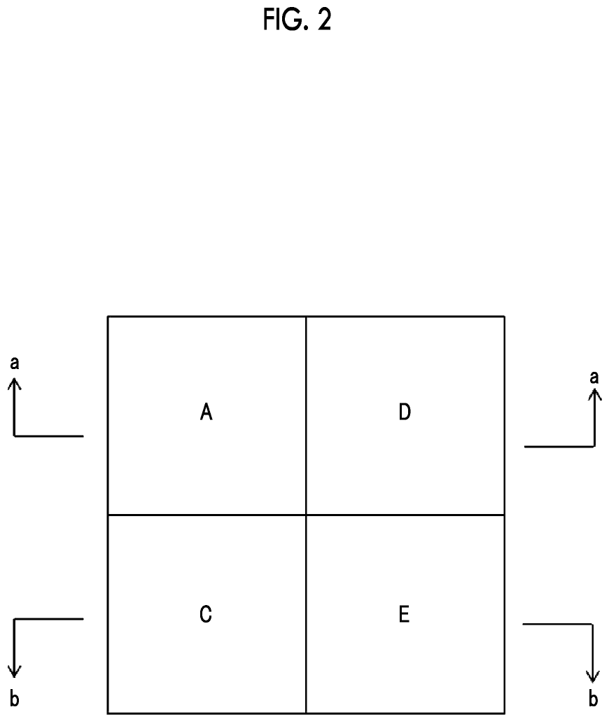

In the first and second embodiments of the optical filter according to the present invention, the second pixel is not particularly limited as long as it is different from the first pixel. For example, a colored pixel, a transparent pixel, a pixel of an infrared transmitting filter, or a pixel of a near infrared cut filter can be used. Examples of the colored pixel include a red pixel, a green pixel, a blue pixel, a magenta pixel, a yellow pixel, and a cyan pixel. In addition, as the second pixel, only one kind may be used, or two or more kinds may be used. That is, as the second pixel adjacent to the first pixel, only one kind may be used, or two or more kinds may be used. For example, in FIG. 2, in a case where it is assumed that a pixel represented by reference numeral E is a first pixel, a pixel represented by reference numeral C adjacent to the pixel of reference numeral E and a pixel represented by reference numeral D may be the same kind of pixels (for example, a case where the pixel represented by reference numeral C and the pixel represented by reference numeral D are blue pixels) or may be different kinds of pixels (for example, a case where the pixel represented by reference numeral C is a green pixel and the pixel represented by reference numeral D is a yellow pixel).

In the second embodiment of the optical filter according to the present invention, the difference (t1−t2) between the above-described refractive indices is preferably −0.05 or higher and more preferably 0 or higher. In addition, in the second embodiment, in a case where plural kinds of second pixels are adjacent to the first pixel, it is preferable that the difference (t1−t2) in refractive index between each of the second pixels and the first pixel is larger than −0.1. For example, in FIG. 2, in a case where it is assumed that the pixel represented by reference numeral E is the first pixel, it is preferable that the difference (t1−t2) in refractive index between each of the pixel represented by reference numeral C and the pixel represented by reference numeral D that are adjacent to the pixel represented by reference numeral E and the first pixel is larger than −0.1.

In the first and second embodiments of the optical filter according to the present invention, It is preferable that the first pixel has a maximum value of a refractive index in a wavelength range of 800 nm or longer and has the following spectral characteristics (IR111) or (IR112).

(IR111): an aspect in which a maximum value of a light transmittance in a thickness direction in a wavelength range of 400 to 830 nm is 20% or lower (preferably 15% or lower and more preferably 10% or lower), and a minimum value of a light transmittance of the film in the thickness direction in a wavelength range of 1,000 to 1,500 nm is 70% or higher (preferably 75% or higher and more preferably 80% or higher). According to this aspect, a pixel that blocks light in a wavelength range of 400 to 830 nm and transmits light having a wavelength of longer than 900 nm can be formed.

(IR112): an aspect in which a maximum value of a light transmittance in a thickness direction in a wavelength range of 400 to 950 nm is 20% or lower (preferably 15% or lower and more preferably 10% or lower), and a minimum value of a light transmittance of the film in the thickness direction in a wavelength range of 1,100 to 1,500 nm is 70% or higher (preferably 75% or higher and more preferably 80% or higher). According to this aspect, a pixel that blocks light in a wavelength range of 400 to 950 nm and transmits light having a wavelength of longer than 1,000 nm can be formed.

In the first and second embodiments of the optical filter according to the present invention, the maximum value of the above-described refractive index of the first pixel is preferably 1.8 or higher, more preferably 1.85 or higher, and still more preferably 1.9 or higher. In addition, the maximum value of the above-described refractive index is present preferably in a wavelength range of 800 to 1,000 nm, more preferably in a wavelength range of 830 to 970 nm, and in a wavelength range of 860 to 940 nm.

In a case where the optical filter according to the embodiment of the present invention is used for an infrared sensor or the like, the refractive index of the first pixel with respect to light (infrared light) having a wavelength used for sensing in the infrared sensor or the like is preferably 1.6 to 2.1. The lower limit is preferably 1.65 or more and more preferably 1.7 or more. The upper limit is preferably 2.0 or less and more preferably 1.9 or less. Examples of the light (infrared light) used for the above-described sensing include any light in a wavelength range of 850 to 1,000 nm. For example, 850 nm, 900 nm, or 940 nm can be used.

The optical filter according to the embodiment of the present invention can be used in various devices including a solid image pickup element such as a charge coupled device (CCD) or a complementary metal-oxide semiconductor (CMOS), an infrared sensor, or an image display device.

<Solid Image Pickup Element>

A solid image pickup element according to the present invention includes the above-described film or optical filter according to the present invention. The solid image pickup element according to the present invention is configured to include the film or optical filter according to the present invention. The configuration of the solid image pickup element is not particularly limited as long as the solid image pickup element functions. For example, the following configuration can be adopted.

The solid image pickup element includes a plurality of photodiodes and transfer electrodes on the support, the photodiodes constituting a light receiving area of the solid image pickup element (for example, a CCD image sensor or a CMOS image sensor), and the transfer electrode being formed of polysilicon or the like. In the solid image pickup element, a light blocking film formed of tungsten or the like which has openings through only light receiving sections of the photodiodes is provided on the photodiodes and the transfer electrodes, a device protective film formed of silicon nitride or the like is formed on the light blocking film so as to cover the entire surface of the light blocking film and the light receiving sections of the photodiodes, and the film or the optical filter according to the embodiment of the present invention is formed on the device protective film. Further, a configuration in which light collecting means (for example, a microlens; hereinafter, the same shall be applied) is provided above the device protective film and below the film or the optical filter according to the embodiment of the present invention (on a side thereof close the support), or a configuration in which light collecting means is provided on the film or the optical filter according to the embodiment of the present invention may be adopted.

<Infrared Sensor>

An infrared sensor according to the present invention includes the above-described film or optical filter according to the present invention. The configuration of the infrared sensor is not particularly limited as long as it functions as an infrared sensor. Hereinafter, an embodiment of the infrared sensor used in the present invention will be described using the drawings.

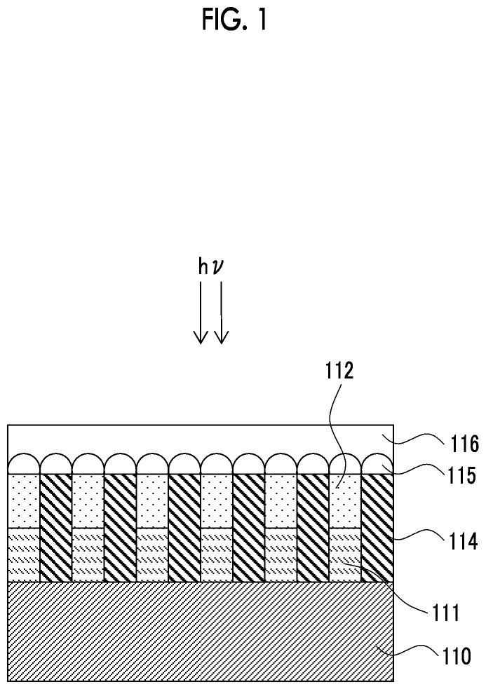

In FIG. 1, reference numeral 110 represents a solid image pickup element. In an imaging region provided on a solid image pickup element 110, near infrared cut filters 111 and infrared transmitting filters 114 are provided. In addition, color filters 112 are laminated on the near infrared cut filters 111. Microlenses 115 are disposed on an incidence ray hv side of the color filters 112 and the infrared transmitting filters 114. A planarizing layer 116 is formed so as to cover the microlenses 115.

The near infrared cut filters 111 are filters that allow transmission of light in a visible light range (for example, light in a wavelength range of 400 to 700 nm) and block light in a infrared range. The color filters 112 is not particularly limited as long as pixels which allow transmission of light having a specific wavelength in a visible range and absorbs the light are formed therein, and well-known color filters of the related art for forming a pixel can be used. For example, pixels of red (R), green (G), and blue (B) are formed in the color filters. For example, the details of the polymerizable compound can be found in paragraphs “0214” to “0263” of JP2014-043556 content of which is incorporated herein by reference. The infrared transmitting filters 114 have visible light blocking properties, allow transmission of infrared light having a specific wavelength, and are formed of the film according to the embodiment of the present invention having the above-described spectral characteristics.

In the infrared sensor shown in FIG. 1, a near infrared cut filter (other near infrared cut filter) other than the near infrared cut filter 111 may be further disposed on the planarizing layer 116. As the other near infrared cut filter, for example, a layer containing copper and/or a dielectric multi-layer film may be provided. The details of the groups are as described above. In addition, as the other near infrared cut filter, a dual band pass filter may be used.

In addition, in the embodiment shown in FIG. 1, the color filters 112 are provided on the incidence ray hv side compared to the near infrared cut filter 111. The lamination order of the near infrared cut filter 111 and the color filters 112 may be reversed, and the near infrared cut filter 111 may be provided on the incidence ray hv side compared to the color filters 112.

In addition, in the embodiment shown in FIG. 1, the near infrared cut filters 111 and the color filters 112 are laminated adjacent to each other. However, the near infrared cut filters 111 and the color filters 112 are not necessarily provided adjacent to each other, and another layer may be provided therebetween.

In addition, in the embodiment shown in FIG. 1, another infrared transmitting filter having spectral characteristics different from those of the infrared transmitting filter 114 may be further provided.

<Image Display Device>

The film or optical filter according to the present invention can also be used in an image display device such as a liquid crystal display device or an organic electroluminescence (organic EL) display device. The definition of a display device and the details of each display device can be found in, for example, “Electronic Display Device (by Akiya Sasaki, Kogyo Chosakai Publishing Co., Ltd., 1990)” or “Display Device (Sumiaki Ibuki, Sangyo Tosho Co., Ltd.). In addition, the details of a liquid crystal display device can be found in, for example, “Next-Generation Liquid Crystal Display Techniques (Edited by Tatsuo Uchida, Kogyo Chosakai Publishing Co., Ltd., 1994)”. The type of the liquid crystal display device to which the embodiment of the present invention is applicable is not particularly limited. For example, the present invention is applicable to various liquid crystal display devices described in “Next-Generation Liquid Crystal Display Techniques”.

The image display device may include a white organic EL element as a display element. It is preferable that the white organic EL element has a tandem structure. The tandem structure of the organic EL element is described in, for example, JP2003-045676A, or pp. 326-328 of “Forefront of Organic EL Technology Development—Know-How Collection of High Brightness, High Precision, and Long Life” (Technical Information Institute, 2008). It is preferable that a spectrum of white light emitted from the organic EL element has high maximum emission peaks in a blue range (430 nm to 485 nm), a green range (530 nm to 580 nm), and a yellow range (580 nm to 620 nm). It is more preferable that the spectrum has a maximum emission peak in a red range (650 nm to 700 nm) in addition to the above-described emission peaks.

### EXAMPLES

Hereinafter, the present invention will be described in more detail using examples. However, the present invention is not limited to the following examples as long as it does not depart from the scope of the present invention. Unless specified otherwise, “part(s)” and “%” represent “part(s) by mass” and “% by mass”.

<Preparation of Dispersion>

After mixing raw materials shown in the following table, further 230 parts by mass of zirconia beads having a diameter of 0.3 mm were added to the mixture, and the solution was dispersed using a paint shaker for 5 hours. Next, the beads were separated by filtration. As a result, a dispersion was manufactured.

TABLE 1

| | Color Material, Near | | | | | | | |
|---|---|---|---|---|---|---|---|---|
| | Infrared Absorbing Colorant, | | | | | | | |
| | Inorganic Particle | | Pigment Derivative | | Dispersant | | Solvent | |
| | | Part(s) | | Part(s) | | Part(s) | | Part(s) |
| | Type | by Mass | Type | by Mass | Type | by Mass | Type | by Mass |
| Dispersion R-2 | PR254 | 8.3 | B1 | 2.3 | C2 | 4.4 | J1 | 81.3 |
| | PY139 | 3.7 | | | | | | |
| Dispersion B-1 | PB15:6 | 12.6 | | | C2 | 4.4 | J1 | 83.0 |
| Dispersion B-2 | PB15:6 | 10.0 | | | C2 | 4.4 | J1 | 83.0 |
| | PV23 | 2.6 | | | | | | |
| Dispersion G-1 | PG36 | 12 | | | C2 | 6.0 | J1 | 83.0 |
| | PY150 | 1.8 | | | | | | |
| | PY185 | 0.7 | | | | | | |
| Dispersion Bk-1 | IB | 12.6 | | | C1 | 4.4 | J1 | 83.0 |
| Dispersion Bk-2 | PBk 32 | 12.6 | | | C2 | 4.4 | J1 | 83.0 |
| Dispersion Bk-3 | PR254 | 6.9 | | | C3 | 8.1 | J1 | 73.9 |
| | PY139 | 4.0 | | | | | | |
| | PB15:6 | 7.1 | | | | | | |
| Dispersion Bk-4 | IB | 11.3 | | | C4 | 5.63 | J1 | 79.32 |
| | PB15:6 | 3.75 | | | | | | |
| Dispersion IR-1 | K1 | 11.0 | B1 | 1.6 | C2 | 6.0 | J1 | 81.4 |
| Dispersion IR-3 | K2 | 6.7 | K4 | 0.8 | C3 | 6.0 | J1 | 86.5 |
| Dispersion T-1 | TiO2 | 10.0 | | | C3 | 4.0 | J1 | 86.0 |
| Dispersion Y-1 | PY139 | 11.0 | B1 | 1.6 | C2 | 4.4 | J1 | 83.0 |
| Dispersion V-1 | PV23 | 14.2 | B1 | 2.0 | C2 | 3.8 | J1 | 70.0 |
| | | | | | | | J2 | 10.0 |
| Dispersion Bk-5 | PR254 | 6.2 | B2-1 | 0.45 | C3 | 8.1 | J1 | 73.9 |
| | PY139 | 3.6 | B2-2 | 0.45 | | | | |
| | PB15:6 | 6.4 | B2-3 | 0.45 | | | | |
| | | | B2-4 | 0.45 | | | | |

<Preparation of Infrared Transmitting Filter-Forming Composition>

Raw materials shown in the following tables were mixed with each other to prepare compositions 101 to 114 and 401 to 410. Numerical values in table are represented by “part(s) by mass”.

In addition, in a case where a film having a thickness of 1 μm is formed using each of the compositions, a wavelength at which the refractive index is the maximum value, the maximum value of the refractive index, and an absorbance ratio A/B are shown together. The absorbance ratio A/B a ratio (A/B) of a minimum value A of an absorbance of the composition in a wavelength range of 400 to 700 nm to a maximum value B of an absorbance of the composition in a wavelength range of 1,400 to 1,500 nm. In addition, the refractive index and the absorbance were measured using the following methods.

Each of the compositions was applied to a glass substrate using a spin coater (manufactured by Mikasa Co., Ltd.) such that the thickness after pre-baking was 1 μm. As a result, a coating film was formed. Next, the coating film was heated (pre-baked) using a hot plate at 100° C. for 120 seconds. Next, the entire surface of the coating film was exposed using an i-ray stepper exposure device FPA-3000 i5+ (manufactured by Canon Corporation) at an exposure dose of 1,000 mJ/cm2 and then was heated (post-baked) again using a hot plate at 200° C. for 300 seconds. As a result, a film was obtained. Regarding the obtained film, the refractive index in a wavelength range of 400 to 1,500 nm was measured using an ellipsometer VUV-VASE (manufactured by J. A. Woollam Co., Inc.), and the wavelength (nm) at which the refractive index was the maximum value and the maximum value of the refractive index were measured. In addition, regarding the obtained film, the absorbance of light in a wavelength range of 400 to 1,500 nm was measured, and the ratio (A/B) of the minimum value A of an absorbance in a wavelength range of 400 to 700 nm to the maximum value B of an absorbance in a wavelength range of 1,400 to 1,500 nm was calculated.

The compositions 101, 103 to 114, and 401 to 410 are the compositions according to Examples of the present invention. The composition 102 is the composition according to Comparative Example.

TABLE 2

| | | Composition | Composition | Composition | Composition | Composition | Composition | Composition |
|---|---|---|---|---|---|---|---|---|
| | | 101 | 102 | 103 | 104 | 105 | 106 | 107 |
| Dispersion | Bk-3 | 49.01 | 49.01 | 49.01 | 49.01 | 49.01 | 49.01 | 39.21 |
| | IR-1 | 26.11 | | 26.11 | 26.11 | | 13.05 | |
| | IR-3 | | | | | | | 31.33 |
| | T-1 | | | 5.00 | | | | |
| | R-2 | | | | | | | |
| | Y-1 | | | | | | | |
| | V-1 | | | | | | | |
| | B-1 | | | | | | | |
| | B-2 | | | | | | | |
| | Bk-1 | | | | | | | |
| | Bk-2 | | | | | | | |
| | Bk-4 | | | | | | | |
| Near Infrared Absorbing | N1 | | | | | 3.29 | 1.65 | |
| Colorant | | | | | | | | |
| Polymerizable Compound | D1 | | | | | | | |
| | D2 | | | | | | | |
| | D3 | | | | | | | |
| | D4 | 2.87 | 5.88 | 2.29 | 1.44 | 2.87 | | 2.87 |
| | D5 | | | | | | | |
| | D6 | | | | | | | |
| | D8 | | | | 1.44 | | | |
| Photopolymerization | I1 | 0.261 | 0.534 | 0.209 | 0.261 | 0.261 | 0.261 | 0.261 |
| Initiator | I2 | 0.910 | 1.863 | 0.727 | 0.910 | 0.910 | 0.910 | 0.910 |
| | I3 | | | | | | | |
| | I4 | | | | | | | |
| | I6 | | | | | | | |
| Resin | P1 | 1.64 | 3.36 | 1.31 | | 5.75 | 3.7 | 1.64 |
| | P2 | | | | | | | |
| | P3 | | | | | | | |
| | P4 | | | | 2.29 | | | |
| Ultraviolet Absorber | L1 | | | | | | | |
| Polyfunctional Thiol | M1 | | | | | | | |
| Surfactant | F1 | 0.05 | 0.10 | 0.04 | 0.05 | 0.05 | 0.05 | 0.05 |
| Polymerization Inhibitor | G1 | 0.0014 | 0.0029 | 0.0011 | 0.0014 | 0.0014 | 0.0014 | 0.0014 |
| Solvent | J1 | 19.20 | 39.31 | 15.35 | 18.50 | 35.96 | 29.47 | 23.73 |
| | J3 | | | | | 1.90 | | |
| | J4 | | | | | | 1.90 | |

| | | | | | | | |
|---|---|---|---|---|---|---|---|
| Wavelength [nm] at which Refractive | 880 | 780 | 880 | 880 | 890 | 890 | 880 |
| Index reaches Maximum Value when Film | | | | | | | |
| with Thickness of 1 μm is formed | | | | | | | |
| Maximum Value of Refractive Index | 1.91 | 1.78 | 2.10 | 1.99 | 1.89 | 1.98 | 1.96 |
| Absorbance Ratio A/B | 67 | 38 | 69 | 67 | 46 | 74 | 65 |

| | | Composition | Composition | Composition | Composition | Composition | Composition | Composition |
|---|---|---|---|---|---|---|---|---|
| | | 108 | 109 | 110 | 111 | 112 | 113 | 114 |
| Dispersion | Bk-3 | 49.01 | 49.01 | | | | | |
| | IR-1 | 26.11 | 26.11 | 26.11 | 26.11 | 26.11 | 26.11 | 26.11 |
| | IR-3 | | | | | | | |
| | T-1 | | | | | | | |
| | R-2 | | | 11.03 | | | | |
| | Y-1 | | | 8.45 | 9.65 | 4.62 | | 20.24 |
| | V-1 | | | 4.94 | | | | 7.95 |
| | B-1 | | | 24.60 | 9.65 | | | 20.81 |
| | B-2 | | | | | 12.02 | | |
| | Bk-1 | | | | | 32.37 | | |
| | Bk-2 | | | | 29.70 | | | |
| | Bk-4 | | | | | | 49.01 | |
| Near Infrared Absorbing | N1 | | | | | | | |
| Colorant | | | | | | | | |
| Polymerizable Compound | D1 | | | 0.80 | 1.89 | | | 4.20 |
| | D2 | | | 1.00 | | | | |
| | D3 | | | 0.80 | | | | |
| | D4 | 2.87 | 2.87 | | | | | |
| | D5 | | | | | 1.98 | | |
| | D6 | | | | | | 2.56 | |
| | D8 | | | | | | | |
| Photopolymerization | I1 | | 0.261 | | | | | |
| Initiator | I2 | 0.910 | 0.910 | | | 0.344 | | 0.500 |
| | I3 | 0.261 | | 0.540 | 0.555 | | | |
| | I4 | | | 0.400 | | 0.340 | | |
| | I6 | | | | | | 0.210 | |
| Resin | P1 | 1.64 | | 2.99 | 2.53 | 2.95 | | 2.05 |
| | P2 | | 1.64 | | | | | |
| | P3 | | | | | | 5.7 | |
| | P4 | | | | | | | |
| Ultraviolet Absorber | L1 | | | | 0.1 | | | |
| Polyfunctional Thiol | M1 | | | | | | | 0.2 |
| Surfactant | F1 | 0.05 | 0.05 | 0.04 | 0.04 | 0.04 | 0.04 | 0.04 |
| Polymerization Inhibitor | G1 | 0.0014 | 0.0014 | 0.0013 | 0.0009 | 0.001 | 0.0013 | 0.0013 |
| Solvent | J1 | 19.20 | 19.20 | 18.31 | 19.76 | 18 | 16.37 | 17.89 |
| | J3 | | | | | | | |
| | J4 | | | | | 1.23 | | |

| | | | | | | | |
|---|---|---|---|---|---|---|---|
| Wavelength [nm] at which Refractive | 880 | 880 | 880 | 880 | 880 | 880 | 880 |
| Index reaches Maximum Value when Film | | | | | | | |
| with Thickness of 1 μm is formed | | | | | | | |
| Maximum Value of Refractive Index | 1.91 | 1.99 | 1.86 | 1.88 | 1.89 | 1.89 | 1.86 |
| Absorbance Ratio A/B | 67 | 67 | 66 | 66 | 67 | 67 | 66 |

TABLE 3

| | | Composition | Composition | Composition | Composition | Composition |
|---|---|---|---|---|---|---|
| | | 401 | 402 | 403 | 404 | 405 |
| Dispersion | Bk-3 | | | | 52.58 | |
| | IR-1 | | 26.11 | 26.11 | | 26.11 |
| | IR-3 | 28.01 | | | 28.01 | |
| | Bk-4 | | 49.01 | 49.01 | | 49.01 |
| | Bk-5 | 52.58 | | | | |
| | T-1 | | | | | |
| Polymerizable Compound | D4 | 2.93 | 2.56 | 2.56 | | 1.06 |
| | D11 | | | | 2.93 | 1.5 |
| | D12 | | | | | |
| High Refractive Index | T10 | | | | | |
| Compound | | | | | | |
| Photopolymerization | I1 | | 1.2 | 1.2 | | |
| Initiator | I2 | 1.20 | | | 1.79 | 1.2 |
| Resin | P4 | | | | | 2.09 |
| | P7 | 1.38 | 2.09 | 2.09 | 1.38 | |
| | P8 | | 2.62 | | | |
| | P9 | | | 2.1 | | 2.1 |
| | P10 | | | | | |
| Epoxy Compound | E1 | 0.59 | | | | |
| Surfactant | F1 | 0.046 | 0.046 | 0.046 | 0.046 | 0.046 |
| Polymerization Inhibitor | G1 | 0.0014 | 0.013 | 0.013 | 0.0014 | 0.013 |
| Solvent | J1 | 13.27 | 16.37 | 6.88 | 13.27 | 6.88 |
| | J3 | | | 10.0 | | 10.0 |
| Wavelength [nm] at which Refractive Index | | 880 | 880 | 880 | 880 | 880 |
| reaches Maximum Value when Film with | | | | | | |
| Thickness of 1 μm is formed | | | | | | |
| Maximum Value of Refractive Index | | 1.91 | 2.08 | 2.01 | 2.03 | 2.11 |
| Absorbance Ratio A/B | | 77 | 67 | 67 | 77 | 67 |
| | | Composition | Composition | Composition | Composition | Composition |
| | | 406 | 407 | 408 | 409 | 410 |
| Dispersion | Bk-3 | | 52.58 | 51.58 | | |
| | IR-1 | 26.11 | | | 25.11 | |
| | IR-3 | | 28.01 | 27.01 | | 28.01 |
| | Bk-4 | 49.01 | | | 48.01 | |
| | Bk-5 | | | | | 52.58 |
| | T-1 | | | 5.00 | 5.00 | |
| Polymerizable Compound | D4 | 2.56 | | | 2.56 | |
| | D11 | | | | | |
| | D12 | | 2.93 | 2.93 | | 2.42 |
| High Refractive Index | T10 | | | | | 0.51 |
| Compound | | | | | | |
| Photopolymerization | I1 | | | | | |
| Initiator | I2 | 1.2 | 1.79 | 1.79 | 1.2 | 1.79 |
| Resin | P4 | 2.09 | | | 2.09 | |
| | P7 | | 1.38 | 1.38 | | 1.38 |
| | P8 | | | | | |
| | P9 | | | | | |
| | P10 | 2.1 | | | 2.1 | |
| Epoxy Compound | E1 | | | | | |
| Surfactant | F1 | 0.046 | 0.046 | 0.046 | 0.046 | 0.046 |
| Polymerization Inhibitor | G1 | 0.013 | 0.0014 | 0.0014 | 0.013 | 0.0014 |
| Solvent | J1 | 16.88 | 13.27 | 10.27 | 13.88 | 13.27 |
| | J3 | | | | | |

| | | | | | |
|---|---|---|---|---|---|
| Wavelength [nm] at which Refractive Index | 880 | 880 | 880 | 880 | 880 |
| reaches Maximum Value when Film with | | | | | |
| Thickness of 1 μm is formed | | | | | |
| Maximum Value of Refractive Index | 2.09 | 2.05 | 2.15 | 2.15 | 2.07 |
| Absorbance Ratio A/B | 67 | 77 | 77 | 67 | 77 |

<Preparation of Color Filter-Forming Composition>

Raw materials shown in the following tables were mixed with each other to prepare compositions 201 to 203. Numerical values in table are represented by “part(s) by mass”.

TABLE 4

| | | Composition | Composition | Composition |
|---|---|---|---|---|
| | | 201 | 202 | 203 |
| Dispersion | R-2 | 85.00 | | |
| | B-2 | | | 50.00 |
| | G-1 | | 70.00 | |
| Polymerizable | D4 | | | 5.20 |
| Compound | D5 | | 2.50 | |
| | D9 | 2.80 | | |
| | D10 | | 1.30 | |
| Silane Coupling Agent | H1 | 1.00 | 0.40 | 0.90 |
| Photopolymerization | I1 | 0.500 | 1.650 | 1.250 |
| Initiator | | | | |
| Resin | P1 | | 1.20 | |
| | P5 | | | 5.6 |
| | P6 | 4.7 | | |
| Surfactant | F1 | 0.04 | 0.04 | 0.04 |
| Polymerization | G1 | 0.0014 | 0.0020 | 0.0010 |
| Inhibitor | | | | |
| Solvent | J1 | 5.96 | 22.91 | 37.01 |

<Preparation of ear Infared Cut Filter-Forming Composition>

Raw materials shown in the following tables were mixed with each other to prepare a composition 301. Numerical values in table are represented by “part(s) by mass”.

TABLE 5

| | | Composition |
|---|---|---|
| | | 301 |
| Near Infrared Absorbing Colorant | N2 | 1.75 |
| Polymerizable Compound | D5 | 2.80 |
| Photopolymerization Initiator | I4 | 1.360 |
| Resin | P7 | 44.04 |
| Surfactant | F2 | 9.67 |
| Polymerization Inhibitor | G1 | 0.001 |
| Solvent | J1 | 25.90 |
| | J5 | 31.63 |

The raw materials shown above in the table are as follows.

(Color Material)

PR254: C.I. Pigment Red 254

PB 15:6: C.I. Pigment Blue 15:6

PY139: C.I. Pigment Yellow 139

PY150: C.I. Pigment Yellow 150

PY185 C.I. Pigment Yellow 185

PV23: C.I. Pigment Violet 23

PG36: C.I. I. Pigment Green 36

PBk 32: C.I. Pigment Black 32

IB: IRGAPHOR BLACK (manufactured by BASF SE)

(Near Infrared Absorbing Colorant)

K1, K2: compounds having the following structures. In the following structural formulae, Et represents an ethyl group, and Ph represents a phenyl group.

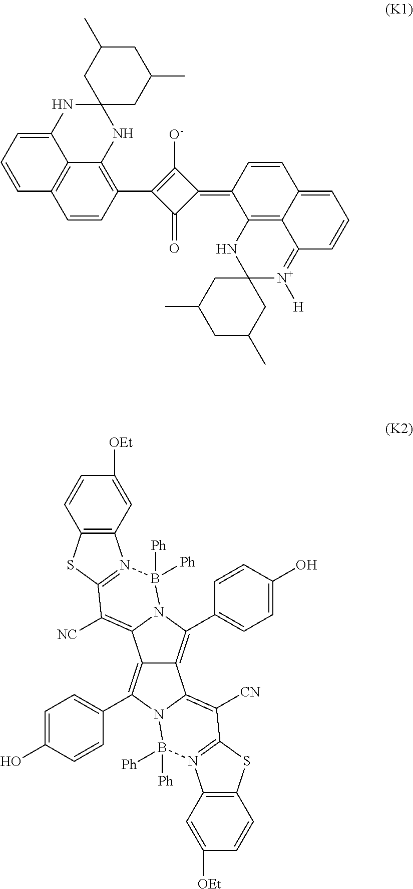

N1: SMP-388 (a cyanine compound, manufactured by Hayashibara Co., Ltd.)

N2: compounds having the following structures. In the following structural formulae, Ph represents a phenyl group.

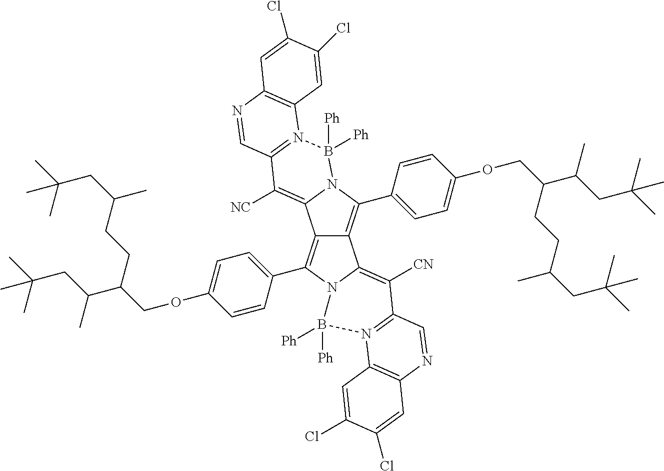

(Inorganic Particles)

TiO₂: TTO-51 (C) (manufactured by Ishihara Sangyo Kaisha Ltd.)

(Derivative)

B1, K4: compounds having the following structures. In the following structural formulae, Et represents a ethyl group, and Ph represents a phenyl group.

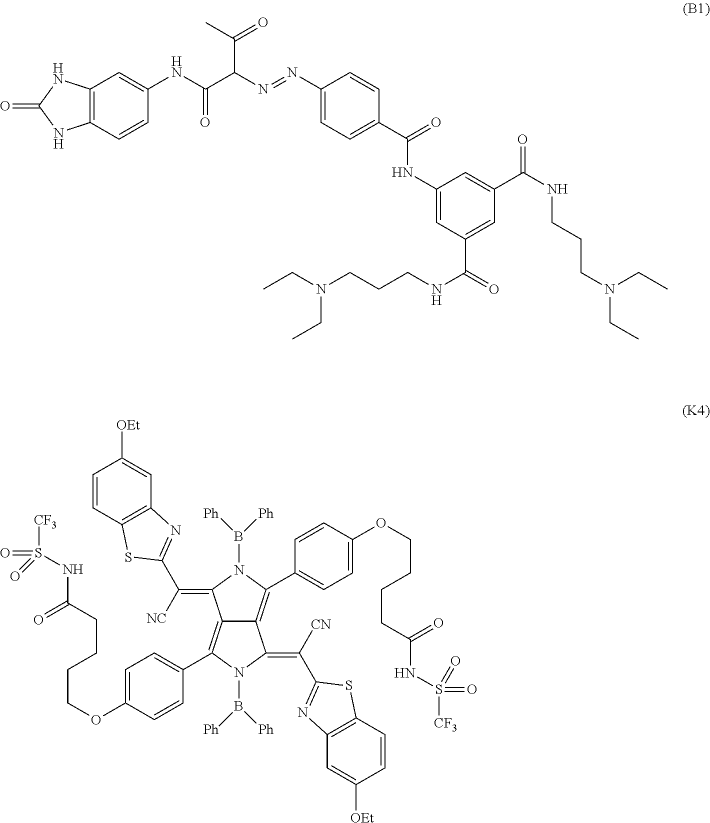 [SMILES: CCN(CC)CCCNC(=O)c1cc(NC(=O)c2ccc(/N=N/C(C(C)=O)C(=O)Nc3ccc4[nH]c(=O)[nH]c4c3)cc2)cc(C(=O)NCCCN(CC)CC)c1 ; CCOc1ccc2sc(/C(C#N)=c3/c4c(-c5ccc(OCCCCC(=O)NS(=O)(=O)C(F)(F)F)cc5)n(B(c5ccccc5)c5ccccc5)/c(=C(/C#N)c5nc6cc(OCC)ccc6s5)c4c(-c4ccc(OCCCCC(=O)NS(=O)(=O)C(F)(F)F)cc4)n3B(c3ccccc3)c3ccccc3)nc2c1]

B2-1: compounds having the following structures.

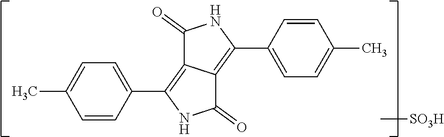

B2-2: compounds having the following structures.

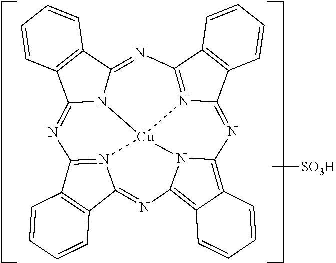

B2-3: compounds having the following structures.

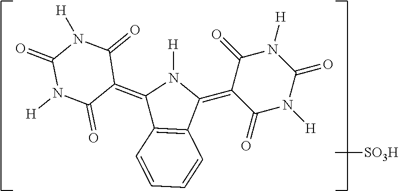

B2-4: compounds having the following structures.

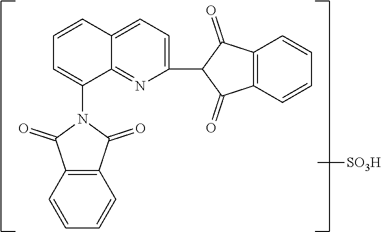

(Dispersant)

C1: a resin having the following structure (a numerical value added to a main chain represents a molar ratio, and a numerical value added to a side chain represents the number of repeating units; Mw=20,000)

C2: a resin having the following structure (a numerical value added to a main chain represents a molar ratio, and a numerical value added to a side chain represents the number of repeating units; Mw=26,000)

C3: a resin having the following structure (a numerical value added to a main chain represents a molar ratio, and a numerical value added to a side chain represents the number of repeating units; Mw=21,000)

C4: DISPERBYK 2000 (resin concentration: 40% by mass, manufactured by BYK Japan

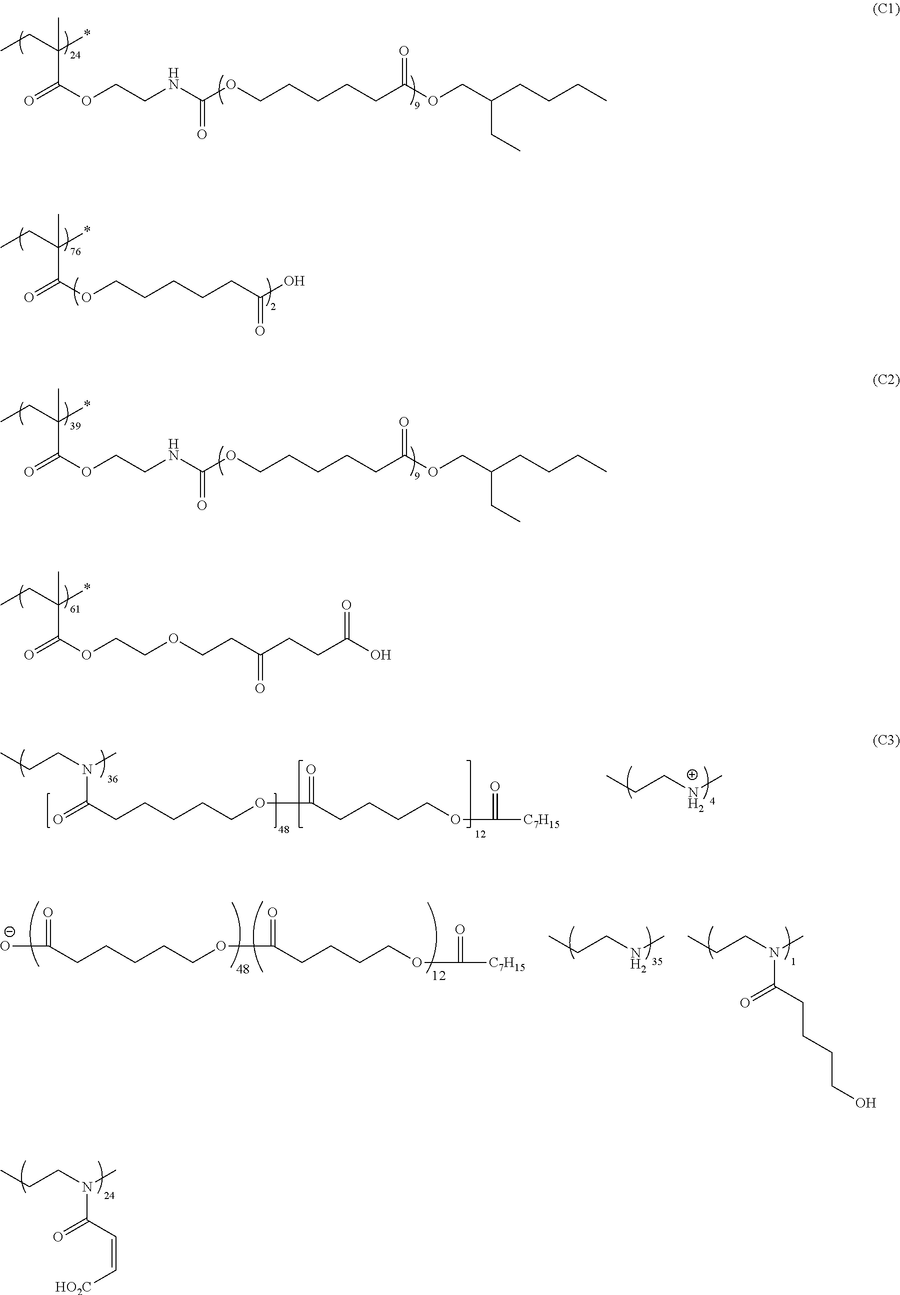

(Resin)

P1: a resin having the following structure (a numerical value added to a main chain represents a molar ratio; Mw=11,000)

P2: a resin having the following structure (Mw=4,400, acid value=95 mgKOH/g; in the following structural formula, M represents a phenyl group, and A represents a biphenyltetracarboxylic anhydride residue)

P3: ACA250 (resin concentration: 45% by mass, manufactured by Daicel Corporation)

P4: a resin having the following structure (a numerical value added to a main chain represents a molar ratio; Mw=14,000)

P5: a resin having the following structure (a numerical value added to a main chain represents a molar ratio; Mw=14,000)

P6: a resin having the following structure (a numerical value added to a main chain represents a molar ratio; Mw=12,000)

P7: a resin having the following structure (a numerical value added to a main chain represents a molar ratio; Mw=41,300)

P8: a resin having the following structure (a resin described in Example 1 of paragraph “0066” of JP2017-133035A; a triazine resin, Mw=3,100)

P9: a resin having the following structure (a numerical value added to a main chain represents a molar ratio; Mw=20,000)

P10: a resin having the following structure (a numerical value added to a main chain represents a molar ratio; Mw=40,000)

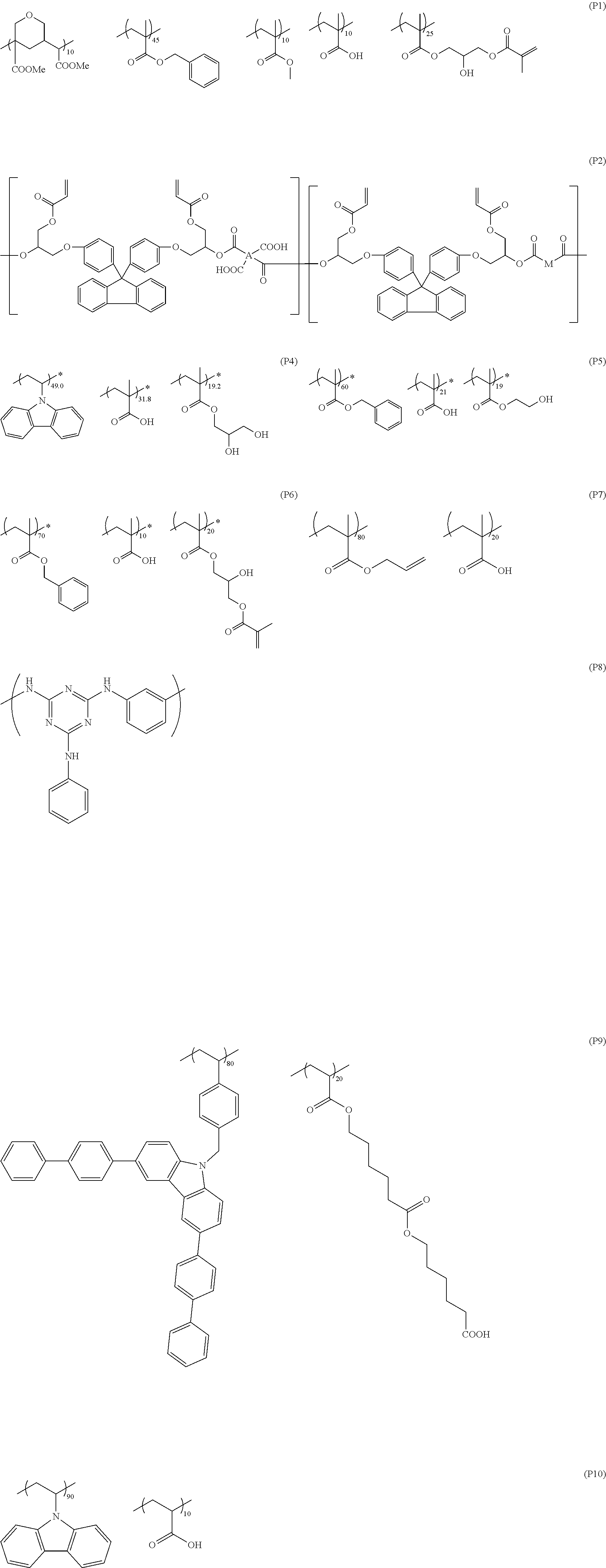

(Polymerizable Compound)

D1: a compound having the following structure (a+b+c=3)

D2: a compound having the following structure (a+b+c=4)

D3: a mixture of compounds having the following structures (compound in which a+b+c=5:compound in which a+b+c=6=3:1 (molar ratio))

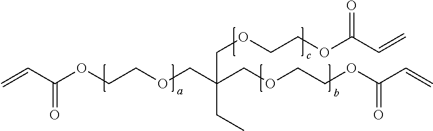

D4: compounds having the following structures

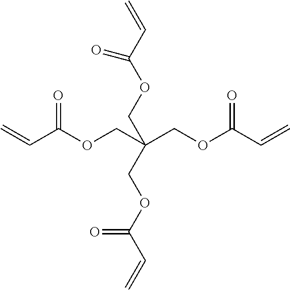 [SMILES: C=CC(=O)OCC(COC(=O)C=C)(COC(=O)C=C)COC(=O)C=C]

D5: a mixture of the following compounds (compound on the left side: compound on the right side=7:3 (mass ratio))

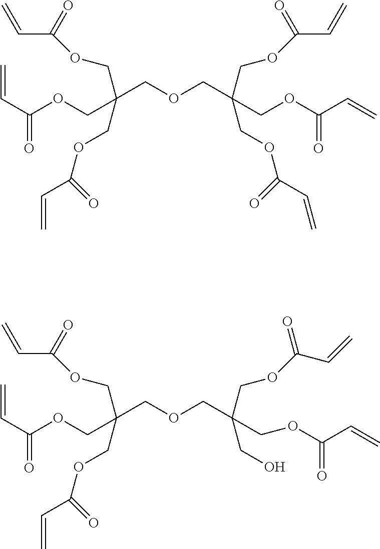 [SMILES: C=CC(=O)OCC(COCC(COC(=O)C=C)(COC(=O)C=C)COC(=O)C=C)(COC(=O)C=C)COC(=O)C=C ; C=CC(=O)OCC(CO)(COCC(COC(=O)C=C)(COC(=O)C=C)COC(=O)C=C)COC(=O)C=C]

D6: ARONIX M-520 (manufactured by Toagosei Co., Ltd.)

D8: OGSOL EA-0300 (manufactured by Osaka Gas Chemicals Co., Ltd., a (meth) acrylate monomer having a fluorene skeleton)

D9: compounds having the following structures

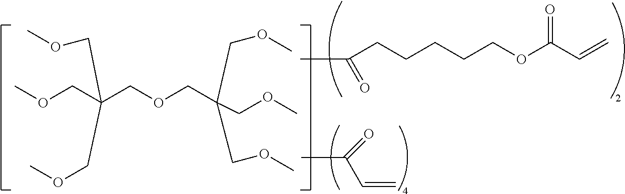

D10: compounds having the following structures

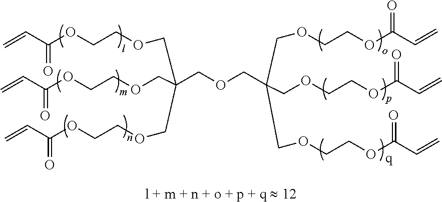

D11: compounds having the following structures

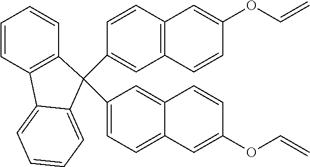 [SMILES: C=COc1ccc2cc(C3(c4ccc5cc(OC=C)ccc5c4)c4ccccc4-c4ccccc43)ccc2c1]

D12: compounds having the following structures

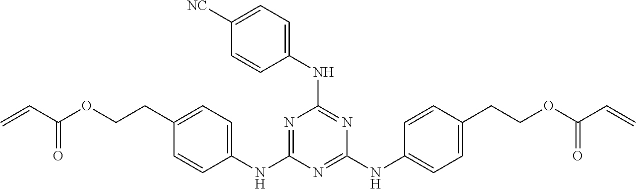 [SMILES: C=CC(=O)OCCc1ccc(Nc2nc(Nc3ccc(C#N)cc3)nc(Nc3ccc(CCOC(=O)C=C)cc3)n2)cc1]

(High Refractive Index Compound)

T10: compounds having the following structures

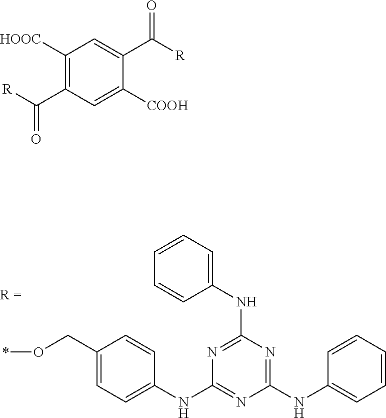

(Photopolymerization Initiator)

I1: IRGACURE OXE01 (manufactured by BASF SE, photoradical polymerization initiator)

I2 to I4: compounds having the following structures

I6: NCI831 (manufactured by ADEKA CORPORATION)

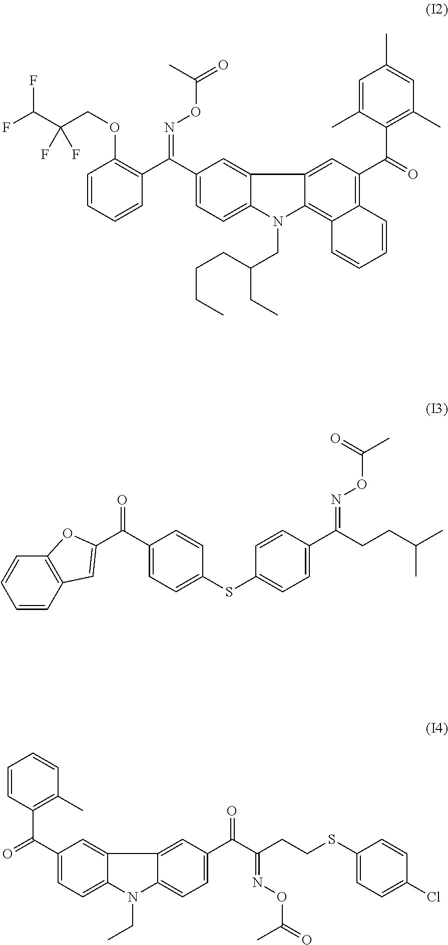 [SMILES: CCCCC(CC)Cn1c2ccc(/C(=N\OC(C)=O)c3ccccc3OCC(F)(F)C(F)F)cc2c2cc(C(=O)c3c(C)cc(C)cc3C)c3ccccc3c21 ; CC(=O)O/N=C(\CCC(C)C)c1ccc(Sc2ccc(C(=O)c3cc4ccccc4o3)cc2)cc1 ; CCn1c2ccc(C(=O)/C(CCSc3ccc(Cl)cc3)=N/OC(C)=O)cc2c2cc(C(=O)c3ccccc3C)ccc21]

(Epoxy Compound)

E1: EPICLON N-695 (manufactured by DIC Corporation)

(Polyfunctional Thiol)

M1: trimethylolpropane tris(3-mercaptobutyrate)

(Ultraviolet Absorber)

L1: compounds having the following structures

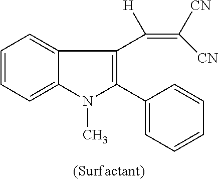 [SMILES: Cn1c(-c2ccccc2)c(C=C(C#N)C#N)c2ccccc21]

F1: the following mixture (Mw=14,000, in the following formula, “%” representing the proportion of a repeating unit is mol %) In the following formula, “%” representing the proportion of a repeating unit is mol %.

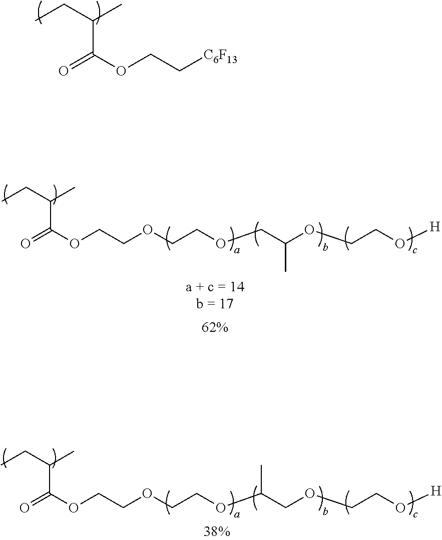

F2: MEGAFACE RS-72-K (manufactured by DIC Corporation)

(Polymerization Inhibitor)

G1: p-methoxyphenol

(Silane Coupling Agent)

H1: a compound having the following structure (in the following structural formulae, Et represents an ethyl group)

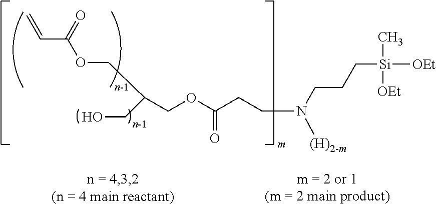

(Solvent)

J1: propylene glycol monomethyl ether acetate (PGMEA)

J2: cyclohexanone

J3: 3-methoxy-N,N-dimethylpropanamide

J4: 3-butoxy-N,N-dimethylpropanamide

J5: cyclopentanone

### Manufacturing of Optical Filter

### Example 1

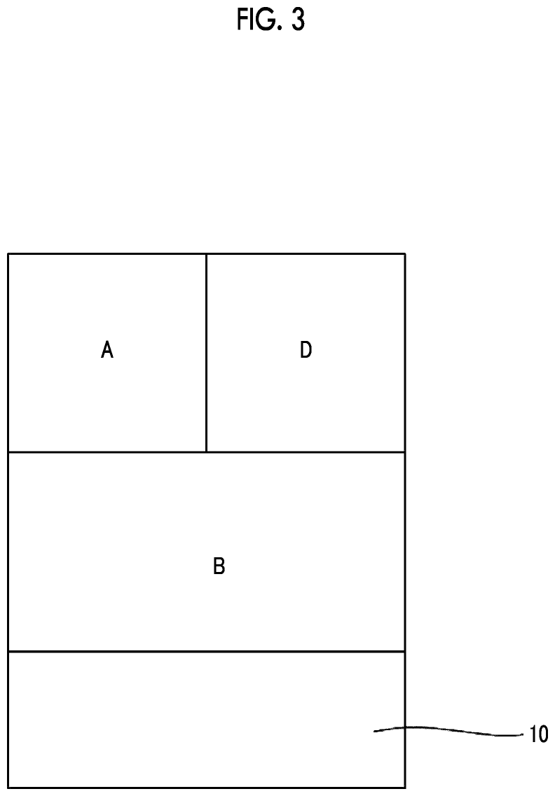

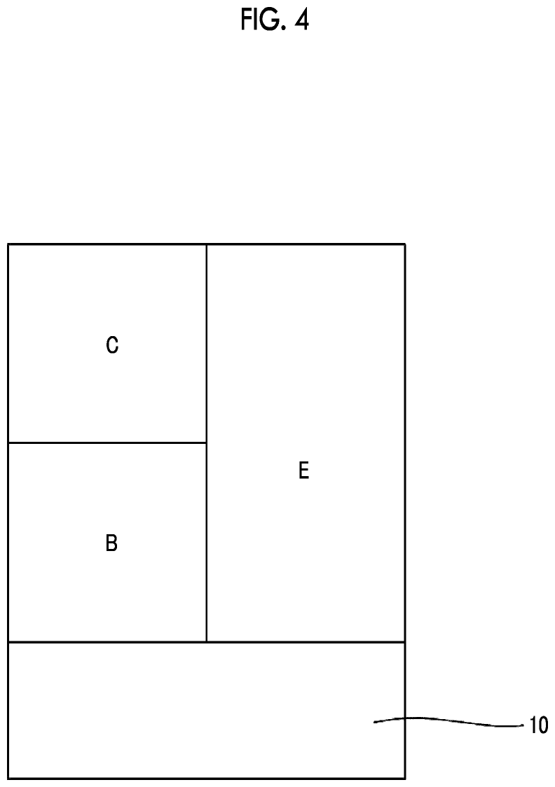

Optical filters shown in FIGS. 2 to 4 were manufactured using the compositions 101, 201, 202, 203, and 301.

Specifically, the composition 301 was applied to a silicon wafer 10 using a spin coating method such that the thickness of the formed film was 0.7 km. Next, the coating film was heated using a hot plate at 100° C. for 2 minutes. Next, using an i-ray stepper exposure device FPA-3000 i5+(manufactured by Canon Corporation), the coating film was exposed through a mask having a 2 μm×2 μm Bayer pattern at an exposure dose of 1,000 mJ/cm².

Next, puddle development was performed at 23° C. for 60 seconds using a tetramethylammonium hydroxide (TMAH) 0.3% by mass aqueous solution. Next, the coating film was rinsed by spin showering using pure water. Next, the coating film was heated using a hot plate at 200° C. for 5 minutes. As a result, a 2 μm×2 μm Bayer pattern (near infrared cut filter B) was formed.

Next, the composition 201 was applied to the pattern of the near infrared cut filter B using a spin coating method such that the thickness of the formed film was 0.7 μm. Next, the coating film was heated using a hot plate at 100° C. for 2 minutes. Next, using an i-ray stepper exposure device FPA-3000 i5+(manufactured by Canon Corporation), the coating film was exposed through a mask having a 2 μm×2 μm Bayer pattern at an exposure dose of 1,000 mJ/cm². Next, puddle development was performed at 23° C. for 60 seconds using a tetramethylammonium hydroxide (TMAH) 0.3% by mass aqueous solution. Next, the coating film was rinsed by spin showering using pure water. Next, the coating film was heated using a hot plate at 200° C. for 5 minutes. As a result, a red pixel A was formed on the pattern of the near infrared cut filter B. Likewise, the composition 202 and the composition 203 were sequentially patterned as described above. As a result, a green pixel C and a blue pixel D were formed.

Next, the composition 101 was applied to the silicon wafer 10 on which the pixels were formed using a spin coating method such that the thickness of the formed film was 1.4 μm. Next, the coating film was heated using a hot plate at 100° C. for 2 minutes. Next, using an i-ray stepper exposure device FPA-3000 i5+(manufactured by Canon Corporation), the coating film was exposed through a mask having a 2 m×2 μm Bayer pattern at an exposure dose of 1,000 mJ/cm². Next, puddle development was performed at 23° C. for 60 seconds using a tetramethylammonium hydroxide (TMAH) 0.3% by mass aqueous solution. Next, the coating film was rinsed by spin showering using pure water. Next, the coating film was heated using a hot plate at 200° C. for 5 minutes. As a result, a pixel E of the infrared transmitting filter was formed on a portion where the pattern of the near infrared cut filter B was not formed. This way, the optical filters shown in FIGS. 2 to 4 were manufactured.

### Examples 2 to 13 and 101 to 110 and Reference Example

Optical filters were manufactured using the same method as that of Example 1, except that the compositions 102 to 114 and 401 to 410 were used instead of the composition 101. The compositions used for forming the respective pixels are shown in the following table.

<Evaluation>

Each of the optical filters manufactured in Examples and Reference Example was incorporated into a solid image pickup element using a well-known method. Using a light emitting diode (LED) having a center wavelength of an emission intensity at a wavelength of 940 nm as a light source, the sensitivity (Signal to Noise Ratio (SN Ratio)) of the pixel E of the optical filter according to Example was measured, and a relative sensitivity factor as a ratio of the sensitivity of the pixel E of the optical filter according to Example to the sensitivity of the pixel E of the optical filter according to Reference Example (the sensitivity of the pixel E of the optical filter according to Example/the sensitivity of the pixel E of the optical filter according to Reference Example) was obtained.

TABLE 6

| | Exam- | Exam- | Exam- | Exam- | Exam- | Exam- | Exam- | Exam- | Exam- | Exam- | Exam- | Exam- | Exam- | Reference |
|---|---|---|---|---|---|---|---|---|---|---|---|---|---|---|
| | ple 1 | ple 2 | ple 3 | ple 4 | ple 5 | ple 6 | ple 7 | ple 8 | ple 9 | ple 10 | ple 11 | ple 12 | ple 13 | Example |
| Composition | E | | | | | | | | | | | | | |
| 101 | | | | | | | | | | | | | | |
| Composition | | | | | | | | | | | | | | E |
| 102 | | | | | | | | | | | | | | |
| Composition | | E | | | | | | | | | | | | |
| 103 | | | | | | | | | | | | | | |
| Composition | | | E | | | | | | | | | | | |
| 104 | | | | | | | | | | | | | | |
| Composition | | | | E | | | | | | | | | | |
| 105 | | | | | | | | | | | | | | |
| Composition | | | | | E | | | | | | | | | |
| 106 | | | | | | | | | | | | | | |
| Composition | | | | | | E | | | | | | | | |
| 107 | | | | | | | | | | | | | | |
| Composition | | | | | | | E | | | | | | | |
| 108 | | | | | | | | | | | | | | |
| Composition | | | | | | | | E | | | | | | |
| 109 | | | | | | | | | | | | | | |
| Composition | | | | | | | | | E | | | | | |
| 110 | | | | | | | | | | | | | | |
| Composition | | | | | | | | | | E | | | | |
| 111 | | | | | | | | | | | | | | |
| Composition | | | | | | | | | | | E | | | |
| 112 | | | | | | | | | | | | | | |
| Composition | | | | | | | | | | | | E | | |
| 113 | | | | | | | | | | | | | | |
| Composition | | | | | | | | | | | | | E | |
| 114 | | | | | | | | | | | | | | |
| Composition | A | A | A | A | A | A | A | A | A | A | A | A | A | A |
| 201 | | | | | | | | | | | | | | |
| Composition | C | C | C | C | C | C | C | C | C | C | C | C | C | C |
| 202 | | | | | | | | | | | | | | |
| Composition | D | D | D | D | D | D | D | D | D | D | D | D | D | D |
| 203 | | | | | | | | | | | | | | |
| Composition | B | B | B | B | B | B | B | B | B | B | B | B | B | B |
| 301 | | | | | | | | | | | | | | |
| Specific | 1.2 | 1.4 | 1.3 | 1.3 | 1.4 | 1.3 | 1.2 | 1.3 | 1.2 | 1.2 | 1.2 | 1.2 | 1.2 | 1 |
| Response | | | | | | | | | | | | | | |

TABLE 7

| | Example | Example | Example | Example | Example | Example | Example | Example | Example | Example |
|---|---|---|---|---|---|---|---|---|---|---|
| | 101 | 102 | 103 | 104 | 105 | 106 | 107 | 108 | 109 | 110 |
| Composition 401 | E | | | | | | | | | |
| Composition 402 | | | | | | | | | | |
| Composition 403 | | E | | | | | | | | |
| Composition 404 | | | E | | | | | | | |
| Composition 405 | | | | E | | | | | | |
| Composition 406 | | | | | E | | | | | |
| Composition 407 | | | | | | E | | | | |
| Composition 408 | | | | | | | E | | | |
| Composition 409 | | | | | | | | E | | |
| Composition 410 | | | | | | | | | E | |
| Composition 201 | A | A | A | A | A | A | A | A | A | A |
| Composition 202 | C | C | C | C | C | C | C | C | C | C |
| Composition 203 | D | D | D | D | D | D | D | D | D | D |
| Composition 301 | B | B | B | B | B | B | B | B | B | B |
| Specific Response | 1.2 | 1.4 | 1.4 | 1.4 | 1.4 | 1.4 | 1.4 | 1.5 | 1.5 | 1.4 |

In Examples 1 to 13 and 101 to 110, the sensitivity of the pixel E was further improved as compared to Reference Example. In addition, in Examples 1 to 13 and 101 to 110, infrared light was able to be accurately detected with high sensitivity without being affected by noise or the like caused by visible light.

In the optical filters according to Examples 1 to 13 and 101 to 110, in at least a part of a wavelength range of 900 to 1,400 nm, a difference (t1−t2a) between a refractive index t1 of the pixel E and a refractive index t2a of the green pixel C adjacent to the pixel E and a difference (t1−t2b) between the refractive index t1 of the pixel E and a refractive index t2b of the blue pixel D adjacent to the pixel E were larger than −0.1. In addition, the difference in refractive index with respect to light having a wavelength of 940 nm was larger than −0.1.

On the other hand, in the optical filter according to Reference Example, in the entire wavelength range of 900 to 1,400 nm, at least one of a difference (t1−t2a) between a refractive index t1 of the pixel E and a refractive index t2a of the green pixel C adjacent to the pixel E or a difference (t1−t2b) between the refractive index t1 of the pixel E and a refractive index t2b of the blue pixel D adjacent to the pixel E was lower than −0.1.

### EXPLANATION OF REFERENCES

110: solid image pickup element
111: near infrared cut filter
112: color filter
114: infrared transmitting filter
115: microlens
116: planarizing layer

What is claimed is:

1. A composition comprising:
a color material that transmits infrared light and blocks visible light;
a near infrared absorbing colorant; and
a curable compound,
wherein a ratio A/B of a minimum value A of an absorbance of the composition in a wavelength range of 400 to 700 nm to a maximum value B of an absorbance of the composition in a wavelength range of 1,400 to 1,500 nm is 4.5 or higher, and
in a case where a film having a thickness of 1 μm is formed using the composition, the film has a maximum value of a refractive index in a wavelength range of 800 nm or longer.

2. The composition according to claim 1,
wherein the maximum value of the refractive index is 1.8 or higher.

3. The composition according to claim 1,
wherein the maximum value of the refractive index is present on a longer wavelength side than a maximum absorption wavelength of the near infrared absorbing colorant.

4. The composition according to claim 1,
wherein the maximum value of the refractive index is present in a wavelength range of 800 to 1,000 nm.

5. The composition according to claim 1,
wherein the near infrared absorbing colorant is at least one selected from a squarylium compound, a pyrrolopyrrole compound, a cyanine compound, a phthalocyanine compound, or an immonium compound.

6. The composition according to claim 1,
wherein the color material that transmits infrared light and blocks visible light includes two or more chromatic colorants and forms black using a combination of the two or more chromatic colorants, or includes one or more chromatic colorants and an organic black colorant.

7. The composition according to claim 1,
wherein a content of the near infrared absorbing colorant is 5 to 200 parts by mass with respect to 100 parts by mass of the color material that transmits infrared light and blocks visible light.

8. The composition according to claim 1,
wherein a content of a blue colorant is 10% to 50% by mass with respect to a total mass of the color material that transmits infrared light and blocks visible light.

9. The composition according to claim 1,
wherein the curable compound includes a compound having at least one selected from a fluorene skeleton or a triazine skeleton.

10. The composition according to claim 1, further comprising:
inorganic particles.

11. The composition according to claim 10,
wherein the inorganic particles are titanium dioxide particles.

12. The composition according to claim 1,
wherein in a case where a film having a thickness of 1 μm is formed using the composition from which the near infrared absorbing colorant is excluded, a minimum value of a refractive index of the film with respect to light in a wavelength of 900 to 1,000 nm is 1.7 or higher.

13. The film which is formed using the composition according to claim 1.

14. An optical filter comprising:
a first pixel that is formed using the composition according to claim 1; and
a second pixel that is adjacent to the first pixel and is different from the first pixel.

15. An optical filter comprising:
a first pixel in which a ratio A/B of a minimum value A of an absorbance in a wavelength range of 400 to 700 nm to a maximum value B of an absorbance in a wavelength range of 1,400 to 1,500 nm is 4.5 or higher and a maximum value of a refractive index is in a wavelength range of 800 nm or longer; and
a second pixel that is adjacent to the first pixel and is different from the first pixel, wherein a difference t1−t2 between a refractive index t1 of the first pixel and a refractive index t2 of the second pixel is larger than −0.1 in at least a part of a wavelength range of 900 to 1,400 nm.

16. The optical filter according to claim 15,
wherein the maximum value of the refractive index of the first pixel is 1.8 or higher.

17. The optical filter according to claim 15,
wherein the maximum value of the refractive index of the first pixel is present in a wavelength range of 800 to 1,000 nm.

18. The optical filter according to claim 14,
wherein a difference t1−t2 between a refractive index t1 of the first pixel and a refractive index t2 of the second pixel is larger than −0.1 in at least a part of a wavelength range of 900 to 1,000 nm.

19. A solid image pickup element comprising:
the film according to claim 13.

20. An infrared sensor comprising:
the film according to claim 13.
